(19) United States
(12) Patent Application Publication
(10) Pub. No.: US 2011/0101461 A1
(43) Pub. Date: May 5, 2011

(54) SEMICONDUCTOR DEVICE AND MANUFACTURING METHOD THEREOF

(75) Inventors: Masahiko TAKEUCHI, Kanagawa (JP); Ryo NAKAGAWA, Osaka (JP); Kazuo NAKAGAWA, Tokyo (JP)

(73) Assignees: RENESAS ELECTRONICS CORPORATION; PANASONIC CORPORATION

(21) Appl. No.: 12/915,377

(22) Filed: Oct. 29, 2010

(30) Foreign Application Priority Data
Oct. 30, 2009 (JP) 2009-250569

(51) Int. Cl. H01L 27/088; H01L 21/336; H01L 29/78

(52) U.S. Cl. 257/368; 438/294; 257/288; 257/E27.06; 257/E21.409; 257/E29.255

(57) ABSTRACT

The present invention presupposes a MIPS electrode in which a gate electrode of a MISFET is made up of a stacked film of a metal film and a polysilicon film. Then, by a first characteristic point that a gate contact hole is formed to have an opening diameter larger than a gate length of the gate electrode of the MIPS electrode and a second characteristic point that a concave portion is formed in a side surface of the metal film constituting the gate electrode, the further reduction of the gate resistance (parasitic resistance) and the improvement of the connection reliability between the gate electrode and the gate plug can be achieved.

### CROSS-REFERENCE TO RELATED APPLICATION

The present application claims priority from Japanese Patent Application No. 2009-250569 filed on Oct. 30, 2009, the content of which is hereby incorporated by reference to this application.

### TECHNICAL FIELD OF THE INVENTION

The present invention relates to a semiconductor device and a manufacturing technology thereof, and more particularly to a technology effectively applied to a semiconductor device having a structure in which a plug is connected to a gate electrode of a MISFET (Metal Insulator Semiconductor Field Effect Transistor) and a manufacturing technology thereof.

### BACKGROUND OF THE INVENTION

Japanese Patent Application Laid-Open Publication No. 11-340322 (Patent Document 1) discloses a technology relating to a shared contact of an SRAM (Static Random Access Memory). An object of this technology is to suppress the increase of the contact resistance caused by the removal of an upper conductive layer which appears first in a shared contact when opening the shared contact.

Japanese Patent Application Laid-Open Publication No. 2007-27348 (Patent Document 2) discloses a technology relating to a shared contact. An object of this technology is to reduce the leakage current.

Japanese Patent Application Laid-Open Publication No. 11-145468 (Patent Document 3) discloses a technology relating to a shared contact. In this technology, a technology of siliciding the surfaces of a gate electrode and a diffusion layer is used, and it is described that the alignment margin to the gate electrode can be obtained in a balanced manner in the shared contact which connects the gate electrode and the drain diffusion layer.

Japanese Patent Application Laid-Open Publication No. 11-150268 (Patent Document 4) discloses a technology relating to a shared contact. An object of this technology is to simplify the manufacturing process of the shared contact and also to reduce the leakage current.

Japanese Patent Application Laid-Open Publication No. 2002-33484 (Patent Document 5) discloses a technology relating to a shared contact. In this technology, a shared contact which overlaps a diffusion layer and a part of a gate electrode is described, and the structure in which the shared contact is in contact with a sidewall of the gate electrode is also described.

Japanese Patent Application Laid-Open Publication No. 2000-58825 (Patent Document 6) discloses a technology relating to a shared contact. An object of this technology is to reduce the resistance of the shared contact which connects a gate electrode of an element and a diffusion layer of another element.

### SUMMARY OF THE INVENTION

For example, a gate electrode of a MISFET is electrically connected to a plug formed in an interlayer insulating film that covers the MISFET. Furthermore, by connecting the plug and a wiring formed on the interlayer insulating film, the gate electrode of the MISFET is connected to the wiring via the plug. As a result, a gate voltage can be applied to the gate electrode of the MISFET via the wiring from a control circuit, and ON/OFF of the MISFET can be controlled by the control circuit.

In recent years, the MISFET is becoming more and more miniaturized. In this case, the gate length of the gate electrode constituting the MISFET is shortened. Usually, the gate electrode of the MISFET and the plug are formed to be in contact with each other on an upper surface of the gate electrode.

However, when the gate electrode is miniaturized, the gate length of the gate electrode is also shortened, and the area of the upper surface of the gate electrode is also decreased. Therefore, when the MISFET is miniaturized, the contact area between the gate electrode and the plug is decreased. This means that the contact resistance between the gate electrode and the plug is increased. Furthermore, when the area of the upper surface of the gate electrode is decreased, higher alignment accuracy of the gate electrode to the plug is required. As a result, when the gate electrode is miniaturized, the alignment margin between the gate electrode and the plug is reduced, and the misalignment between the gate electrode and the plug is likely to occur. In such a case, when the misalignment by the photolithography technology occurs, the gate electrode and the plug are not electrically connected, resulting in the connection failure. As described above, as the gate electrode is miniaturized, the improvement of the reliability in the electrical connection between the gate electrode and the plug is more required.

An object of the present invention is to provide a technology capable of improving the connection reliability between a gate electrode and a plug.

The above and other objects and novel characteristics of the present invention will be apparent from the description of the present specification and the accompanying drawings.

The following is a brief description of an outline of the typical invention disclosed in the present application.

A semiconductor device according to a typical embodiment comprises: (a) a semiconductor substrate; (b) element isolation regions formed in the semiconductor substrate; (c) a MISFET formed in an active region defined by the element isolation regions; (d) a first insulating film formed on the semiconductor substrate so as to cover the MISFET; and (e) a plug formed to penetrate through the first insulating film. In this case, the MISFET includes: (f) a gate insulating film formed on the semiconductor substrate; (g) a gate electrode formed on the gate insulating film; (h) a source region formed in the semiconductor substrate; and (i) a drain region formed in the semiconductor substrate. Further, the gate electrode is made up of: (g1) a first conductive film made of metal or metal compound formed on the gate insulating film; and (g2) a second conductive film including a polysilicon film formed on the first conductive film. At this time, the gate insulating film and the gate electrode extend from the active region to the element isolation region, and the gate electrode and the plug are electrically connected on the element isolation region. Here, a concave portion is formed in one side surface of the first conductive film on the element isolation region, and the second conductive film and the plug are electrically connected at a part of an upper surface of the second conductive film, one side surface of the second conductive film, and a part of a bottom surface of the second conductive film exposed from the concave portion.

Also, a semiconductor device according to a typical embodiment comprises: (a) a semiconductor substrate; (b) element isolation regions formed in the semiconductor substrate; (c) a first MISFET formed in a first active region defined by the element isolation regions; and (d) a second MISFET formed in a second active region defined by the element isolation regions. Furthermore, the semiconductor device further comprises: (e) a first insulating film formed on the semiconductor substrate so as to cover the first MISFET and the second MISFET; and (f) a plug formed to penetrate through the first insulating film. At this time, the first MISFET includes: (g) a first gate insulating film formed on the semiconductor substrate; (h) a first gate electrode formed on the first gate insulating film; (i) a first source region formed in the first active region of the semiconductor substrate; and (j) a first drain region formed in the first active region of the semiconductor substrate. Also, the first gate electrode is made up of: (h1) a first conductive film made of metal or metal compound formed on the first gate insulating film; and (h2) a second conductive film including a polysilicon film formed on the first conductive film. The first gate insulating film and the first gate electrode extend from the first active region to the element isolation region. On the other hand, the second MISFET includes: (k) a second gate insulating film formed on the semiconductor substrate; (l) a second gate electrode formed on the second gate insulating film; (m) a second source region formed in the second active region of the semiconductor substrate; and (n) a second drain region formed in the second active region of the semiconductor substrate. At this time, the plug is arranged so as to be electrically connected to both the first gate electrode formed on the element isolation region and the second drain region formed in the second active region. Here, a concave portion is formed in one side surface of the first conductive film on the element isolation region, and the second conductive film and the plug are electrically connected at a part of an upper surface of the second conductive film, one side surface of the second conductive film, and a part of a bottom surface of the second conductive film exposed from the concave portion.

A manufacturing method of a semiconductor device according to a typical embodiment comprises the steps of: (a) forming element isolation regions for defining active regions in a semiconductor substrate; (b) forming a gate insulating film from above the active region to above the element isolation region of the semiconductor substrate; and (c) forming a first conductive film made of metal or metal compound on the gate insulating film. Also, the manufacturing method further comprises the steps of: (d) forming a second conductive film including a polysilicon film on the first conductive film; and (e) patterning the second conductive film and the first conductive film, thereby forming a gate electrode extending from the active region to the element isolation region. Furthermore, the manufacturing method further comprises the steps of: (f) forming a source region and a drain region in the active region of the semiconductor substrate; and (g) forming a first insulating film on the semiconductor substrate so as to cover the gate electrode. Next, the manufacturing method further comprises the step of: (h) forming a contact hole penetrating through the first insulating film so as to expose a part of an upper surface of the gate electrode, one side surface of the gate electrode and a part of a surface of the element isolation region. Subsequently, the manufacturing method further comprises the step of: (i) performing wet etching to a part of the first conductive film from one side surface of the first conductive film exposed on an inner surface of the contact hole, thereby forming a concave portion in the one side surface of the first conductive film. Thereafter, the manufacturing method further comprises the step of: (j) embedding a conductive material into the contact hole including the concave portion, thereby forming a plug. Here, the second conductive film and the plug are in contact with each other at a part of an upper surface of the second conductive film, one side surface of the second conductive film, and a part of a bottom surface of the second conductive film exposed from the concave portion.

Also, a manufacturing method of a semiconductor device according to a typical embodiment comprises the steps of: (a) forming element isolation regions in a semiconductor substrate, thereby defining a first MISFET forming region and a second MISFET forming region; and (b) forming a first gate insulating film in the first MISFET forming region and a second gate insulating film in the second MISFET forming region. Also, the manufacturing method further comprises: (c) forming a first conductive film made of metal or metal compound on the first gate insulating film in the first MISFET forming region and on the second gate insulating film in the second MISFET forming region; and (d) forming a second conductive film including a polysilicon film on the first conductive film. Furthermore, the manufacturing method further comprises the step of: (e) patterning the second conductive film and the first conductive film, thereby forming a first gate electrode extending from the first MISFET forming region to the element isolation region and a second gate electrode extending from the second MISFET forming region to the element isolation region. Next, the manufacturing method further comprises the steps of: (f) forming a first source region and a first drain region in the first MISFET forming region of the semiconductor substrate; and (g) forming a second source region and a second drain region in the second MISFET forming region of the semiconductor substrate. Subsequently, the manufacturing method further comprises the step of: (h) forming a first insulating film on the semiconductor substrate so as to cover the first gate electrode and the second gate electrode. Thereafter, the manufacturing method further comprises the step of: (i) forming a contact hole penetrating through the first insulating film so as to expose a part of an upper surface of the first gate electrode formed on the element isolation region, one side surface of the first gate electrode formed on the element isolation region and the second drain region formed in the second MISFET forming region. Furthermore, the manufacturing method further comprises the step of: (j) performing wet etching to a part of the first conductive film constituting the first gate electrode from one side surface of the first conductive film exposed on an inner surface of the contact hole, thereby forming a concave portion in the one side surface of the first conductive film constituting the first gate electrode. Finally, the manufacturing method further comprises the step of: (k) embedding a conductive material into the contact hole including the concave portion, thereby forming a plug. Here, the second conductive film constituting the first gate electrode and the plug are in contact with each other at a part of an upper surface of the second conductive film constituting the first gate electrode, one side surface of the second conductive film constituting the first gate electrode, and a part of a bottom surface of the second conductive film constituting the first gate electrode and exposed from the concave portion.

The effects obtained by typical embodiments of the invention disclosed in the present application will be briefly described below.

It is possible to improve the connection reliability between a gate electrode and a plug.

### BRIEF DESCRIPTIONS OF THE DRAWINGS

FIG. 1 is a diagram showing a layout configuration of a semiconductor chip according to the first embodiment of the present invention;

FIG. 2 is an equivalent circuit diagram showing a memory cell of an SRAM according to the first embodiment;

FIG. 3 is a schematic plan view showing a layout configuration of the SRAM;

FIG. 4 shows a cross-sectional view taken along the line A-A in FIG. 3 on a left side and a cross-sectional view taken along the line B-B in FIG. 3 on the right side;

FIG. 5 is a cross-sectional view showing the manufacturing process of the semiconductor device according to the first embodiment;

FIG. 6 is a cross-sectional view showing the manufacturing process of the semiconductor device continued from FIG. 5;

FIG. 7 is a cross-sectional view showing the manufacturing process of the semiconductor device continued from FIG. 6;

FIG. 8 is a cross-sectional view showing the manufacturing process of the semiconductor device continued from FIG. 7;

FIG. 9 is a cross-sectional view showing the manufacturing process of the semiconductor device continued from FIG. 8;

FIG. 10 is a cross-sectional view showing the manufacturing process of the semiconductor device continued from FIG. 9;

FIG. 11 is a cross-sectional view showing the manufacturing process of the semiconductor device continued from FIG. 10;

FIG. 12 is a cross-sectional view showing the manufacturing process of the semiconductor device continued from FIG. 11;

FIG. 13 is a cross-sectional view showing the manufacturing process of the semiconductor device continued from FIG. 12;

FIG. 14 is a cross-sectional view showing the manufacturing process of the semiconductor device continued from FIG. 13;

FIG. 15 is a cross-sectional view showing the manufacturing process of the semiconductor device continued from FIG. 14;

FIG. 16 is a cross-sectional view showing the manufacturing process of the semiconductor device continued from FIG. 15;

FIG. 17 is a cross-sectional view showing the manufacturing process of the semiconductor device continued from FIG. 16;

FIG. 18 is a cross-sectional view showing the manufacturing process of the semiconductor device continued from FIG. 17;

FIG. 19 is a cross-sectional view showing the manufacturing process of the semiconductor device continued from FIG. 18;

FIG. 20 is a cross-sectional view showing the manufacturing process of the semiconductor device continued from FIG. 19;

FIG. 21 is a cross-sectional view showing the manufacturing process of the semiconductor device continued from FIG. 20;

FIG. 22 is a cross-sectional view showing a first modification example of the semiconductor device according to the first embodiment;

FIG. 23 is a cross-sectional view showing a second modification example of the semiconductor device according to the first embodiment;

FIG. 24 is a cross-sectional view taken along the line C-C in FIG. 3;

FIG. 25 is a cross-sectional view showing the manufacturing process of the semiconductor device according to the second embodiment;

FIG. 26 is a cross-sectional view showing the manufacturing process of the semiconductor device continued from FIG. 25;

FIG. 27 is a cross-sectional view showing the manufacturing process of the semiconductor device continued from FIG. 26;

FIG. 28 is a cross-sectional view showing the manufacturing process of the semiconductor device continued from FIG. 27;

FIG. 29 is a cross-sectional view showing the manufacturing process of the semiconductor device continued from FIG. 28;

FIG. 30 is a cross-sectional view showing the manufacturing process of the semiconductor device continued from FIG. 29;

FIG. 31 is a cross-sectional view showing the manufacturing process of the semiconductor device continued from FIG. 30;

FIG. 32 is a cross-sectional view showing the manufacturing process of the semiconductor device continued from FIG. 31;

FIG. 33 is a cross-sectional view showing the manufacturing process of the semiconductor device continued from FIG. 32;

FIG. 34 is a cross-sectional view showing the manufacturing process of the semiconductor device continued from FIG. 33;

FIG. 35 is a cross-sectional view showing the manufacturing process of the semiconductor device continued from FIG. 34;

FIG. 36 is a cross-sectional view showing the manufacturing process of the semiconductor device continued from FIG. 35;

FIG. 37 is a cross-sectional view showing the manufacturing process of the semiconductor device continued from FIG. 36;

FIG. 38 is a cross-sectional view showing the manufacturing process of the semiconductor device continued from FIG. 37;

FIG. 39 is a cross-sectional view showing the manufacturing process of the semiconductor device continued from FIG. 38;

FIG. 40 is a cross-sectional view showing the manufacturing process of the semiconductor device continued from FIG. 39;

FIG. 41 is a cross-sectional view showing the manufacturing process of the semiconductor device continued from FIG. 40;

FIG. 42 is a cross-sectional view showing a first modification example of the semiconductor device according to the second embodiment;

FIG. 43 is a cross-sectional view showing a second modification example of the semiconductor device according to the second embodiment;

FIG. 44 is a cross-sectional view showing the manufacturing process of the semiconductor device according to the third embodiment;

FIG. 45 is a cross-sectional view showing the manufacturing process of the semiconductor device continued from FIG. 44;

FIG. 46 is a cross-sectional view showing the manufacturing process of the semiconductor device continued from FIG. 45;

FIG. 47 is a cross-sectional view showing the manufacturing process of the semiconductor device continued from FIG. 46;

FIG. 48 is a cross-sectional view showing the manufacturing process of the semiconductor device continued from FIG. 47;

FIG. 49 is a cross-sectional view showing the manufacturing process of the semiconductor device continued from FIG. 48;

FIG. 50 is a cross-sectional view showing the manufacturing process of the semiconductor device continued from FIG. 49; and

FIG. 51 is a cross-sectional view showing the structure of the semiconductor device according to the fourth embodiment.

### DESCRIPTIONS OF THE PREFERRED EMBODIMENTS

In the embodiments described below, the invention will be described in a plurality of sections or embodiments when required as a matter of convenience. However, these sections or embodiments are not irrelevant to each other unless otherwise stated, and the one relates to the entire or a part of the other as a modification example, details, or a supplementary explanation thereof.

Also, in the embodiments described below, when referring to the number of elements (including number of pieces, values, amount, range, and the like), the number of the elements is not limited to a specific number unless otherwise stated or except the case where the number is apparently limited to a specific number in principle. The number larger or smaller than the specified number is also applicable.

Further, in the embodiments described below, it goes without saying that the components (including element steps) are not always indispensable unless otherwise stated or except the case where the components are apparently indispensable in principle.

Similarly, in the embodiments described below, when the shape of the components, positional relation thereof, and the like are mentioned, the substantially approximate and similar shapes and the like are included therein unless otherwise stated or except the case where it is conceivable that they are apparently excluded in principle. The same goes for the numerical value and the range described above.

Also, components having the same function are denoted by the same reference symbols throughout the drawings for describing the embodiments, and the repetitive description thereof is omitted. Note that hatching is used even in a plan view so as to make the drawings easy to see.

### First Embodiment

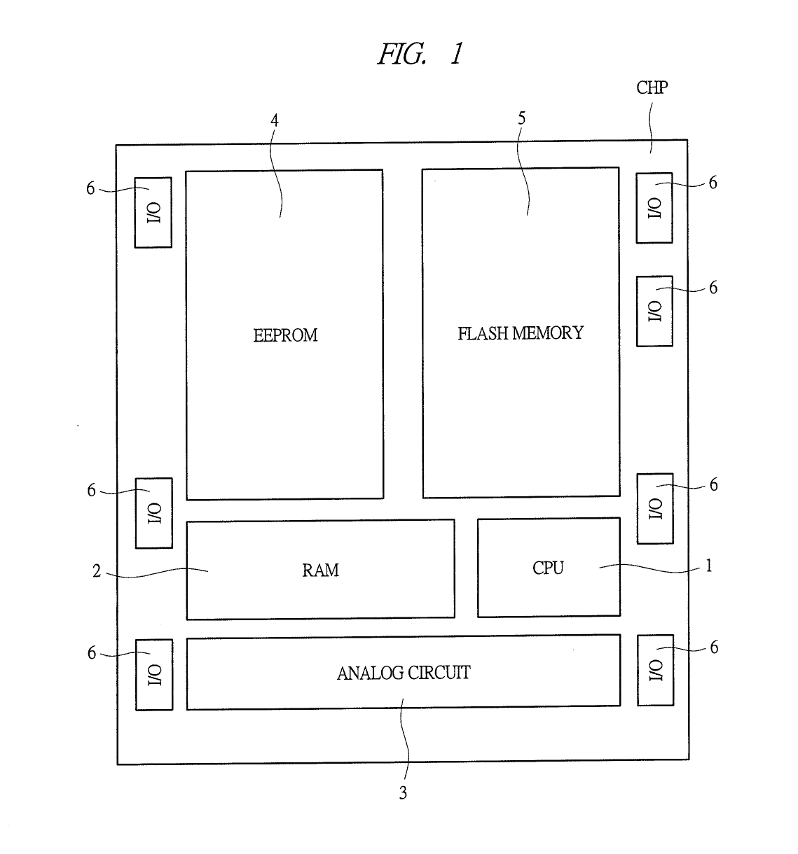

A semiconductor device according to the first embodiment will be described with reference to the drawings. First, a layout configuration of a semiconductor chip in which a system including a microcomputer is formed will be described. FIG. 1 is a diagram showing a layout configuration of a semiconductor chip CHP according to the first embodiment. In FIG. 1, the semiconductor chip CHP includes a CPU (Central Processing Unit) 1, a RAM (Random Access Memory) 2, an analog circuit 3, an EEPROM (Electrical Erasable Programmable Read Only Memory) 4, a flash memory 5 and I/O (Input/Output) circuits 6.

The CPU (circuit) 1 is also referred to as a central processing unit, and it corresponds to a heart of the computer or others. This CPU 1 reads and deciphers an instruction from a storage device and carries out various operations and controls based on the instruction.

The RAM (circuit) 2 is a memory in which the memory information can be accessed in a random manner, in other words, the stored memory information can be read and the memory information can be newly written anytime, and it is also referred to as a random access memory. The RAMs as IC memories include two types of memories such as a DRAM (Dynamic RAM) using a dynamic circuit and an SRAM (Static RAM) using a static circuit. The DRAM is a random access memory which requires the memory holding operation, and the SRAM is a random access memory which does not require the memory holding operation. In the first embodiment, the SRAM is used for the RAM 2.

The analog circuit 3 is a circuit which processes voltage and current signals sequentially changed temporally, that is, analog signals, and it is made up of, for example, an amplifier circuit, a converter circuit, a modulator circuit, an oscillator circuit, a power supply circuit and others.

The EEPROM 4 and the flash memory 5 are types of nonvolatile memories in which both the writing operation and the erasing operation can be electrically carried out, and it is also referred to as an electrically erasable programmable read only memory. Memory cells of the EEPROM 4 and the flash memory 5 are made up of MONOS (Metal Oxide Nitride Oxide Semiconductor) transistors and MNOS (Metal Nitride Oxide Semiconductor) transistors for storage (memory). For example, Fowler-Nordheim tunneling is used for the writing operation and the erasing operation of the EEPROM 4 and the flash memory 5. Note that it is also possible to carry out the writing operation and the erasing operation by using hot electrons and hot holes. The difference between the EEPROM 4 and the flash memory 5 is that the EEPROM 4 is a nonvolatile memory which can carry out the erasing operation in units of byte and the flash memory 5 is a nonvolatile memory which can carry out the erasing operation in units of word lines. In general, programs and others for executing various processes in the CPU 1 are stored in the flash memory 5. On the other hand, various data which are frequently rewritten are stored in the EEPROM 4.

The I/O circuit 6 is an input/output circuit, and it is a circuit for carrying out the data output from the semiconductor chip CHP to a device connected to an outside of the semiconductor chip CHP and the data input from a device connected to an outside of the semiconductor chip CHP to the semiconductor chip CHP.

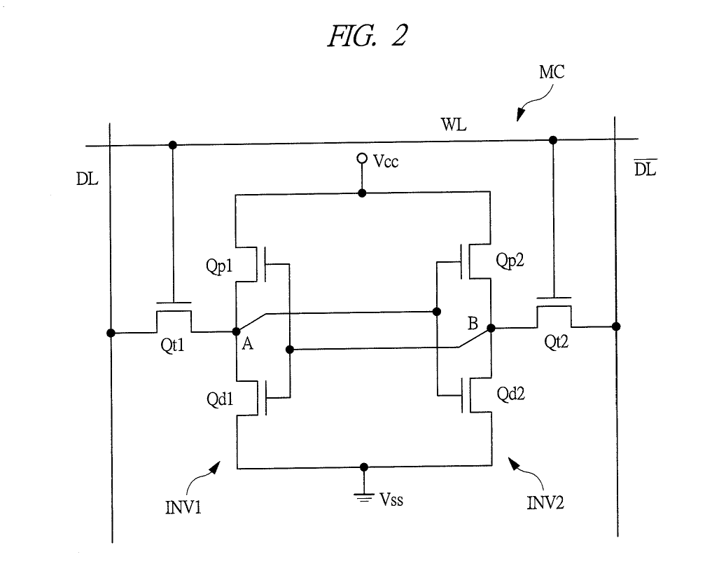

The semiconductor chip CHP according to the first embodiment has the layout configuration as described above, and the SRAM constituting the RAM 2 will be described below. First, an equivalent circuit of a memory cell MC constituting the SRAM will be described. FIG. 2 is an equivalent circuit diagram showing the memory cell MC of the SRAM according to the first embodiment. As shown in FIG. 2, the memory cell MC is disposed at each intersection between a pair of complementary data lines (data line DL, data line D̅L̅) and a word line WL and is made up of a pair of drive MISFETs Qd1 and Qd2, a pair of load MISFETs Qp1 and Qp2 and a pair of transfer MISFETs Qt1 and Qt2. The drive MISFETs Qd1 and Qd2 and the transfer MISFETs Qt1 and Qt2 are made up of n channel MISFETs, and the load MISFETs Qp1 and QP2 are made up of p channel MISFETs.

Of the six MISFETs constituting the memory cell MC, the drive MISFET Qd1 and the load MISFET Qp1 constitute a CMOS inverter INV1, and the drive MISFET Qd2 and the load MISFET Qp2 constitute a CMOS inverter INV2. Input/output terminals (storage nodes A and B) of the pair of CMOS inverters INV1 and INV2 are cross-connected to constitute a flip-flop circuit as an information storage unit for storing the information of 1 bit. Also, one input/output terminal (storage node A) of the flip-flop circuit is connected to one of a source region and a drain region of the transfer MISFET Qt1, and the other input/output terminal (storage node B) is connected to one of a source region and a drain region of the transfer MISFET Qt2.

Furthermore, the other of the source region and the drain region of the transfer MISFET Qt1 is connected to the data line DL, and the other of the source region and the drain region of the transfer MISFET Qt2 is connected to the data line D̅L̅. Also, one end of the flip-flop circuit (each source region of the load MISFETs Qp1 and Qp2) is connected to a power supply voltage (Vcc), and the other end (each source region of the drive MISFETs Qd1 and Qd2) is connected to a reference voltage (Vss).

The operation of the above-described circuit will be described. When the storage node A of one CMOS inverter INV1 is at a high potential (“H”), since the drive MISFET Qd2 is turned ON, the storage node B of the other CMOS inverter INV2 is at a low potential (“L”). Therefore, the drive MISFET Qd1 is turned OFF and the high potential (“H”) of the storage node A is retained. In other words, the state of the mutual storage nodes A and B is retained by the latch circuit in which the pair of CMOS inverters INV1 and INV2 are cross-connected, and the information is stored while the power supply voltage is being applied.

The word line WL is connected to each gate electrode of the transfer MISFETs Qt1 and Qt2, and the conduction and non-conduction of the transfer MISFETs Qt1 and Qt2 are controlled by the word line WL. More specifically, when the word line WL is at a high potential (“H”), since the transfer MISFETs Qt1 and Qt2 are turned ON and the latch circuit and the complementary data lines (data lines DL and D̅L̅) are electrically connected, the potential state of the storage nodes A and B (“H” or “L”) appears on the data lines DL and D̅L̅ and is read as the information of the memory cell MC.

When writing the information in the memory cell MC, the word line WL is set to a “H” potential level and the transfer MISFETs Qt1 and Qt2 are put into an ON state, thereby transmitting the information of the data lines DL and D̅L̅ to the storage nodes A and B. In this manner, the SRAM can be operated.

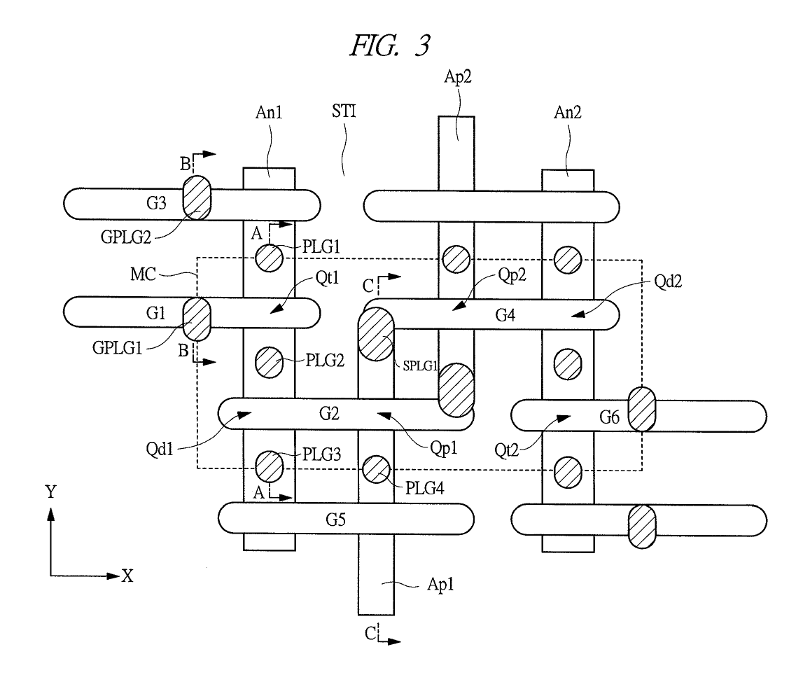

Next, an example of a layout configuration of the above-described SRAM will be described with reference to FIG. 3. FIG. 3 is a schematic plan view showing the layout configuration of the SRAM. As shown in FIG. 3, a memory cell MC of the SRAM is made up of, for example, six field effect transistors formed on a semiconductor substrate such as the pair of drive MISFETs Qd1 and Qd2, the pair of load MISFETs Qp1 and Qp2 and the pair of transfer MISFETs Qt1 and Qt2. At this time, the pair of drive MISFETs Qd1 and Qd2 and the pair of transfer MISFETs Qt1 and Qt2 are made up of n channel MISFETs, and the pair of load MISFETs Qp1 and QP2 are made up of p channel MISFETs.

As shown in FIG. 3, element isolation regions STI are formed in the semiconductor substrate, and active regions An1, Ap1, Ap2 and An2 are defined by the element isolation regions STI. More specifically, the active region An1 defined by the element isolation regions STI is formed so as to extend in a Y direction, and the active region Ap1 is formed adjacent to the active region An1 via the element isolation region STI so as to extend in the Y direction. Also, the active region Ap2 is formed adjacent to the active region Ap1 via the element isolation region STI so as to extend in the Y direction. Furthermore, the active region An2 is formed adjacent to the active region Ap2 via the element isolation region STI so as to extend in the Y direction. As described above, in the SRAM, the active regions An1, Ap1, Ap2 and An2 are formed so as to be arranged in a row in an X direction via the element isolation regions STI, and each of the active regions An1, Ap1, Ap2 and An2 is formed so as to extend in the Y direction.

The active regions An1 and An2 are semiconductor regions obtained by implanting an n type impurity such as phosphorus or arsenic into a semiconductor substrate, and the active regions Ap1 and Ap2 are semiconductor regions obtained by implanting a p type impurity such as boron into the semiconductor substrate.

First, when focusing on the active region An1, a gate electrode G1 and a gate electrode G2 are formed so as to intersect the active region An1 extending in the Y direction in a grade-separated manner. In other words, the gate electrode G1 and the gate electrode G2 are arranged so as to be parallel to each other and extend in the X direction. At this time, the gate electrode G1 and parts of the active region An1 formed on both sides of the gate electrode G1 constitute the transfer MISFET Qt1. In this transfer MISFET Qt1, the parts of the active region An1 formed on both sides of the gate electrode G1 serve as the source region and the drain region, and a plug PLG1 and a plug PLG2 are connected to the parts of the active region An1 to be the source region and the drain region. On the other hand, the gate electrode G1 of the transfer MISFET Qt1 extends from above the active region An1 to above the element isolation region STI, and a gate plug GPLG1 is electrically connected to the gate electrode G1 above the element isolation region STI. Note that a gate electrode G3 included in a memory cell adjacent to the memory cell MC is arranged so as to be parallel to the gate electrode G1. The gate electrode G3 is also formed so as to extend from above the active region An1 to above the element isolation region STI, and the gate electrode G3 is electrically connected to a gate plug GPLG2 above the element isolation region STI.

When further focusing on the active region An1 in the memory cell MC, the gate electrode G2 and parts of the active region An1 formed on both sides of the gate electrode G2 constitute the drive MISFET Qd1. In this drive MISFET Qd1, the parts of the active region An1 formed on both sides of the gate electrode G2 serve as the source region and the drain region, and a plug PLG2 and a plug PLG3 are connected to the parts of the active region An1 to be the source region and the drain region. As described above, the transfer MISFET Qt1 and the drive MISFET Qd1 are formed in the active region An1, and the transfer MISFET Qt1 and the drive MISFET Qd1 share the active region An1 connected by the plug PLG2.

Subsequently, when focusing on the active region Ap1, the gate electrode G2 is formed so as to intersect the active region Ap1 extending in the Y direction in a grade-separated manner. In other words, the gate electrode G2 arranged above the active region An1 is formed so as to further extend in the X direction up to above the active region Ap1. The gate electrode G2 and parts of the active region Ap1 formed on both sides of the gate electrode G2 constitute the load MISFET Qp1. Therefore, it can be understood that the gate electrode G2 functions as the gate electrode of the drive MISFET Qd1 in relation to the active region An1 and also functions as the gate electrode of the load MISFET Qp1 in relation to the active region Ap1.

In the load MISFET Qp, the parts of the active region Ap1 formed on both sides of the gate electrode G2 serve as the source region and the drain region, and a shared plug SPLG1 and a plug PLG4 are connected to the parts of the active region Ap1 to be the source region and the drain region. The shared plug SPLG1 is the plug connected to both the active region Ap1 and the gate electrode G4. More specifically, in the memory cell MC, an end of the gate electrode G4 is disposed at a position adjacent to an upper end portion of the active region Ap1, and the shared plug SPLG1 is formed so as to be connected to both the gate electrode G4 and the active region Ap1 adjacent to each other. Note that a gate electrode G5 included in a memory cell adjacent to the memory cell MC is arranged so as to be parallel to the gate electrode G2.

Next, focusing on the active region Ap2, the gate electrode G4 is formed so as to intersect the active region Ap2 extending in the Y direction in a grade-separated manner. The gate electrode G4 is arranged so as to be adjacent to an upper end portion of the active region Ap1 and also extends in the X direction so as to intersect the active region Ap2 in a grade-separated manner. The gate electrode G4 and parts of the active region Ap2 formed on both sides of the gate electrode G4 constitute the load MISFET Qp2.

In the load MISFET Qp2, the parts of the active region Ap2 formed on both sides sandwiching the gate electrode G4 serve as the source region and the drain region, and a shared plug and a plug are connected to the parts of the active region Ap2 to be the source region and the drain region. This shared plug is the plug connected to both the active region Ap2 and the gate electrode G2. More specifically, in the memory cell MC, an end of the gate electrode G2 is disposed at a position adjacent to a lower end portion of the active region Ap2, and the shared plug is formed so as to be connected to both the gate electrode G2 and the active region Ap2 adjacent to each other.

Furthermore, when focusing on the active region An2, the gate electrode G4 and a gate electrode G6 are formed so as to intersect the active region An2 extending in the Y direction in a grade-separated manner. In other words, the gate electrode G4 and the gate electrode G6 are arranged so as to be parallel to each other and extend in the X direction. At this time, the gate electrode G4 and parts of the active region An2 formed on both sides sandwiching the gate electrode G4 constitute the drive MISFET Qd2. In the drive MISFET Qd2, the parts of the active region An2 formed on both sides of the gate electrode G4 serve as the source region and the drain region, and plugs are connected to the parts of the active region An2 to be the source region and the drain region. At this time, the gate electrode G4 extends in the X direction so that one end thereof is disposed at a position adjacent to an upper end portion of the active region Ap1 and further extends so as to intersect both the active region Ap2 and the active region An2 in a grade-separated manner. Therefore, the gate electrode G4 is electrically connected to the active region Ap1 by the shared plug SPLG1 at the one end thereof. Also, it can be understood that the gate electrode G4 functions as the gate electrode of the load MISFET Qp2 in relation to the active region Ap2 and also functions as the gate electrode of the drive MISFET Qd2 in relation to the active region An2.

On the other hand, the gate electrode G6 and parts of the active region An2 formed on both sides sandwiching the gate electrode G6 constitute the transfer MISFET Qt2. In this transfer MISFET Qt2, the parts of the active region An2 formed on both sides of the gate electrode G6 serve as the source region and the drain region, and plugs are connected to the parts of the active region An2 to be the source region and the drain region. Also, the gate electrode G6 of the transfer MISFET Qt2 extends from above the active region An2 to above the element isolation region STI, and a gate plug is electrically connected to the gate electrode G6 above the element isolation region STI.

As described above, the transfer MISFET Qt2 and the drive MISFET Qd2 are formed in the active region An2, and the transfer MISFET Qt2 and the drive MISFET Qd2 share a region of the active region An2 sandwiched between the gate electrode G4 and the gate electrode G6.

The layout configuration of the SRAM has been described above. Next, a cross-sectional structure of a MISFET constituting a memory cell of an SRAM will be described. In the first embodiment, the structure of an n channel MISFET out of the MISFETs constituting the memory cell of the SRAM will be described, and furthermore, a characteristic connection structure between a gate electrode of the n channel MISFET and a gate plug will be described. For the description of this structure, a cross-sectional view taken along the line A-A in FIG. 3 and a cross-sectional view taken along the line B-B in FIG. 3 are used in the first embodiment.

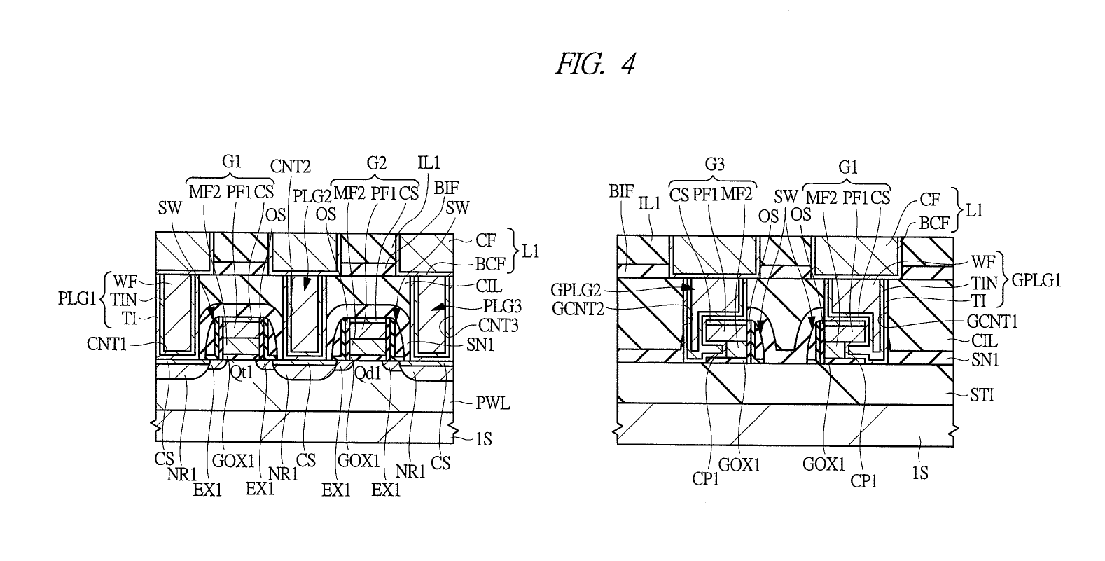

FIG. 4 is a diagram showing the cross-sectional view taken along the line A-A in FIG. 3 and the cross-sectional view taken along the line B-B in FIG. 3 side by side. In FIG. 4, the view on the left corresponds to the cross-sectional view taken along the line A-A in FIG. 3, and the view on the right corresponds to the cross-sectional view taken along the line B-B in FIG. 3. First, the structures of the transfer MISFET Qt1 and the drive MISFET Qd1 will be described with reference to the left view of FIG. 4. Both of the transfer MISFET Qt1 and the drive MISFET Qd1 are n type MISFETs and have the same structure.

The structures of the transfer MISFET Qt1 and the drive MISFET Qd1 will be described. A p type well PWL is formed in a semiconductor substrate 1S. This p type well PWL is a semiconductor region obtained by implanting a p type impurity such as boron, and the transfer MISFET Qt1 and the drive MISFET Qd1 are formed on the p type well PWL. More specifically, a gate insulating film GOX1 is formed on the p type well PWL, and a gate electrode G1 (gate electrode G2) is formed on the gate insulating film GOX1.

The gate insulating film GOX1 is formed of a high dielectric constant film with a dielectric constant higher than that of a silicon oxide film, and it is formed of, for example, a hafnium-based insulating film obtained by implanting lanthanum oxide into hafnium oxide. The gate electrode G1 (gate electrode G2) is made up of a metal film MF2 formed to be in direct contact with the gate insulating film GOX1, a polysilicon film PF1 formed on the metal film MF2 and a nickel platinum silicide film CS formed on a surface of the polysilicon film PF1. The metal film MF2 is formed of, for example, a titanium nitride film. Also, the nickel platinum silicide film CS is formed on the surface of the polysilicon film PF1 in order to reduce the resistance of the gate electrode G1 in the first embodiment, but a nickel silicide film, a titanium silicide film, a cobalt silicide film or a platinum silicide film may be formed instead of the nickel platinum silicide film CS.

Subsequently, on both sidewalls of the gate electrode G1 (gate electrode G2), offset spacers OS formed of, for example, a silicon oxide film are formed. Furthermore, a sidewall SW is formed outside the offset spacer OS, and the sidewall SW is formed of, for example, a stacked film of a silicon oxide film and a silicon nitride film. However, the structure of the sidewall SW is not limited to this, and the sidewall SW can be formed of a single film of a silicon oxide film or a single film of a silicon nitride film.

In the semiconductor substrate 1S below the sidewall SW, a shallow n type impurity diffusion region EX1 is formed as a semiconductor region. Also, a deep n type impurity diffusion region NR1 is formed outside the shallow n type impurity diffusion region EX1, and the nickel platinum silicide film CS is formed on a surface of the deep n type impurity diffusion region NR1.

The sidewall SW is formed so that the source region and the drain region which are the semiconductor regions of the transfer MISFET Qt1 and the drive MISFET Qd1 have the LDD structure. More specifically, each of the source region and the drain region of the transfer MISFET Qt1 and the drive MISFET Qd1 is made up of the shallow n type impurity diffusion region EX1, the deep n type impurity diffusion region NR1 and the nickel platinum silicide film CS. At this time, an impurity concentration of the shallow n type impurity diffusion region EX1 is lower than that of the deep n type impurity diffusion region NR1. Therefore, by forming the shallow n type impurity diffusion regions EX1 with a low impurity concentration for the source region and the drain region below the sidewalls SW, the field concentration below an edge of the gate electrode G1 (gate electrode G2) can be suppressed. The transfer MISFET Qt1 and the drive MISFET Qd1 are formed on the semiconductor substrate 1S in the manner described above.

Subsequently, a multilayer wiring is formed above the semiconductor substrate 1S on which the transfer MISFET Qt1 and the drive MISFET Qd1 have been formed. The structure of the multilayer wiring will be described below. As shown in FIG. 4 (left), on the semiconductor substrate 1S on which the transfer MISFET Qt1 and the drive MISFET Qd1 have been formed, a silicon nitride film SN1 is formed so as to cover the transfer MISFET Qt1 and the drive MISFET Qd1, and a contact interlayer insulating film CIL is formed on the silicon nitride film SN1. The contact interlayer insulating film CIL is formed of, for example, a stacked film of an ozone TEOS film formed by the thermal CVD method using ozone and TEOS (Tetra Ethyl Ortho Silicate) as materials and a plasma TEOS film formed by the plasma CVD method using TEOS as a material provided on the ozone TEOS film. Then, plugs PLG1 to PLG3 which reach the source region and the drain region of the transfer MISFET Qt1 and the drive MISFET Qd1 are formed through the contact interlayer insulating film CIL. The plugs PLG1 to PLG3 are formed by, for example, embedding a titanium film TI, a titanium nitride film TIN formed on the titanium film TI and a tungsten film WF formed on the titanium nitride film TIN into contact holes CNT1 to CNT3. The titanium film TI and the titanium nitride film TIN are provided in order to prevent the diffusion of the tungsten constituting the tungsten film WF into silicon. Note that the contact interlayer insulating film CIL may be formed of either of a silicon oxide film (SiO₂ film) and an SiOF film.

Subsequently, wiring L1s are formed as a first wiring layer on the contact interlayer insulating film CIL. More specifically, the wirings L1 are formed so as to be embedded in a barrier insulating film BIF and an interlayer insulating film IL1 formed on the contact interlayer insulating film CIL in which the plugs PLG1 to plug PLG3 have been formed. In other words, the wirings L1 are formed by embedding a barrier conductive film BCF and a film mainly made of copper (hereinafter, referred to as a copper film CF) into wiring trenches which penetrate through the barrier insulating film BIF and the interlayer insulating film IL1 and in which the plugs PLG1 to PLG3 are exposed at the bottom. In other words, the wirings L1 are formed of the barrier conductive film BCF formed so as to cover a side surface and a bottom surface of the wiring trenches and the copper film CF formed on the barrier conductive film BCF so as to fill the wiring trenches. Furthermore, a multilayer wiring will be formed on the wiring L1, but the description thereof is omitted in the first embodiment. In the manner described above, the transfer MISFET Qt1 and the drive MISFET Qd1 are formed on the semiconductor substrate 1S, and the wirings L1 are formed on the transfer MISFET Qt1 and the drive MISFET Qd1.

In the first embodiment, the gate insulating film GOX1 of the transfer MISFET Qt1 and the drive MISFET Qd1 is formed of a high dielectric constant film with a dielectric constant higher than that of a silicon oxide film. The reason therefor will be described below.

A silicon oxide film has been conventionally used as the gate insulating film GOX1 in terms of its high dielectric strength and excellent electrical and physical stability at an interface between silicon and silicon oxide. The ultra-thin thickness of the gate insulating film GOX1 has been demanded with the miniaturization of the element. When a thin silicon oxide film like this is used as the gate insulating film GOX1, the so-called tunnel current occurs, that is, electrons flowing through the channel of the transfer MISFET Qt1 and the drive MISFET Qd1 tunnel through a barrier formed of the silicon oxide film to flow into the gate electrode.

For its prevention, a high dielectric constant film made of a material with a dielectric constant higher than that of a silicon oxide film, which can increase the physical thickness without changing capacitance, has been used. Since the physical thickness can be increased without changing the capacitance when the high dielectric constant film is used, the leakage current can be reduced. For the reason described above, a high dielectric constant film with a dielectric constant higher than that of a silicon oxide film is used for the gate insulating film GOX1 of the transfer MISFET Qt1 and the drive MISFET Qd1 in the first embodiment.

Note that, for example, hafnium oxide (HfO), hafnium silicate (HfSiO), nitride hafnium silicate (HfSiON) or others is used as a material of the high dielectric constant film.

Subsequently, the reason for using the stacked film of the metal film MF2 and the polysilicon film PF1 for the gate electrode G1 (gate electrode G2) of the transfer MISFET Qt1 and the drive MISFET Qd1 will be described.

For example, when a silicon oxide film is used for the gate insulating film GOX1, usually, the gate electrode G1 (gate electrode G2) formed on the gate insulating film GOX1 is formed of a polysilicon film. Then, in the n channel MISFET (transfer MISFET Qt1 and drive MISFET Qd1), an n type impurity (phosphorus or arsenic) is implanted into the polysilicon film constituting the gate electrode G1 (gate electrode G2). By this means, the work function (Fermi level) of the gate electrode is set near the conduction band of silicon (near 4.05 eV), thereby achieving the reduction of the threshold voltage of the n channel MISFET. Meanwhile, though not described in the first embodiment, in the p channel MISFET (load MISFET), a p type impurity (for example, boron) is implanted into the polysilicon film constituting the gate electrode. By this means, the work function of the gate electrode is set near the valence band of silicon (near 5.17 eV), thereby achieving the reduction of the threshold voltage of the p channel MISFET. More specifically, in the case where a silicon oxide film is used as the gate insulating film GOX1, the work function of the gate electrode can be set near the conduction band or the valence band by implanting an n type impurity or a p type impurity into the gate electrode.

However, in the case where a high dielectric constant film is used as the gate insulating film GOX1 like in the first embodiment, the work function of the gate electrode G1 (gate electrode G2) cannot be set near the conduction band or the valence band even when an n type impurity or a p type impurity is implanted into the gate electrode G1 (gate electrode G2) formed of a polysilicon film. More specifically, when a high dielectric constant film is used as the gate insulating film GOX1, the work function of the gate electrode G1 (gate electrode G2) is increased and separated from near the conduction band in the n channel MISFET (transfer MISFET Qt1 and drive MISFET Qd1). Therefore, the threshold voltage of the n channel MISFET (transfer MISFET Qt1 and drive MISFET Qd1) is increased. Meanwhile, since the work function of the gate electrode is reduced and separated from the valence band in the p channel MISFET (load MISFET), similar to the n channel MISFET (transfer MISFET Qt1 and drive MISFET Qd1), the threshold voltage thereof is increased. The phenomenon that the work function of the gate electrode G1 (gate electrode G2) shifts in a direction of the increase of a threshold voltage as described above is interpreted as Fermi level pinning. Accordingly, it can be understood that the threshold voltage cannot be appropriately adjusted if the gate electrode G1 (gate electrode G2) is formed of a polysilicon film when a high dielectric constant film is used as the gate insulating film GOX1.

Therefore, when a high dielectric constant film with a dielectric constant higher than that of a silicon oxide film is used for the gate insulating film GOX1, in the first embodiment, as the gate electrode G1 (gate electrode G2) disposed on the gate insulating film GOX1, the metal film MF2 is formed to be in direct contact with the gate insulating film GOX1 and the polysilicon film PF1 is formed on the metal film MF2 instead of a single film of a polysilicon film. In other words, in the first embodiment, the gate electrode G1 (gate electrode G2) is formed of a stacked film of the metal film MF2 and the polysilicon film PF1. The gate electrode G1 (gate electrode G2) with such a structure is called a MIPS (Metal Inserted Poly Silicon) electrode.

As described above, when the gate electrode G1 (gate electrode G2) is formed of the MIPS electrode, it is the metal film MF2 that is in direct contact with the gate insulating film GOX1. Accordingly, when the MIPS electrode is used, the threshold voltage can be adjusted by selecting the types of the metal film MF2 instead of adjusting the threshold value by implanting an impurity like in the case of the polysilicon film. Therefore, the above-described problem of the Fermi level pinning can be avoided by using the MIPS electrode as the gate electrode G1 (gate electrode G2).

Furthermore, another reason for using the MIPS electrode for the gate electrode G1 (gate electrode G2) will be described. For example, when a polysilicon film is formed directly on the gate insulating film GOX1, a depletion region is formed at the interface of the polysilicon film on the side of the gate insulating film GOX1. Since the depletion region functions as an insulating region, the depletion region serves as a capacitive insulating film and the gate insulating film GOX1 is apparently increased in thickness. As a result, since the gate capacitance becomes lower than a design value, it becomes difficult to ensure the on-current of the MISFET, and there occurs a problem that the operation speed of the MISFET is lowered. The problem of the depletion of the polysilicon film has become more and more evident with the miniaturization of the MISFET.

Therefore, in the first embodiment, the MIPS electrode is used as the gate electrode G1 (gate electrode G2). In the MIPS electrode, since it is the metal film MF2 that is in direct contact with the gate insulating film GOX1, the problem of the depletion does not occur. More specifically, since the metal film MF2 is made of metal and does not deplete unlike the semiconductor, the problem of the depletion of the gate electrode G1 (gate electrode G2) does not occur. Therefore, it is possible to prevent the gate capacitance from being lower than the design value, and the on-current can be ensured even when the MISFET is miniaturized.

As described above, in the first embodiment, since the MIPS electrode is used as the gate electrode G1 (gate electrode G2), it is possible to prevent the problem of the Fermi level pinning and the problem of the depletion which occur when the gate electrode G1 (gate electrode G2) is formed of the single film of a polysilicon film.

Here, since the problem of the Fermi level pinning and the problem of the depletion can be solved when the gate electrode G1 (gate electrode G2) is formed of a metal film, it is considered that the gate electrode G1 (gate electrode G2) is formed of a single film of a metal film. In the first embodiment, however, the MIPS electrode formed of a stacked film of the metal film MF2 and the polysilicon film PF1 is used for the gate electrode G1 (gate electrode G2) instead of using a single film of a metal film for the gate electrode G1 (gate electrode G2). The reason therefor will be described below.

With the miniaturization of the MISFET, the higher processing accuracy of the gate electrode G1 (gate electrode G2) is also required. However, the process of the metal film has becomes difficult in general. Therefore, when the gate electrode G1 (gate electrode G2) is formed of a single film of a metal film, the thickness of the metal film is increased, and it becomes difficult to achieve the higher processing accuracy of the gate electrode G1 (gate electrode G2). In other words, when a single film of a metal film is used to form the gate electrode G1 (gate electrode G2), it is difficult to improve the processing accuracy, and it becomes difficult to form the gate electrode G1 (gate electrode G2) with a designed gate length. In this case, it becomes difficult to obtain the prescribed electrical properties, and further, the variation in gate length is increased in a plurality of MISFETs.

Therefore, in the first embodiment, the stacked film of a metal film and a polysilicon film is used to form the gate electrode G1 (gate electrode G2) instead of using a single film of a metal film. By forming the gate electrode G1 (gate electrode G2) in the above-described manner, the thickness of the metal film itself can be reduced, and therefore, the processing difficulty of the metal film can be reduced. Furthermore, since the polysilicon film can be easily processed, even when the gate electrode G1 (gate electrode G2) is miniaturized, the high processing accuracy of the gate electrode G1 (gate electrode G2) can be maintained by using the MIPS electrode for the gate electrode G1 (gate electrode G2), and the desired electrical properties can be advantageously obtained.

Therefore, in the first embodiment, a metal film is used so as to be in direct contact with the gate insulating film GOX1 in order to solve the problem of the Fermi level pinning and the depletion, and a stacked film of a metal film and a polysilicon film is used as the gate electrode G1 (gate electrode G2) in order to reduce the processing difficulty of the metal film. More specifically, by using the MIPS electrode for the gate electrode G1 (gate electrode G2) like in the first embodiment, both the suppression of the Fermi level pinning and the depletion and the reduction of the processing difficulty can be achieved.

Next, the structure of a gate plug which is a characteristic structure of the first embodiment will be described with reference to the drawings. The view on the right side of FIG. 4 is a cross-sectional view taken along the line B-B in FIG. 3. In the right view in FIG. 4, the element isolation region STI is formed on the semiconductor substrate 1S, and the gate electrode G1 and the gate electrode G3 are formed on the element isolation region STI via the gate insulating film GOX1. Here, since the structure of the gate plug GPLG1 connected to the gate electrode G1 is the same as the structure of the gate plug GPLG2 connected to the gate electrode G3, the structure of the gate plug GPLG1 connected to the gate electrode G1 will be described below as a representative.

The gate electrode G1 is made up of the metal film MF2 directly formed on the gate insulating film GOX1, the polysilicon film PF1 formed on the metal film MF2 and the nickel platinum silicide film CS formed on the surface of the polysilicon film PF1. On both the sidewalls of the gate electrode G1 thus formed, the offset spacers OS are formed, and sidewalls SW are formed outside the offset spacers OS.

Furthermore, the silicon nitride film SN1 is formed on the element isolation region STI so as to cover the gate electrode G1, and the contact interlayer insulating film CIL is formed on the silicon nitride film SN1. The gate plug GPLG1 is formed so as to penetrate through the contact interlayer insulating film CIL and the silicon nitride film SN1. The barrier insulating film BIF and the interlayer insulating film IL1 are formed on the contact interlayer insulating film CIL in which the gate plug GPLG1 has been formed. A wiring trench is formed in the barrier insulating film BIF and the interlayer insulating film IL1, and the gate plug GPLG1 is disposed at the bottom of the wiring trench. The barrier conductive film BCF is formed on the bottom surface and the side surface of the wiring trench, and the copper film CF is formed so as to fill the wiring trench on the barrier conductive film BCF. By embedding the barrier conductive film BCF and the copper film CF in the wiring trench, the wiring L1 is formed. From the description above, the wiring L1 and the gate electrode G1 are electrically connected via the gate plug GPLG1. In other words, for example, a control circuit is connected to the multilayer wiring, and the gate voltage (gate signal) from the control circuit is applied to the gate electrode G1 via the wiring L1 formed in the lowermost layer of the multilayer wiring and the gate plug GPLG1 connected to the wiring L1.

The gate plug GPLG1 is formed by embedding the titanium film TI, the titanium nitride film TIN and the tungsten film WF into a gate contact hole GCNT1 formed so as to penetrate through the silicon nitride film SN1 and the contact interlayer insulating film CIL. In other words, the gate plug GPLG1 is made up of the titanium film TI formed on the inner wall of the gate contact hole GCNT1, the titanium nitride film TIN formed on the titanium film TI and the tungsten film WF formed on the titanium nitride film TIN.

Here, the first characteristic point of the first embodiment is that the opening diameter of the gate contact hole GCNT1 is made larger than the gate length of the gate electrode G1. In other words, the gate contact hole GCNT1 reaches not only the upper surface of the gate electrode G1 but also the element isolation region STI. Accordingly, not only the upper surface of the gate electrode G1 but also one side surface of the gate electrode G1 is exposed from the gate contact hole GCNT1. Therefore, the area of the gate electrode G1 exposed from the gate contact hole GCNT1 can be increased. This means that the contact area between the gate plug GPLG1 formed to be embedded in the gate contact hole GCNT1 and the gate electrode G1 can be increased. As a result, the contact resistance between the gate plug GPLG1 and the gate electrode G1 can be reduced. In other words, since the diameter of the gate plug GPLG1 is larger than that gate length of the gate electrode G1, the gate plug GPLG1 contacts the gate electrode G1 at not only the upper surface of the gate electrode G1 but also one side surface of the gate electrode G1. Since the contact resistance between the gate plug GPLG1 and the gate electrode G1 is proportional to the size of the contact area, the gate resistance (parasitic resistance) can be reduced by increasing the contact area between the gate plug GPLG1 and the gate electrode G1. When the gate resistance can be reduced, the loss due to the resistance can be reduced, and therefore, it leads to the improvement in the electrical properties of the semiconductor device.

For example, the case where the bottom surface of the gate plug PLG contacts only at the upper surface of the gate electrode G1 will be considered. When the gate electrode G1 is miniaturized, the gate length of the gate electrode G1 is shortened. This means that the area of the upper surface of the gate electrode G1 is reduced. Therefore, when the gate plug GPLG1 contacts the gate electrode G1 only at the upper surface of the gate electrode G1, the contact area between the gate plug GPLG1 and the gate electrode G1 is reduced with the miniaturization of the semiconductor element (with the reduction in the gate length of the gate electrode G1), and the gate resistance (parasitic resistance) is increased. In this case, the loss due to the parasitic resistance is increased, and the electrical properties of the semiconductor element are deteriorated.

On the other hand, in the first embodiment, the diameter of the gate plug GPLG1 is made larger than the gate length of the gate electrode G1. Therefore, the gate plug GPLG1 and the gate electrode G1 can contact at not only the upper surface of the gate electrode G1 but also one side surface of the gate electrode G1. Accordingly, the contact area between the gate electrode G1 and the gate plug GPLG1 can be increased.

Furthermore, the gate electrode G1 has a stacked structure made up of the metal film MF2, the polysilicon film PF1 and the nickel platinum filicide film CS. At this time, when the gate plug GPLG1 is connected only at the upper surface of the gate electrode G1, the gate plug GPLG1 is connected to only the nickel platinum silicide film CS. On the other hand, in the first embodiment, the gate plug GPLG1 is connected also to the side surface of the gate electrode G1, and therefore, the gate plug GPLG1 directly contacts also the polysilicon film PF1 and the metal film MF2 constituting the gate electrode G1. In particular, since the metal film MF2 has a low resistance, the further reduction of the parasitic resistance can be achieved in the structure of the first embodiment in which the metal film MF2 directly contacts the gate plug GPLG1.

Also, according to the first embodiment, even when the connection failure between the upper surface of the gate electrode G1 and the gate plug GPLG1 occurs due to a reason such as the adhesion of a foreign material on the upper surface of the gate electrode G1, since the side surface of the gate electrode G1 and the gate plug GPLG1 are connected, the potential of the connection failure between the gate electrode G1 and the gate plug GPLG1 can be reduced. In other words, according to the first embodiment, the connection reliability between the gate electrode G1 and the gate plug GPLG1 can also be improved.

Furthermore, according to the first characteristic point of the first embodiment that the opening diameter of the gate contact hole GCNT1 is made larger than the gate length of the gate electrode G1, the following effects can be obtained. That is, in the structure in which the gate plug GPLG1 is connected only at the upper surface of the gate electrode G1, with the miniaturization of the gate electrode G1, the misalignment between the gate electrode G1 and the gate plug GPLG1 becomes a significant problem. For example, when the gate electrode G1 is miniaturized, even the slight misalignment prevents the connection between the upper surface of the gate electrode G1 and the bottom surface of the gate plug GPLG1. In this case, the gate electrode G1 and the gate plug GPLG1 are not electrically connected, and the connection failure between the gate electrode G1 and the gate plug GPLG1 occurs. In other words, in the structure in which the gate plug GPLG1 is connected only at the upper surface of the gate electrode G1, the potential of the occurrence of the connection failure due to the misalignment is increased with the progress of the miniaturization.

On the other hand, in the first embodiment, the gate contact hole GCNT1 is formed to have the opening diameter larger than the gate length of the gate electrode G1. More specifically, according to the first embodiment, it becomes less necessary to accurately align the bottom surface of the gate plug GPLG1 with the upper surface of the gate electrode G1. In the first place, since the gate plug GPLG1 is formed to have the diameter larger than the gate electrode G1 in the first embodiment, the bottom surface of the gate plug GPLG1 reaches not only the upper surface of the gate electrode G1 but also the element isolation region STI. Accordingly, it is less necessary from the beginning to accurately align the bottom surface of the gate plug GPLG1 with the upper surface of the gate electrode G1 in the first embodiment. For example, even if some positional displacement of the forming position of the gate plug GPLG1 occurs due to the misalignment, the connection failure does not occur when the gate plug GPLG1 contacts the gate electrode G1 at the upper surface and the side surface of the gate electrode G1. In other words, according to the first characteristic point of the first embodiment, the occurrence of the connection failure between the gate electrode G1 and the gate plug GPLG1 due to the misalignment can be reduced. According to the first embodiment, it is possible to take a sufficient margin for the misalignment, and the connection failure between the gate electrode G1 and the gate plug GPLG1 can be prevented even when the gate electrode G1 is miniaturized. Therefore, according to the first embodiment, the connection reliability between the gate electrode G1 and the gate plug GPLG1 can be improved.

Subsequently, the second characteristic point of the first embodiment will be described. The second characteristic point of the first embodiment is that a concave portion CP1 is formed in the side surface of the metal film MF2 constituting the gate electrode G1 and a conductive material is embedded in the concave portion CP1 to be a part of the gate plug GPLG1. By forming the concave portion CP1 in the side surface of the metal film MF2 as described above, the contact area between the gate electrode G1 and the gate plug GPLG1 can be further increased. For example, according to the above-described first characteristic point, the gate plug GPLG1 contacts the gate electrode G1 at the upper surface of the gate electrode G1 and the side surface of the gate electrode G1. At this time, with regard to the relation to the side surface of the gate electrode G1, the gate electrode G1 contacts the gate plug GPLG1 at the side surface of the nickel platinum silicide film CS, the side surface of the polysilicon film PF1 and the side surface of the metal film MF2.

On the other hand, in the semiconductor device having not only the first characteristic point but also the second characteristic point, the area of the side surface of the gate electrode G1 connected to the gate plug GPLG1 can be further increased. More specifically, in addition to the side surface of the nickel platinum silicide film CS, the side surface of the polysilicon film PF1 and the side surface of the metal film MF2, a part of the bottom surface of the polysilicon film PF1 exposed from the concave portion CP1 is connected to the gate plug GPLG1. In other words, by forming the concave portion CP1 in the side surface of the metal film MF2, a part of the bottom surface of the polysilicon film PF1 can be exposed from the concave portion CP1. As a result, by embedding a conductive material in the concave portion CP1 formed in the side surface of the metal film MF2, the contact area to the gate plug GPLG1 is increased. Note that, for example, the titanium film TI and the titanium nitride film TIN constituting the gate plug GPLG1 can be embedded in the concave portion CP1 formed in the side surface of the metal film MF2.

In the first embodiment, by providing both the first characteristic point and the second characteristic point, the contact area between the gate electrode G1 and the gate plug GPLG1 can be increased, and the gate resistance (parasitic resistance) can be further reduced. Furthermore, by forming the concave portion CP1 in the side surface of the gate electrode G1, the connection reliability between the gate electrode G1 and the gate plug GPLG1 is also improved. As described above, according to the first embodiment, by the first characteristic point that the gate contact hole GCNT1 is formed to have the opening diameter larger than the gate length of the gate electrode G1 and the second characteristic point that the concave portion CP1 is formed in the side surface of the metal film MF2 constituting the gate electrode G1, the further reduction of the gate resistance (parasitic resistance) and the improvement of the connection reliability between the gate electrode G1 and the gate plug GPLG1 can be achieved.

Here, the concave portion CP1 is formed in the side surface of the metal film MF2 constituting the gate electrode G1 in the first embodiment, and the electrical properties of, for example, the transfer MISFET Qt1 are not affected even when the concave portion CP1 is formed. This will be described below.

For example, in the left view of FIG. 4, the metal film MF2 of the transfer MISFET Qt1 is directly formed on the gate insulating film GOX1. Since the threshold voltage of the gate electrode G1 is determined by the work function of the metal film MF2, the role of the metal film MF2 is important. Here, in the first embodiment, the concave portion CP1 is formed in the side surface of the metal film MF2 as shown in the right view of FIG. 4. Therefore, it is concerned that the threshold voltage of the gate electrode G1 is changed when the concave portion CP1 is formed in the side surface of the metal film MF2 which determines the threshold voltage.

However, the threshold voltage of the gate electrode G1 is not changed even when the concave portion CP1 is formed in the metal film MF2. The reason therefor will be described below.

For example, as shown in FIG. 3, the position at which the gate electrode G1 and the gate plug GPLG1 are connected and the position at which the transfer MISFET Qt1 having the gate electrode G1 is actually formed are different. In other words, as shown in FIG. 3, the gate electrode G1 extends from the active region An1 to above the element isolation region STI. Therefore, the transfer MISFET Qt1 is formed in the region in which the gate electrode G1 and the active region An1 intersect in a grade-separated manner, and the gate electrode G1 and the gate plug GPLG1 are connected in the region in which the gate electrode G1 extends above the element isolation region STI. Therefore, since the forming position of the gate plug GPLG1 is not on the active region An1 but on the element isolation region STI, the forming position of the gate plug GPLG1 and the forming position of the transfer MISFET Qt1 are separated from each other. Accordingly, the structure shown in the right view of FIG. 4 is formed on the element isolation region STI in which the gate plug GPLG1 is formed. That is, only in the connection region of the gate electrode G1 and the gate plug GPLG1 formed on the element isolation region STI, the concave portion CP1 is formed in the side surface of the metal film FM2. In other words, as shown in the left view of FIG. 4, with regard to the gate electrode G1 formed on the active region An1, the concave portion CP1 is not formed in the metal film MF2 formed on the gate insulating film GOX1. Therefore, in the transfer MISFET Qt1 and others, the threshold voltage can be adjusted by the work function of the metal film MF2 without any problem.

The semiconductor device according to the first embodiment has the structure as described above, and the manufacturing method thereof will be described below with reference to the drawings. In the drawings used in the following description, the region taken along the line A-A in FIG. 3 (n channel MISFET forming region) is shown on the left side, and the gate contact region taken along the line B-B in FIG. 3 is shown on the right side.

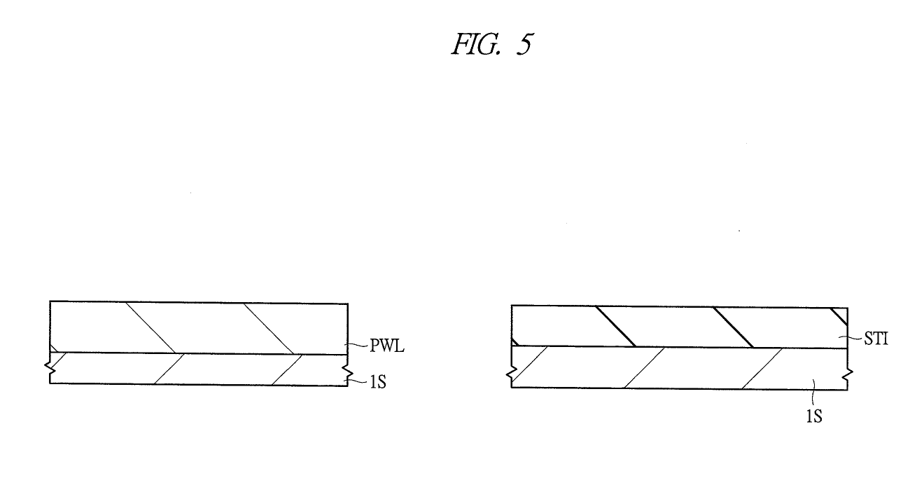

First, the semiconductor substrate 1S made of single crystal silicon to which a p type impurity such as boron (B) is implanted is prepared as shown in FIG. 5. At this time, the semiconductor substrate 1S is in a state of a semiconductor wafer in an almost disc shape. Then, the element isolation regions STI for isolating the elements are formed in the semiconductor substrate 1S. The element isolation regions STI are formed to prevent the mutual interference between the elements. The element isolation regions STI can be formed by using, for example, the LOCOS (Local Oxidation of Silicon) method or the STI (Shallow Trench Isolation) method. For example, in the STI method, the element isolation regions STI are formed in the following manner. That is, element isolation trenches are formed in the semiconductor substrate 1S by using the photolithography technology and the etching technology. Then, a silicon oxide film is formed on the semiconductor substrate so as to fill the element isolation trenches, and thereafter, the unnecessary silicon oxide film formed on the semiconductor substrate is removed by the chemical mechanical polishing (CMP). In this manner, the element isolation regions STI in which the silicon oxide film is embedded only in the element isolation trenches can be formed.

Next, an impurity is implanted into an active region isolated by the element isolation regions STI, thereby forming a p type well PWL. The p type well PWL is formed by implanting a p type impurity such as boron into the semiconductor substrate 1S by the ion implantation method.

Subsequently, a semiconductor region (not shown) for forming a channel is formed in a surface region of the p type well PWL. The semiconductor region for forming a channel is formed to adjust the threshold voltage for forming the channel.

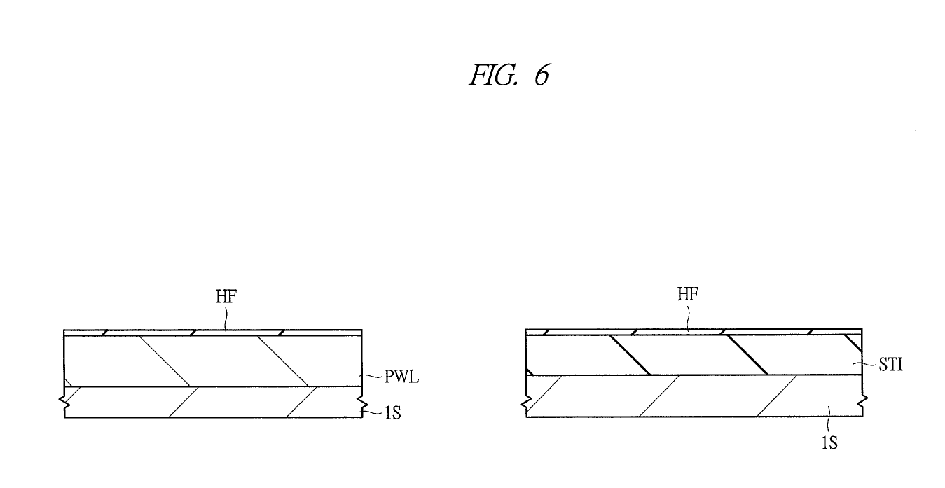

Subsequently, as shown in FIG. 6, a hafnium oxide film HF is formed on the semiconductor substrate 1S (p type well PWL and element isolation region STI). The hafnium oxide film HF can be formed by using, for example, the chemical vapor deposition (CVD) method or the atomic layer deposition (ALD) method.

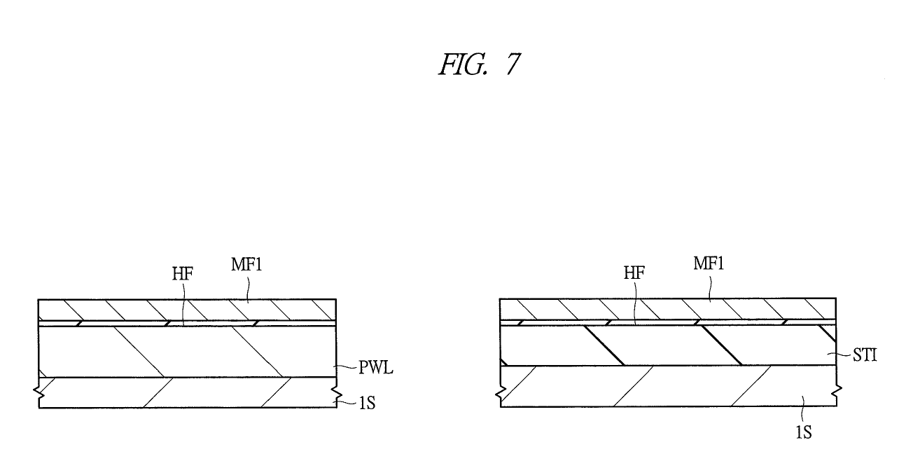

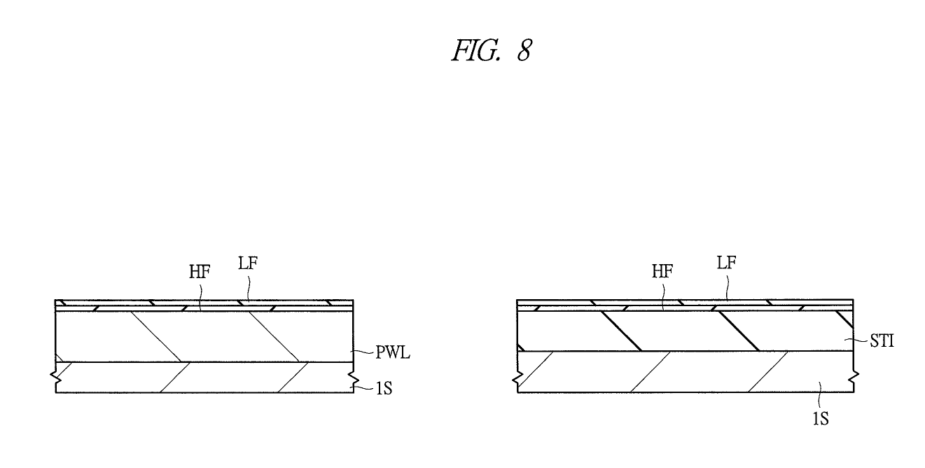

Then, as shown in FIG. 7, a metal film MF1 is formed on the hafnium oxide film HF. In other words, the metal film MF1 is formed on the whole surface of the semiconductor substrate 1S. Thereafter, the metal film MF1 is patterned by using the photolithography technology and the etching technology. The patterning of the metal film MF1 is performed so that the metal film MF1 is left in the p channel MISFET forming region (not shown) and the metal film MF1 is removed in the other region. Therefore, the metal film MF1 is removed in FIG. 8 showing the n channel MISFET forming region and the gate contact region.

Next, as shown in FIG. 8, a lanthanum oxide film LF is formed on the hafnium oxide film HF exposed by removing the metal film MF1. The lanthanum oxide film LF can be formed by using, for example, the CVD method or the ALD method.

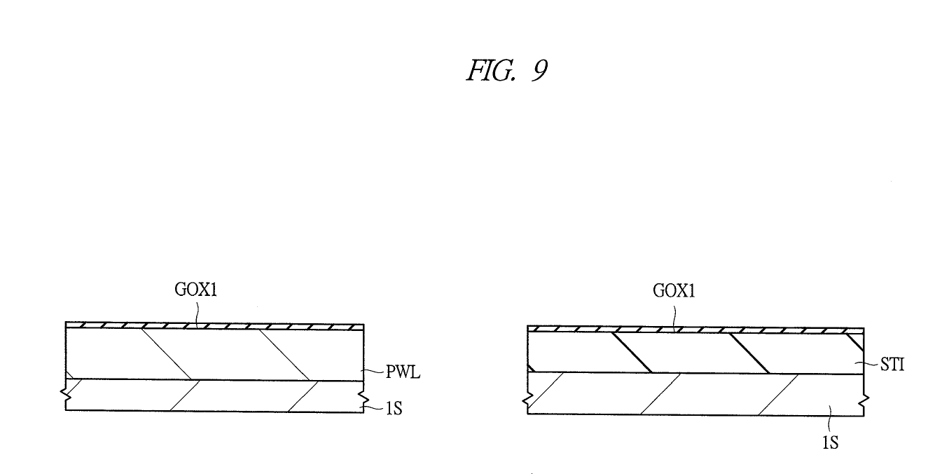

Then, as shown in FIG. 9, the heat treatment is performed to implant lanthanum oxide into the hafnium oxide film HF, thereby forming the gate insulating film GOX1 formed of the hafnium oxide film containing lanthanum oxide. The gate insulating film GOX1 is a high dielectric constant film with a dielectric constant higher than that of a silicon oxide film because it is formed of a hafnium oxide film to which lanthanum oxide is implanted.

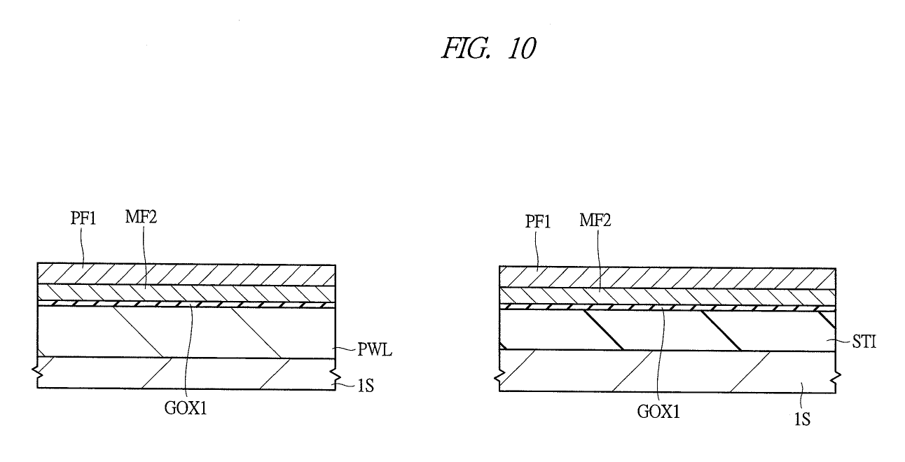

Subsequently, as shown in FIG. 10, the metal film MF2 is formed on the gate insulating film GOX1, and the polysilicon film PF1 is formed on the metal film MF2. The metal film MF2 is made of metal or metal compound and is formed of, for example, a titanium nitride film. The titanium nitride film can be formed by using, for example, the sputtering method. Also, the polysilicon film PF1 can be formed by using, for example, the CVD method.

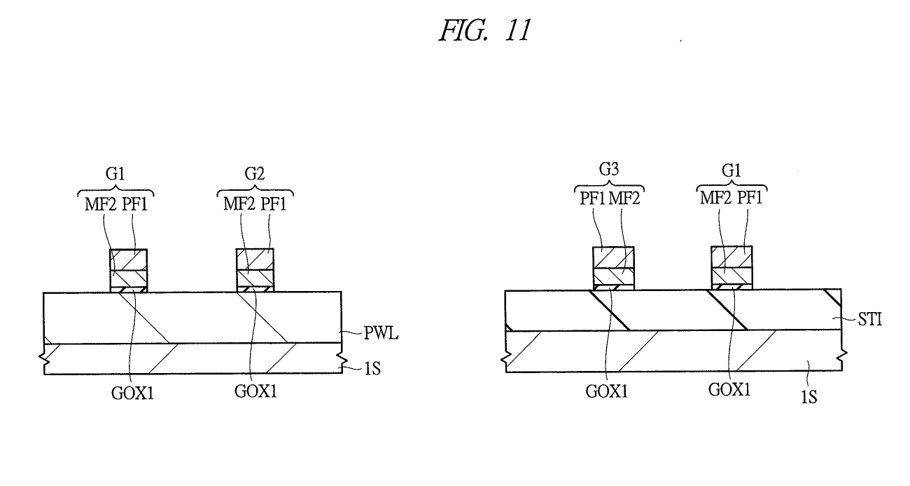

Next, as shown in FIG. 11, the polysilicon film PF1 and the metal film MF2 are patterned by using the photolithography technology and the etching technology. The patterning of the polysilicon film PF1 and the metal film MF2 is performed so that the polysilicon film PF1 and the metal film MF2 are left only in a gate electrode forming region. In this manner, the gate electrodes G1 to G3 made up of the stacked film of the metal film MF2 and the polysilicon film PF1 are formed. When processing the gate electrodes G1 to G3, the polysilicon film PF1 whose processing is easy is first processed and the metal film MF2 whose processing is relatively difficult is then processed. First, by processing the polysilicon film PF1, the profile (outline) of the gate electrodes G1 to G3 is determined, and thereafter, the metal film MF2 is processed, thereby completing the gate electrodes G1 to G3. Therefore, even when the gate electrodes G1 to G3 are miniaturized, the gate electrodes G1 to G3 can be formed in good shape. In other words, according to the first embodiment, the processing accuracy of the gate electrodes G1 to G3 can be improved compared with the case where the gate electrodes G1 to G3 are formed by processing the single film of the metal film MF2 whose processing is difficult.

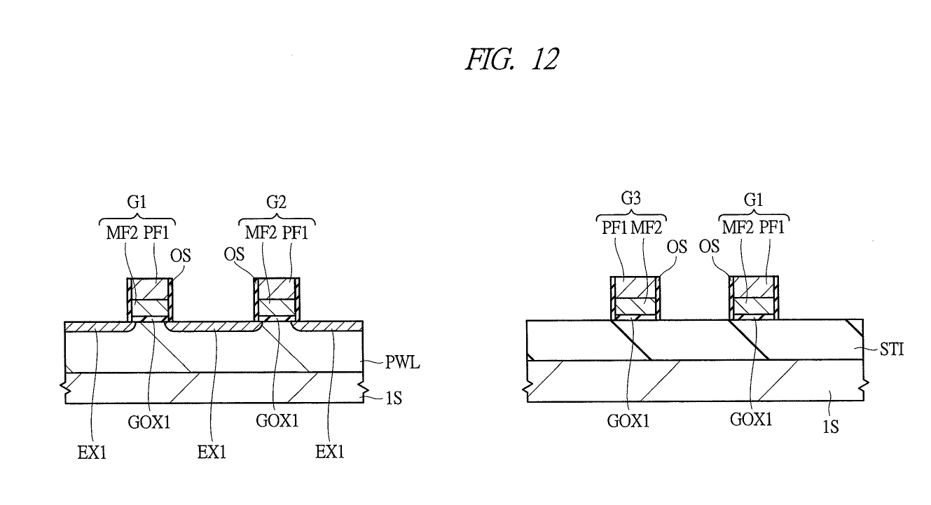

Subsequently, as shown in FIG. 12, a silicon oxide film is formed on the semiconductor substrate 1S on which the gate electrodes G1 to G3 have been formed, and the anisotropic etching is performed to the silicon oxide film. By this means, the offset spacers OS are formed on both sidewalls of the gate electrodes G1 to G3. The offset spacers OS are formed for adjusting the implantation of an impurity into the regions reaching the edges of the channel regions from the edges of the gate electrodes G1 and G2 when the shallow n type impurity diffusion regions EX1 aligned with the gate electrodes G1 and G2 are formed as described later.

After forming the offset spacers OS, the shallow n type impurity diffusion regions EX1 aligned with the gate electrodes G1 and G2 are formed by using the photolithography technology and the ion implantation method. The shallow n type impurity diffusion region EX1 is a semiconductor region and an n type impurity such as phosphorus or arsenic is implanted thereto.

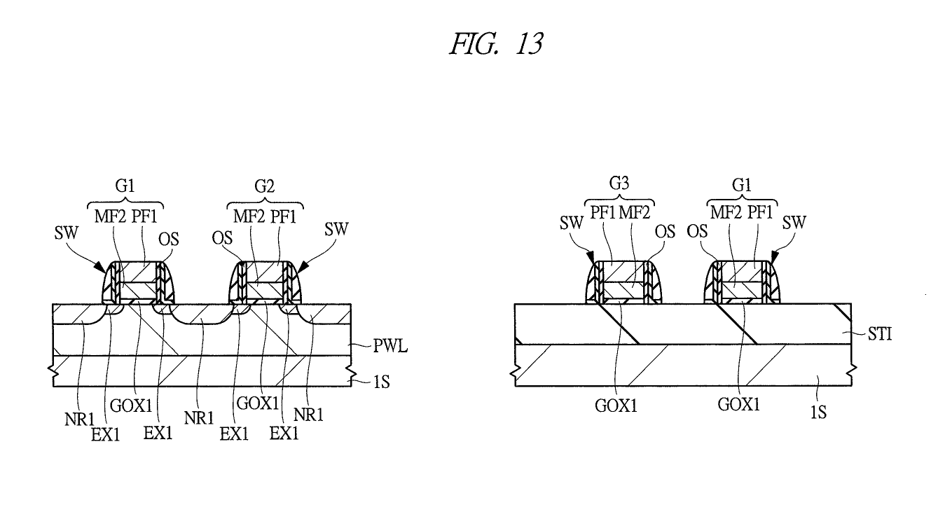

Next, as shown in FIG. 13, a staked film of a silicon oxide film and a silicon nitride film is formed on the semiconductor substrate 1S. The silicon oxide film and the silicon nitride film can be formed by using, for example, the CVD method. Then, by performing the anisotropic etching to the silicon oxide film and the silicon nitride film, the sidewalls SW are formed on the sidewalls of the gate electrodes G1 to G3. The sidewall SW is formed of a stacked film of a silicon oxide film and a silicon nitride film, but the sidewall SW is not limited to this and it may be formed of a single film of a silicon nitride film or a single film of a silicon oxide film.

Thereafter, the deep n type impurity diffusion regions NR1 aligned with the sidewalls SW are formed by using the photolithography technology and the ion implantation method. The deep n type impurity diffusion region NR1 is a semiconductor region to which an n type impurity such as phosphorus or arsenic is implanted. The deep n type impurity diffusion region NR1 and the shallow n type impurity diffusion region EX1 constitute the source region. Similarly, the deep n type impurity diffusion region NR1 and the shallow n type impurity diffusion region EX1 constitute the drain region. By forming the source region and the drain region from the shallow n type impurity diffusion regions EX1 and the deep n type impurity diffusion regions NR1 as described above, the source region and the drain region can have the LDD (Lightly Doped Drain) structure.

After forming the deep n type impurity diffusion regions NR1 in the above-described manner, the heat treatment at about 1000° C. is performed. By this means, the activation of the implanted impurity is carried out.

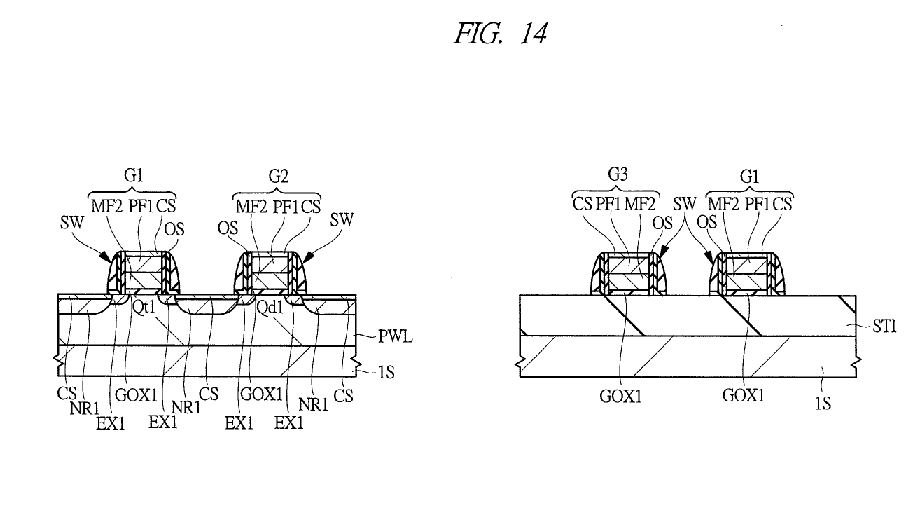

Thereafter, as shown in FIG. 14, a nickel platinum film is formed on the semiconductor substrate 1S. At this time, the nickel platinum film is formed so as to directly contact the gate electrodes G1 to G3. Similarly, the nickel platinum film directly contacts the deep n type impurity diffusion region NR1.

The nickel platinum film can be formed by using, for example, the sputtering method. Then, by performing the heat treatment after forming the nickel platinum film, the polysilicon film PF1 constituting the gate electrodes G1 to G3 and the nickel platinum film are reacted, thereby forming the nickel platinum silicide film CS. In this manner, the gate electrodes G1 to G3 have the stacked structure of the metal film MF2, the polysilicon film PF1 and the nickel platinum silicide film CS. The nickel platinum silicide film CS is formed for reducing the resistance of the gate electrodes G1 to G3. Similarly, the silicon and the nickel platinum film are reacted also on the surface of the deep n type impurity diffusion region NR1 by the above-described heat treatment, thereby forming the nickel platinum silicide film CS. Therefore, the resistance reduction can be achieved also in the deep n type impurity diffusion region NR1.

Then, the unreacted nickel platinum film is removed from the semiconductor substrate 1S. Note that, in the structure of the first embodiment, the nickel platinum silicide film CS is formed, but a nickel silicide film, a titanium silicide film, a cobalt silicide film or a platinum silicide film may be formed instead of the nickel platinum silicide film CS. In the above-described manner, the transfer MISFET Qt1 and the drive MISFET Qd1 can be formed on the semiconductor substrate 1S. Furthermore, the gate contact region can be formed by extending the gate electrode G1 and the gate electrode G3 to above the element isolation region STI.

Subsequently, as shown in FIG. 15, the silicon nitride film SN1 is formed on the semiconductor substrate 1S on which the gate electrodes G1 to G3 have been formed. The silicon nitride film SN1 is a film functioning as an etching stopper when contact holes are formed in the subsequent process. The silicon nitride film SN1 can be formed by using, for example, the CVD method.

Then, the contact interlayer insulating film CIL is formed on the silicon nitride film SN1. The contact interlayer insulating film CIL is formed so as to cover the gate electrodes G1 to G3 via the silicon nitride film SN1. More specifically, the contact interlayer insulating film CIL is formed of a stacked film of an ozone TEOS film formed by the thermal CVD method using ozone and TEOS as materials and a plasma TEOS film formed by the plasma CVD method using TEOS as a material.

The reason for forming the contact interlayer insulating film CIL from a TEOS film is that the TEOS film has a good coatability to the unevenness of the underlying structure. The underlying structure on which the contact interlayer insulating film CIL is to be formed is in an uneven state having the gate electrodes G1 to G3 formed on the semiconductor substrate 1S. In other words, since the gate electrodes G1 to G3 are formed on the semiconductor substrate 1S, the semiconductor substrate 1S has an uneven surface. Therefore, the minute unevennesses cannot be filled unless the film with a good coatability to the unevenness is used, and it causes the occurrence of voids and others. Therefore, the TEOS film is used for the contact interlayer insulating film CIL. This is because, in the case of the TEOS film made of TEOS, the TEOS as a material forms an intermediate before being a silicon oxide film and easily moves on a film surface and the coatability to the underlying structure is improved.

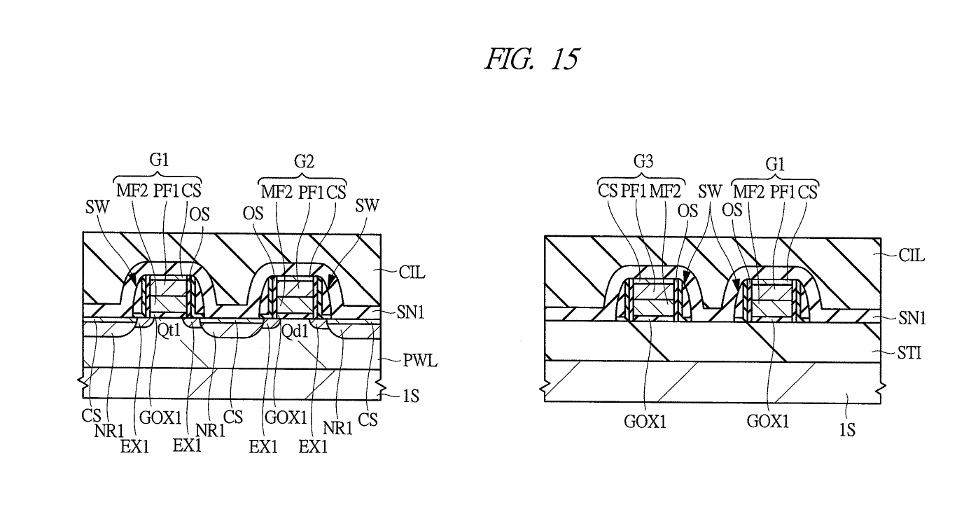

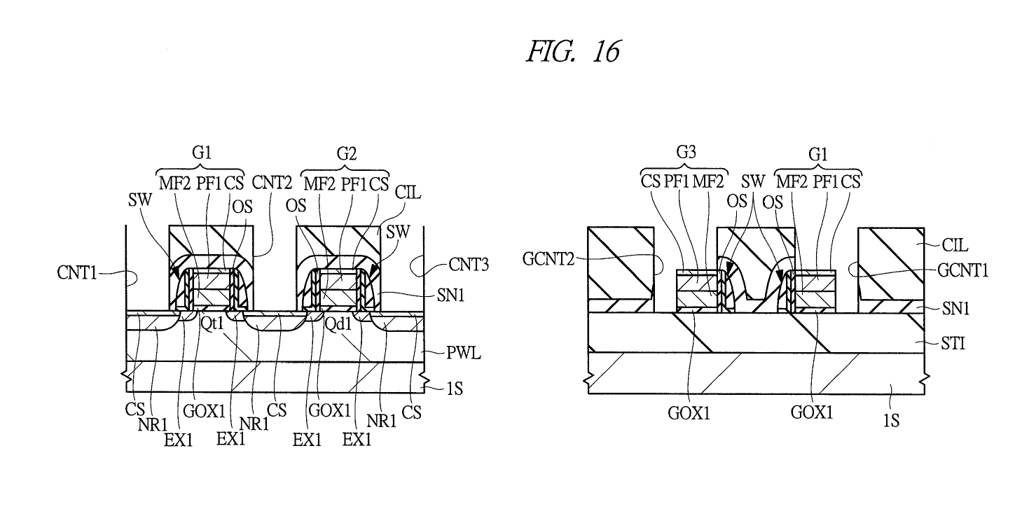

Next, as shown in FIG. 16, the contact holes CNT1 to CNT3 and the gate contact holes GCNT1 and GCNT2 are formed by using the photolithography technology and the etching technology. More specifically, the contact holes CNT1 to CNT3 are formed in the n channel MISFET forming region on the left side of FIG. 16, and the gate contact holes GCNT1 and GCNT2 are formed in the gate contact region on the right side of FIG. 16. The contact holes CNT1 to CNT3 and the gate contact holes GCNT1 and GCNT2 are formed in the same process.

At this time, the diameter of the gate contact hole GCNT1 is larger than the gate length of the gate electrode G1. Therefore, by forming the gate contact hole GCNT1, the upper surface and one side surface of the gate electrode G1 are exposed, and a part of the surface of the element isolation region STI is also exposed. Similarly, the diameter of the gate contact hole GCNT2 is larger than the gate length of the gate electrode G3. Therefore, by forming the gate contact hole GCNT2, the upper surface and one side surface of the gate electrode G3 are exposed, and a part of the surface of the element isolation region STI is also exposed.

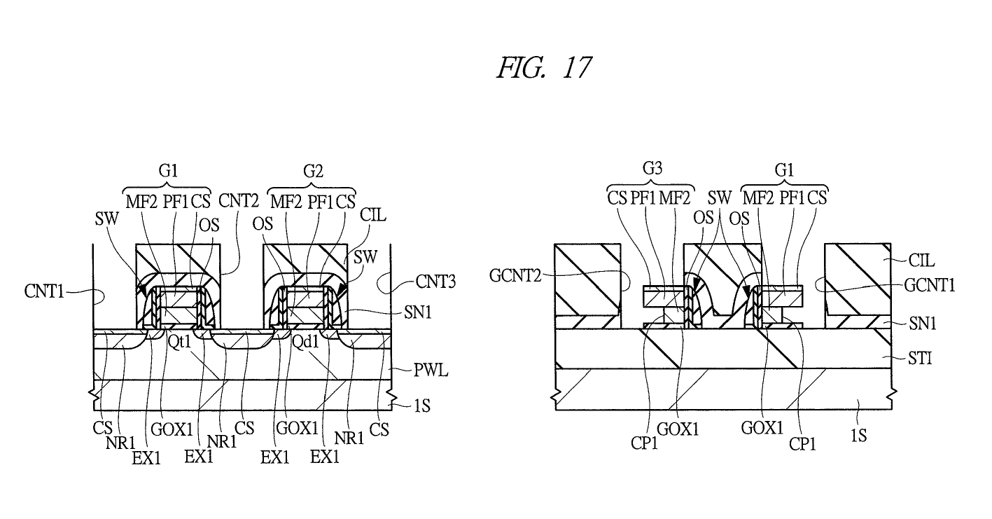

Subsequently, as shown in FIG. 17, the concave portion CP1 is formed in the side surface of the metal film MF2 exposed by forming the gate contact hole GCNT1. Similarly, the concave portion CP1 is formed in the side surface of the metal film MF2 exposed by forming the gate contact hole GCNT2. The following process is performed for forming the concave portion CP1 in the side surface of the metal film MF2. That is, the parts of the metal films MF2 are wet-etched from one side surfaces of the metal films MF2 exposed on the inner surfaces of the gate contact hole GCNT1 and the gate contact hole GCNT2, thereby forming the concave portions CP1 in the one side surfaces of the metal films MF2. More specifically, in this wet etching, the sulfuric acid treatment by sulfuric acid is performed to the inner surfaces of the gate contact hole GCNT1 and the gate contact hole GCNT2, and then, the hydrogen peroxide treatment by hydrogen peroxide is performed. At this time, by adjusting the process time for performing the wet etching, the depth of the concave portion CP1 formed in the side surface of the metal film MF2 can be adjusted. Thereafter, the APM cleaning is performed as a cleaning process. The APM cleaning is the cleaning process using mixture solution of ammonia and hydrogen peroxide.

When the sulfuric acid treatment and the hydrogen peroxide treatment are performed, only the metal films MF2 exposed on the inner surfaces of the gate contact hole GCNT1 and the gate contact hole GCNT2 are wet-etched, and the polysilicon film PF1 is not etched. Therefore, as shown in FIG. 17, the concave portions CP1 by the etching are formed only in the side surfaces of the exposed metal films MF2. Note that, although the sulfuric acid treatment and the hydrogen peroxide treatment are performed for the whole surface of the semiconductor substrate 1S, since the metal film MF2 is not exposed in the contact holes CNT1 to CNT3 formed in the n channel MISFET forming region, the metal film MF2 is not wet-etched in the n channel MISFET forming region.

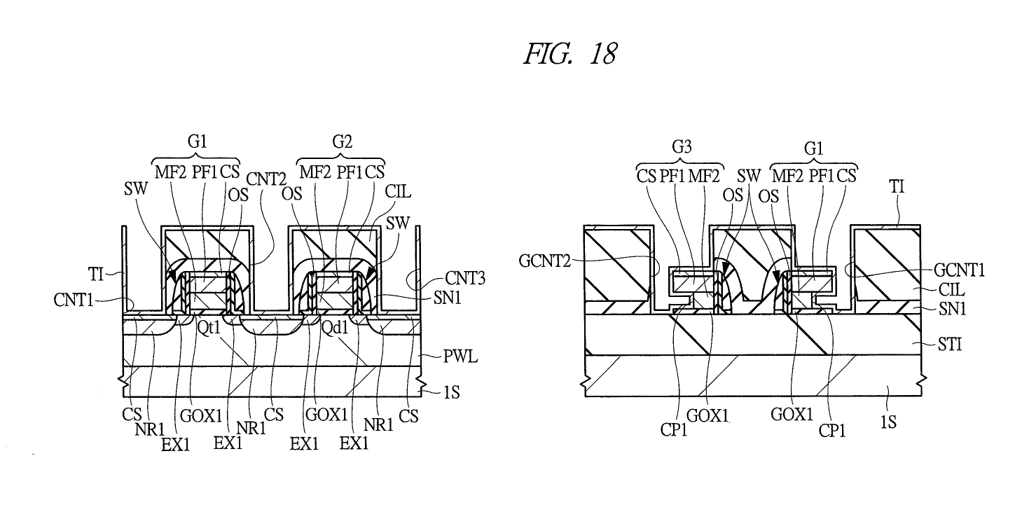

Thereafter, as shown in FIG. 18, the titanium film TI is formed on the contact interlayer insulating film CIL including the inside of the contact holes CNT1 to CNT3 and the gate contact holes GCNT1 and GCNT2. At this time, in the first embodiment, the titanium film TI is formed by the CVD method. The titanium film TI is usually formed by using the sputtering method. In the first embodiment, however, the titanium film TI has to be formed also on the surfaces of the concave portions CP1 formed in the gate contact holes GCNT1 and GCNT2. At this time, when the titanium film TI is formed by the sputtering method, it is difficult to make the titanium atoms reach the inside of the concave portions CP1 due to the geometric arrangement of the concave portions CP1. For its solution, the titanium film TI is formed by using the CVD method in the first embodiment. This is because, since the source gas can be supplied to the inside of the concave portions CP1 by the CVD method, the titanium film TI is produced by the chemical reaction in the concave portions CP1 and the conformal titanium film TI can be produced on the surfaces of the concave portions CP1.

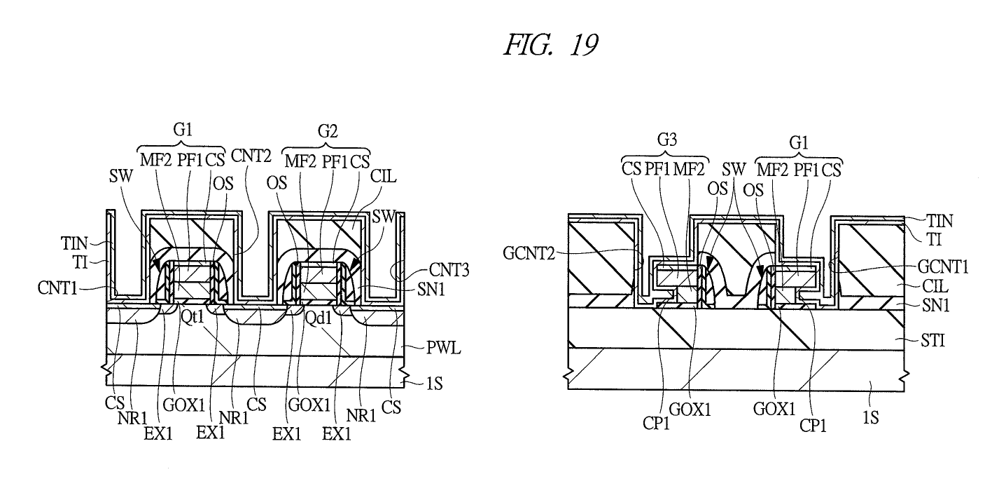

Next, as shown in FIG. 19, the titanium nitride film TIN is formed on the titanium film TI. The titanium nitride film TIN can be formed by, for example, the plasma nitridation treatment using ammonia gas to the surface of the titanium film TI. In this manner, the concave portions CP1 exposed from the gate contact holes GCNT1 and GCNT2 are filled with the titanium film TI and the titanium nitride film TIN. The titanium film TI and the titanium nitride film TIN are provided in order to prevent the diffusion of tungsten constituting the tungsten film described later into silicon.

Subsequently, as shown in FIG. 20, the tungsten film WF is formed on the titanium nitride film TIN. In this manner, the inside of the contact holes CNT1 to CNT3 and the inside of the gate contact holes GCNT1 and GCNT2 are filled with the titanium film TI, the titanium nitride film TIN and the tungsten film WF. The tungsten film WF can be formed by, for example, the CVD method. Usually, silane gas is used as a source gas in the CVD method for forming the tungsten film WF, but diborane (B₂H₆) gas is used instead of silane gas in the first embodiment. This is because the damage applied to the inner walls of the contact holes CNT1 to CNT3 and the inner walls of the gate contact holes GCNT1 and GCNT2 can be reduced by using the diborane gas. In particular, the concave portions CP1 are formed in the gate contact holes GCNT1 and GCNT2 in the first embodiment, and the damage applied to the concave portions CP1 can also be reduced by the CVD method using diborane as a source gas.

Note that the concave portions CP1 are filled with the titanium film TI and the titanium nitride film TIN in the first embodiment. This is because the embedding properties for the concave portions CP1 in the formation of the titanium nitride film TIN by the plasma nitridation treatment are better than the coverage properties by the CVD method when forming the tungsten film WF. That is, this is because the occurrence of the voids can be suppressed when the concave portions CP1 are filled with the titanium nitride film TIN formed by the plasma nitridation treatment with good embedding properties. In other words, this is because, when the tungsten film WF is embedded in the concave portions CP1, the voids are likely to occur due to the deterioration of the embedding properties, and there is a possibility that the reduction of the parasitic resistance and the improvement of the connection reliability achieved by providing the concave portions CP1 cannot be fully exerted.

Thereafter, as shown in FIG. 21, the unnecessary titanium film TI, titanium nitride film TIN and tungsten film WF formed on the contact interlayer insulating film CIL are removed by the CMP (Chemical Mechanical Polishing) method. In this manner, the plugs PLG1 to PLG3 and the gate plugs GPLG1 and GPLG2 in which the titanium film TI, the titanium nitride film TIN and the tungsten film WF are embedded only in the contact holes CNT1 to CNT3 and the gate contact holes GCNT1 and GCNT2 can be formed.

Next, as shown in FIG. 4, the plasma treatment is performed to the surface of the contact interlayer insulating film CIL in which the plugs PLG1 to PLG3 and the gate plugs GPLG1 and GPLG2 have been formed. More specifically, the semiconductor substrate 1S is carried in a chamber, and ammonia gas or mixed gas containing ammonia gas and nitrogen gas is introduced into the chamber. Thereafter, the temperature in the chamber is set at about 400° C. to convert the ammonia gas or the mixed gas introduced in the chamber into plasma. In this manner, the plasma treatment is performed to the surface of the contact interlayer insulating film CIL by the ammonia gas or the nitrogen gas converted into plasma.

Then, the barrier insulating film BIF is formed on the contact interlayer insulating film CIL by using, for example, the CVD method, and the interlayer insulating film IL1 is formed on the barrier insulating film BIF. The barrier insulating film BIF is formed of, for example, a film including any one of an SiN film (silicon nitride film), an SiON film (silicon oxynitride film), an SiC film (silicon carbide film), an SiCN film (silicon oxynitride film) and an SiCO film. Also, the interlayer insulating film IL1 is formed of a silicon oxide film or a low dielectric constant film with a dielectric constant lower than that of a silicon oxide film. More specifically, the interlayer insulating film IL1 is formed of, for example, an SiOC film, an HSQ (Hydrogen SilsesQuioxane, silicon oxide film formed by a coating process and having Si—H bonds, or hydrogen-containing silsesquioxane) film, an MSQ (Methyl SilsesQuioxane, silicon oxide film formed by a coating process and having Si—C bonds, or carbon-containing silsesquioxane) film, a TEOS film, a silicon oxide film or an SiOF film. At this time, since the plasma treatment by the ammonia gas has been performed to the surface of the contact interlayer insulating film CIL, the adhesion between the contact interlayer insulating film CIL and the barrier insulating film BIF is improved.

Then, wiring trenches penetrating through the interlayer insulating film IL1 and the barrier insulating film BIF are formed by using the photolithography technology and the etching technology. The wiring trenches are formed through the interlayer insulating film IL1 and the barrier insulating film BIF so that the bottom surfaces thereof reach the contact interlayer insulating film CIL. In this manner, the surfaces of the plugs PLG1 to PLG3 and the gate plugs GPLG1 and GPLG2 are exposed at the bottom of the wiring trenches.

Thereafter, the barrier conductive film BCF is formed on the interlayer insulating film IL1 in which the wiring trenches have been formed. More specifically, the barrier conductive film BCF is made of tantalum (Ta), titanium (Ti), ruthenium (Ru), tungsten (W), manganese (Mn), nitride or nitride silicide of these materials, or a stacked film of these materials, and it can be formed by using, for example, the sputtering method.

Subsequently, a seed film formed of, for example, a thin copper film is formed by the sputtering method on the barrier conductive film BCF formed inside the wiring trenches and on the interlayer insulating film IL1. Then, the copper film CF is formed by the electroplating method using the seed layer as an electrode. The copper film CF is formed so as to be embedded in the wiring trenches. The copper film CF is formed of, for example, a film mainly made of copper. More specifically, the copper film CF is made of copper (Cu) or copper alloy (alloy of copper (Cu) and aluminum (Al), magnesium (Mg), titanium (Ti), manganese (Mn), iron (Fe), zinc (Zn), zirconium (Zr), niobium (Nb), molybdenum (Mo), ruthenium (Ru), palladium (Pd), silver (Ag), gold (Au), indium (In), lanthanoid-based metal, actinoid-based metal or the like).

Next, the unnecessary barrier conductive film BCF and copper film CF formed on the interlayer insulating film IL1 are removed by the CMP method. In this manner, the wirings L1 in which the barrier conductive film BCF and the copper film CF are embedded in the wiring trenches can be formed. Furthermore, a multilayer wiring will be formed on the wiring L1, but the description thereof is omitted. In the manner as described above, the semiconductor device according to the first embodiment can be manufactured. Note that, although the connection structure between the gate electrode and the gate plug has been described with taking a MISFET constituting a memory cell of an SRAM as an example in the first embodiment, the connection structure between the gate electrode and the gate plug according to the first embodiment can be applied also to, for example, a MISFET constituting a logic circuit of a CPU.

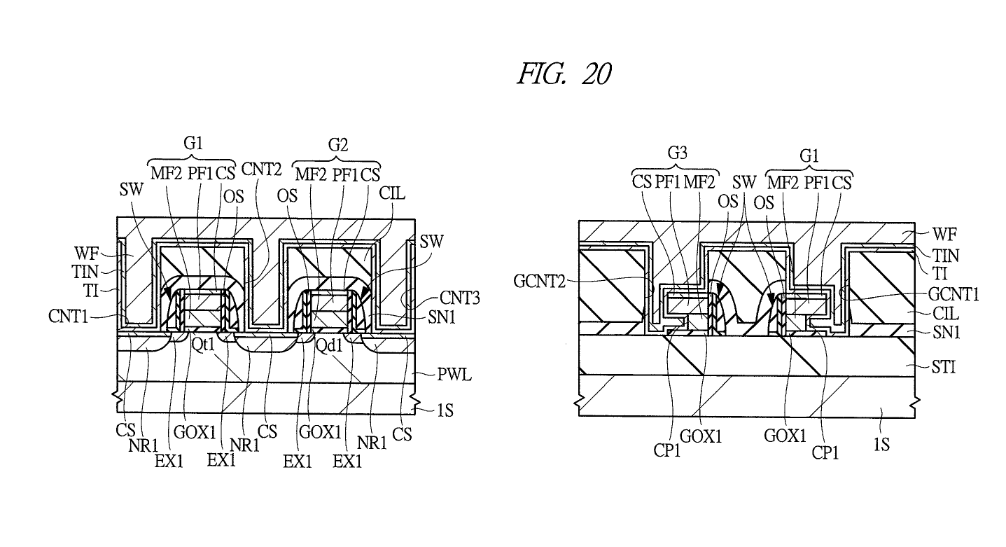

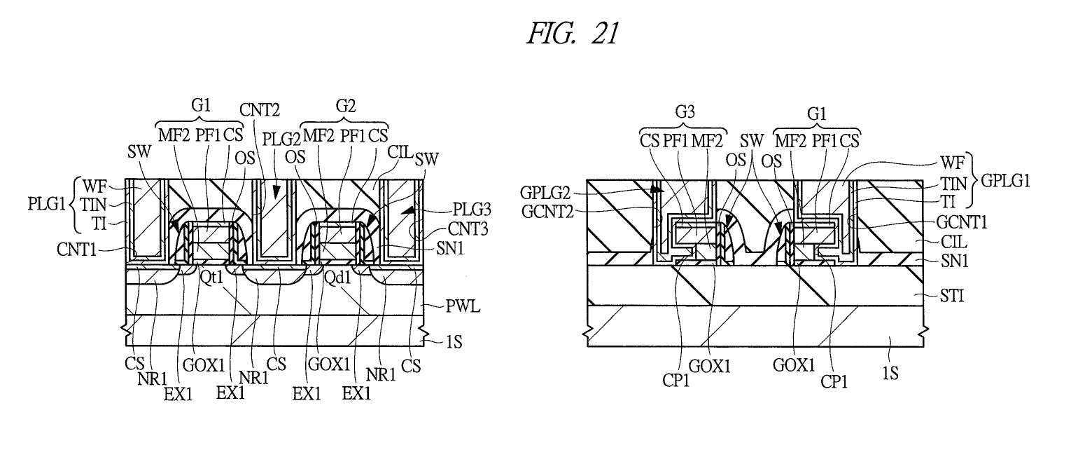

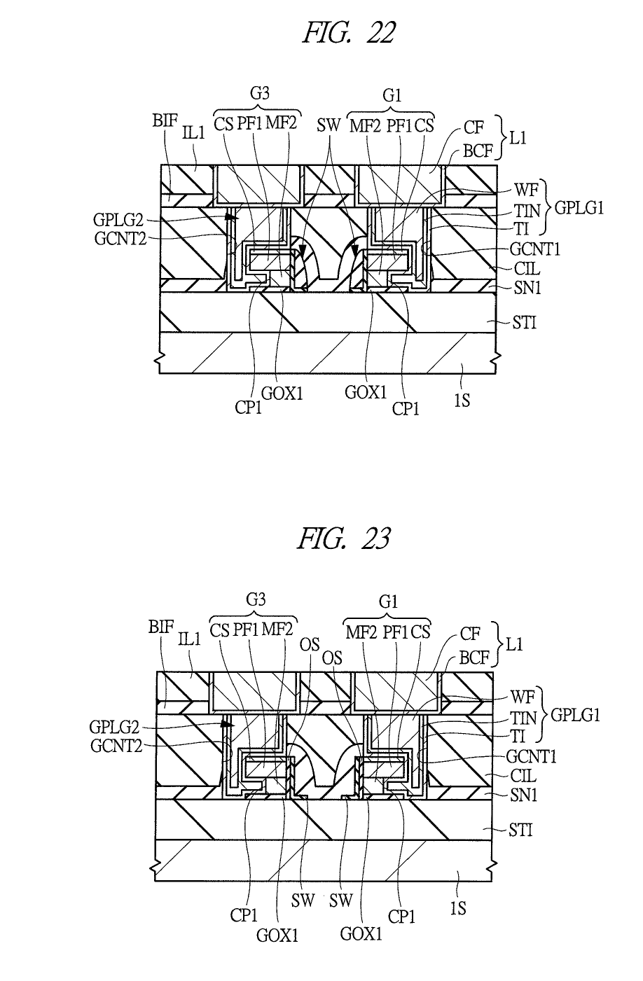

A modification example of the semiconductor device according to the first embodiment will be described below. FIG. 22 is a diagram showing a first modification example according to the first embodiment. FIG. 22 shows the gate contact region to connect a gate electrode and a gate plug. The structure shown in FIG. 22 has almost the same structure as the right view of FIG. 4 showing the gate contact region. In other words, the first modification example shown in FIG. 22 is also provided with the first characteristic point that the gate contact hole GCNT1 (gate contact hole GCNT2) is formed to have the opening diameter larger than the gate length of the gate electrode G1 (gate electrode G3) and the second characteristic point that the concave portion CP1 is formed in the side surface of the metal film MF2 constituting the gate electrode G1. Therefore, the reduction of the gate resistance (parasitic resistance) and the improvement of the connection reliability between the gate electrode G1 and the gate plug GPLG1 can be achieved.

The difference between FIG. 22 and FIG. 4 lies in that the offset spacers OS are not formed on the sidewalls of the gate electrode G1 (gate electrode G3) in FIG. 22. The offset spacers OS do not have to be formed on the sidewalls of the gate electrode G1 (gate electrode G3) in this way.

FIG. 23 is a diagram showing a second modification example according to the first embodiment. FIG. 23 shows the gate contact region to connect a gate electrode and a gate plug. The structure shown in FIG. 23 has almost the same structure as the right view of FIG. 4 showing the gate contact region. In other words, the second modification example shown in FIG. 23 is also provided with the first characteristic point that the gate contact hole GCNT1 (gate contact hole GCNT2) is formed to have the opening diameter larger than the gate length of the gate electrode G1 (gate electrode G3) and the second characteristic point that the concave portion CP1 is formed in the side surface of the metal film MF2 constituting the gate electrode G1. Therefore, the reduction of the gate resistance (parasitic resistance) and the improvement of the connection reliability between the gate electrode G1 and the gate plug GPLG1 can be achieved.

The difference between FIG. 23 and FIG. 4 lies in the structure of the sidewalls SW formed on the sidewalls of the gate electrode G1 (gate electrode G3). More specifically, the sidewall SW formed of a silicon oxide film and a silicon nitride film is formed in FIG. 4, but a silicon nitride film is removed by, for example, thermal phosphoric acid and the sidewall SW formed of only a silicon oxide film is formed in FIG. 23. The sidewall SW like this is called a disposable sidewall. The disposable sidewall may be used as the sidewall SW in this way.

### Second Embodiment

In the first embodiment, the structure of an n channel MISFET out of the MISFETs constituting a memory cell of an SRAM has been described, and furthermore, the characteristic connection structure between a gate electrode of the n channel MISFET and a gate plug has been described. In the second embodiment, the structure of a p channel MISFET out of the MISFETs constituting a memory cell of an SRAM will be described, and furthermore, the characteristic structure of a shared plug will be described. In the second embodiment, a cross-sectional view taken along the line C-C in FIG. 3 is used.

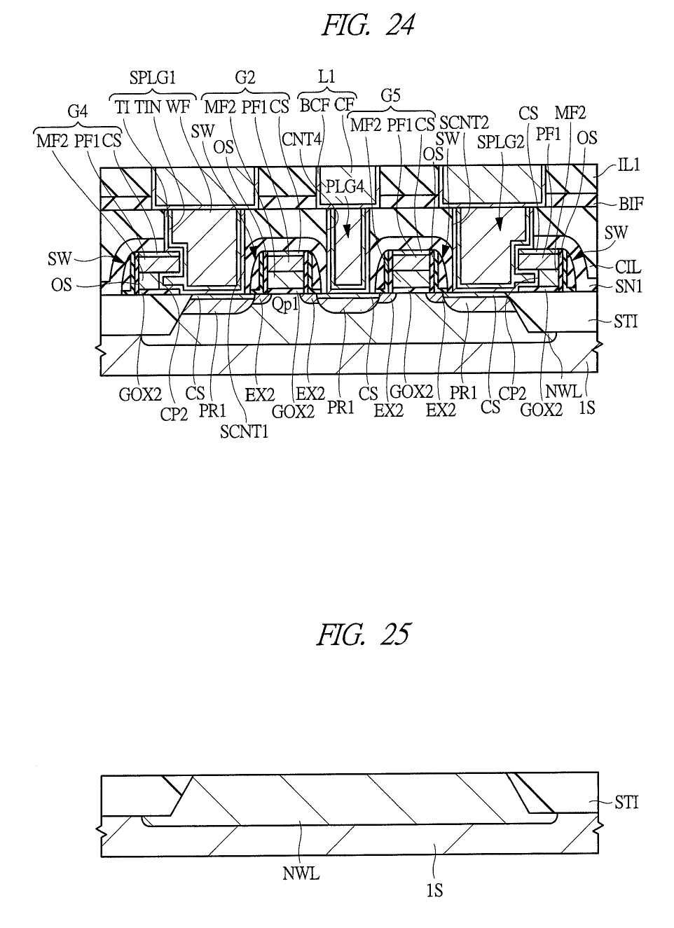

FIG. 24 is a cross-sectional view taken along the line C-C in FIG. 3. FIG. 24 shows the load MISFET Qp1 which is a p channel MISFET and the shared plugs SPLG1 and SPLG2.

First, the structure of the load MISFET Qp1 will be described. As shown in FIG. 24, the element isolation regions STI are formed in the semiconductor substrate 1S, and an n type well NWL is formed in the active region defined by the element isolation regions STI. The n type well NWL is a semiconductor region to which an n type impurity such as phosphorus or arsenic is implanted, and the load MISFET Qp1 is formed on the n type well NWL. More specifically, the gate insulating film GOX2 is formed on the n type well NWL, and the gate electrode G2 (gate electrode G5) is formed on the gate insulating film GOX2.

The gate insulating film GOX2 is formed of a high dielectric constant film with a dielectric constant higher than that of a silicon oxide film, and it is formed of, for example, a hafnium-based insulating film obtained by implanting aluminum oxide into hafnium oxide. The gate electrode G2 (gate electrode G5) is made up of the metal film MF2 formed to be in direct contact with the gate insulating film GOX2, the polysilicon film PF1 formed on the metal film MF2 and the nickel platinum silicide film CS formed on a surface of the polysilicon film PF1. The metal film MF2 is formed of, for example, a titanium nitride film. Also, the nickel platinum silicide film CS is formed on the surface of the polysilicon film PF1 in order to reduce the resistance of the gate electrode G2 (gate electrode G5) in the second embodiment, but a nickel silicide film, a titanium silicide film, a cobalt silicide film or a platinum silicide film may be formed instead of the nickel platinum silicide film CS.

Subsequently, on both sidewalls of the gate electrode G2 (gate electrode G5), offset spacers OS formed of, for example, a silicon oxide film are formed. Furthermore, the sidewall SW is formed outside the offset spacer OS, and the sidewall SW is formed of, for example, a stacked film of a silicon oxide film and a silicon nitride film. However, the structure of the sidewall SW is not limited to this, and the sidewall SW can be formed of a single film of a silicon oxide film or a single film of a silicon nitride film.

In the semiconductor substrate 1S below the sidewall SW, a shallow p type impurity diffusion region EX2 is formed as a semiconductor region. Also, a deep p type impurity diffusion region PR1 is formed outside the shallow p type impurity diffusion region EX2, and the nickel platinum silicide film CS is formed on a surface of the deep p type impurity diffusion region PR1.

The sidewall SW is formed so that the source region and the drain region which are the semiconductor regions of the load MISFET Qp1 have the LDD structure. More specifically, each of the source region and the drain region of the load MISFET Qp1 is made up of the shallow p type impurity diffusion region EX2, the deep p type impurity diffusion region PR1 and the nickel platinum silicide film CS. At this time, an impurity concentration of the shallow p type impurity diffusion region EX2 is lower than that of the deep p type impurity diffusion region PR1. Therefore, by forming the shallow p type impurity diffusion regions EX2 with a low impurity concentration for the source region and the drain region below the sidewalls SW, the field concentration below an edge of the gate electrode G2 (gate electrode G5) can be suppressed. The load MISFET Qp1 is formed on the semiconductor substrate 1S in the manner described above.

Subsequently, a multilayer wiring is formed above the semiconductor substrate 1S on which the load MISFET Qp1 has been formed. The structure of the multilayer wiring will be described below. As shown in FIG. 24, on the semiconductor substrate 1S on which the load MISFET Qp1 has been formed, a silicon nitride film SN1 is formed so as to cover the load MISFET Qp1, and a contact interlayer insulating film CIL is formed on the silicon nitride film SN1. The contact interlayer insulating film CIL is formed of, for example, a stacked film of an ozone TEOS film formed by the thermal CVD method using ozone and TEOS (Tetra Ethyl Ortho Silicate) as materials and a plasma TEOS film formed by the plasma CVD method using TEOS as a material provided on the ozone TEOS film. Then, a plug PLG4 which reaches the source region of the load MISFET Qp1 is formed through the contact interlayer insulating film CIL. The plug PLG4 is formed by embedding a titanium film TI, a titanium nitride film TIN formed on the titanium film TI and a tungsten film WF formed on the titanium nitride film TIN into a contact hole CNT4. The titanium film TI and the titanium nitride film TIN are provided in order to prevent the diffusion of the tungsten constituting the tungsten film WF into silicon. Note that the contact interlayer insulating film CIL may be formed of either of a silicon oxide film (SiO₂ film) and an SiOF film.

Subsequently, a wiring L1 is formed as a first wiring layer on the contact interlayer insulating film CIL. More specifically, the wiring L1 is formed so as to be embedded in a barrier insulating film BIF and an interlayer insulating film IL1 formed on the contact interlayer insulating film CIL in which the plug PLG4 has been formed. In other words, the wiring L1 is formed by embedding a barrier conductive film BCF and a film mainly made of copper (hereinafter, referred to as a copper film CF) into a wiring trench which penetrates through the barrier insulating film BIF and the interlayer insulating film IL1 and in which the plug PLG4 is exposed at the bottom. In other words, the wiring L1 is formed of the barrier conductive film BCF formed so as to cover a side surface and a bottom surface of the wiring trench and the copper film CF formed on the barrier conductive film BCF so as to fill the wiring trench. Furthermore, a multilayer wiring will be formed on the wiring L1, but the description thereof is omitted in the second embodiment. In the manner described above, the load MISFET Qp1 is formed on the semiconductor substrate 1S, and the wiring L1 is formed on the load MISFET Qp1.

Here, the gate insulating film GOX1 is formed of a hafnium oxide film to which lanthanum oxide is added in the first embodiment described above, but the gate insulating film GOX2 is formed of a hafnium oxide film to which aluminum oxide is added in the second embodiment. In this manner, different films are used for the gate insulating film of the n channel MISFET in the first embodiment and the gate insulating film of the p channel MISFET in the second embodiment. The reason therefor will be described below.

When a metal film (including a metal compound film) is used to form the gate electrode, the work function value for reducing the threshold voltage differs in the n channel MISFET and the p channel MISFET. Therefore, it is conceivable that different metal films are used for the n channel MISFET and the p channel MISFET. However, it is necessary to ensure the vertical processability of the gate electrodes for different types of metal films at a time. In other words, when different metal films are used for the n channel MISFET and the p channel MISFET, the vertical processability has to be ensured for both the different metal films. For this reason, the gate electrode of the n channel MISFET in the first embodiment described above and the gate electrode of the p channel MISFET described in the second embodiment are made up of a stacked film (titanium nitride film and tungsten film) with the same composition. In this case, it is impossible to optimally adjust the threshold voltage of the n channel MISFET and the threshold voltage of the p channel MISFET at the same time. Therefore, the gate electrode G1 of the n channel MISFET described in the first embodiment and the gate electrode of the p channel MISFET described in the second embodiment are formed to have the same composition, and at the same time, the gate insulating film GOX1 and the gate insulating film GOX2 are formed to have different compositions. In other words, by using the films of different compositions for the gate insulating film GOX1 of the n channel MISFET and the gate insulating film GOX2 of the p channel MISFET, both the threshold voltage of the n channel MISFET and the threshold voltage of the p channel MISFET can be reduced. For this reason, a high dielectric constant film with a dielectric constant higher than that of a silicon oxide film is used for the gate insulating film GOX1 and the gate insulating film GOX2, and the gate insulating film GOX1 and the gate insulating film GOX2 are formed to have different compositions.

Subsequently, the structure of the shared plug which is a characteristic structure of the second embodiment will be described. Although FIG. 24 shows the shared plug SPLG1 and the shared plug SPLG2, since they have the same structure, the description will be made with taking the shared plug SPLG1 as an example.

First, as shown in FIG. 2, in the memory cell MC of the SRAM, the drain region of the load MISFET Qp1 is connected to the gate electrodes of the load MISFET Qp2 and the drive MISFET Qd2. It is also possible to connect the drain region of the load MISFET Qp1 to the gate electrodes of the load MISFET Qp2 and the drive MISFET Qd2 through the wiring, but this connection is made through the shared plug in the SRAM of the second embodiment. In other words, the shared plug is the plug formed so as to be connected to both the drain region of the load MISFET Qp1 and the gate electrodes of the load MISFET Qp2 and the drive MISFET Qd2.

More specifically, as shown in FIG. 3, the active region Ap1 of the load MISFET Qp1 and the gate electrode G4 of the load MISFET Qp2 and the drive MISFET Qd2 are connected by the shared plug SPLG1. The structure of the shared plug SPLG1 will be described below.

FIG. 24 is a cross-sectional view taken along the line C-C in FIG. 3. In FIG. 24, the element isolation regions STI are formed in the semiconductor substrate 1S, and the n type well NWL is formed in an active region defined by the element isolation regions STI. The load MISFET Qp1 is formed on the n type well NWL. On the other hand, the gate electrode G4 is formed on the element isolation region STI via the gate insulating film GOX2.

The gate electrode G4 is made up of the metal film MF2 directly formed on the gate insulating film GOX2, the polysilicon film PF1 formed on the metal film MF2 and the nickel platinum silicide film CS formed on a surface of the polysilicon film PF1. The offset spacer OS is formed on a left sidewall of the gate electrode G4 thus formed, and the sidewall SW is formed outside the offset spacer OS.

Further, the silicon nitride film SN1 is formed so as to cover the gate electrode G4 and the load MISFET QP1, and the contact interlayer insulating film CIL is formed on the silicon nitride film SN1. The shared plug SPLG1 and the plug PLG4 are formed so as to penetrate through the contact interlayer insulating film CIL and the silicon nitride film SN1. On the contact interlayer insulating film CIL in which the shared plug SPLG1 and the plug PLG4 have been formed, the barrier insulating film BIF and the interlayer insulating film IL1 are formed. Wiring trenches are formed in the barrier insulating film BIF and the interlayer insulating film IL1, and the shared plug SPLG1 and the plug PLG4 are disposed at the bottom of the wiring trenches. The barrier conductive film BCF is formed on the bottom surfaces and the side surfaces of the wiring trenches, and the copper film CF is formed on the barrier conductive film BCF so as to fill the wiring trenches. The wiring L1 is formed by embedding the barrier conductive film BCF and the copper film CF into the wiring trench.

The plug PLG4 is formed by embedding the titanium film TI, the titanium nitride film TIN and the tungsten film WF into the contact hole CNT4 formed so as to penetrate through the silicon nitride film SN1 and the contact interlayer insulating film CIL. In other words, the plug PLG4 is made up of the titanium film TI formed on the inner wall of the contact hole CNT4, the titanium nitride film TIN formed on the titanium film TI and the tungsten film WF formed on the titanium nitride film TIN. The plug PLG4 is electrically connected to the source region (shallow p type impurity diffusion region EX2 and deep p type impurity diffusion region PR1) of the load MISFET Qp1 at the bottom surface thereof.

The shared plug SPLG1 is formed by embedding the titanium film TI, the titanium nitride film TIN and the tungsten film WF into the shared contact hole SCNT1 formed so as to penetrate through the silicon nitride film SN1 and the contact interlayer insulating film CIL. In other words, the shared plug SPLG1 is made up of the titanium film TI formed on the inner wall of the shared contact hole SCNT1, the titanium nitride film TIN formed on the titanium film TI and the tungsten film WF formed on the titanium nitride film TIN. The shared plug SPLG1 is electrically connected to both the gate electrode G4 extending on the element isolation region STI and the drain region (shallow p type impurity diffusion region EX2 and deep p type impurity diffusion region PR1) of the load MISFET Qp1. By this means, the gate electrode G4 and the drain region of the load MISFET Qp1 are connected by the shared plug SPLG1.

The characteristic point of the second embodiment is that a concave portion CP2 is formed in the right side surface of the metal film MF2 constituting the gate electrode G4 and a conductive material is embedded in the concave portion CP2 to be a part of the shared plug SPLG1. By forming the concave portion CP2 in the right side surface of the metal film MF2 as described above, the contact area between the gate electrode G4 and the shared plug SPLG1 can be increased. For example, when considering the shared plug without the concave portion CP2, the shared plug is connected to the gate electrode G4 at the upper surface and the side surface of the gate electrode G4. At this time, with regard to the relation to the side surface of the gate electrode G4, the gate electrode G4 is connected to the shared plug at the side surface of the nickel platinum silicide film CS, the side surface of the polysilicon film PF1 and the side surface of the metal film MF2.

On the other hand, in the second embodiment, the area of the side surface of the gate electrode G4 connected to the shared plug SPLG1 can be further increased. More specifically, in addition to the side surface of the nickel platinum silicide film CS, the side surface of the polysilicon film PF1 and the side surface of the metal film MF2, a part of the bottom surface of the polysilicon film PF1 exposed from the concave portion CP2 is also connected to the shared plug SPLG1. That is, by forming the concave portion CP2 in the side surface of the metal film MF2, a part of the bottom surface of the polysilicon film PF1 can be exposed from the concave portion CP2. As a result, by embedding a conductive material in the concave portion CP2 formed in the side surface of the metal film MF2, the contact area to the shared plug SPLG1 is increased. Note that, for example, the titanium film TI and the titanium nitride film TIN constituting the shared plug SPLG1 can be embedded in the concave portion CP2 formed in the side surface of the metal film MF2.

As described above, according to the second embodiment, by the characteristic point that the concave portion CP2 is formed in the side surface of the gate electrode G4, the contact area between the gate electrode G4 and the shared plug SPLG1 can be increased, and the gate resistance (parasitic resistance) can be reduced. Furthermore, according to the second embodiment, the connection reliability between the gate electrode G4 and the shared plug SPLG1 can be improved by the above-described characteristic point.

Furthermore, according to the second embodiment, the connection reliability between the shared plug SPLG1 and the drain region of the load MISFET Qp1 can be also improved by the characteristic point that the concave portion CP2 is formed in the side surface of the metal film MF2 constituting a part of the gate electrode G4. This will be described below.

First, for forming the shared plug SPLG1, the shared contact hole SCNT1 penetrating through the silicon nitride film SN1 and the contact interlayer insulating film CIL is formed. Then, after forming the shared contact hole SCNT1, the surface of the nickel platinum silicide film CS (drain region of load MISFET Qp1) exposed from the bottom of the shared contact hole SCNT1 is cleaned. At this time, for sufficiently cleaning the surface of the nickel platinum silicide film CS, the solution with a high etching rate to the metal film is desirably used. In this manner, the surface of the nickel platinum silicide film CS is sufficiently cleaned, and the connection reliability between the nickel platinum silicide film CS constituting a part of the drain region of the load MISFET Qp1 and the shared plug SPLG1 can be improved.

However, the shared plug SPLG1 is connected not only to the nickel platinum silicide film CS but also to the gate electrode G4 formed on the element isolation region STI. In other words, not only the surface of the nickel platinum silicide film CS but also the side surface of the gate electrode G4 is exposed on the inner surface of the shared contact hole SCNT1. More specifically, the side surface of the metal film MF2 constituting a part of the gate electrode G4 is also exposed.

Therefore, if the solution with a high etching rate to the metal film is used when cleaning the surface of the nickel platinum silicide film CS (drain region of load MISFET Qp1) exposed from the bottom of the shared contact hole SCNT1, the metal film MF2 of the gate electrode G4 exposed from the shared contact hole SCNT1 is also etched from the side surface. For its prevention, the solution with a low etching rate to the metal film is conventionally used for the cleaning of the nickel platinum silicide film CS exposed from the shared contact hole SCNT1. However, in the case of using the solution with a low etching rate to the metal film, the surface of the nickel platinum silicide film CS cannot be sufficiently cleaned in many cases, and as a result, there occurs a problem that the connection reliability between the shared plug SPLG1 and the drain region of the load MISFET Qp1 is reduced.

Therefore, in the second embodiment, in order to sufficiently clean the nickel platinum silicide film CS exposed from the shared contact hole SCNT1, the solution with a high etching rate to the metal film is used. In this case, the metal film MF2 exposed from the side surface of the gate electrode G4 is also etched, but the etching of the metal film MF2 is actively utilized in the second embodiment. In other words, although the concave portion CP2 is formed in the side surface of the metal film MF2 by the cleaning inside the shared contact hole SCNT1, the conductive material is embedded also in the concave portion CP2 to use it as a part of the shared plug SPLG1 in the second embodiment. As a result, since the bottom surface of the polysilicon film PF1 exposed from the concave portion CP2 can also be used as the connecting portion between the gate electrode G4 and the shared plug SPLG1, the contact area between the gate electrode G4 and the shared plug SPLG1 can be increased, and the gate resistance (parasitic resistance) can be reduced.

As described above, when the structure in which the concave portion CP2 is formed in the side surface of the metal film MF2 constituting the gate electrode G4 is applied to the shared plug SPLG1, the reduction of the gate resistance (parasitic resistance) can be achieved as a direct effect. Furthermore, in the second embodiment, since the solution with a high cleaning effect to the surface of the nickel platinum silicide film CS can be used for the cleaning of the shared contact hole SCNT1, it is possible to exert the remarkable effect that the connection reliability between the shared plug SPLG1 and the drain region (nickel platinum silicide film CS) of the load MISFET Qp1 can be improved.

The semiconductor device according to the second embodiment has the structure as described above, and the manufacturing method thereof will be described below with reference to the drawings. In the drawings used in the following description, the p channel MISFET forming region is shown.

First, the semiconductor substrate 1S made of single crystal silicon to which a p type impurity such as boron (B) is implanted is prepared as shown in FIG. 25. At this time, the semiconductor substrate 1S is in a state of a semiconductor wafer in an almost disc shape. Then, the element isolation regions STI for isolating the elements are formed in the semiconductor substrate 1S. The element isolation regions STI are formed to prevent the mutual interference between the elements. The element isolation regions STI can be formed by using, for example, the LOCOS (Local Oxidation of Silicon) method or the STI (Shallow Trench Isolation) method. For example, in the STI method, the element isolation regions STI are formed in the following manner. That is, element isolation trenches are formed in the semiconductor substrate 1S by using the photolithography technology and the etching technology. Then, a silicon oxide film is formed on the semiconductor substrate so as to fill the element isolation trenches, and thereafter, the unnecessary silicon oxide film formed on the semiconductor substrate is removed by the chemical mechanical polishing (CMP). In this manner, the element isolation regions STI in which the silicon oxide film is embedded only in the element isolation trenches can be formed.

Next, an impurity is implanted into an active region isolated by the element isolation regions STI, thereby forming an n type well NWL. The n type well NWL is formed by implanting an n type impurity such as phosphorus or arsenic into the semiconductor substrate 1S by the ion implantation method.

Subsequently, a semiconductor region (not shown) for forming a channel is formed in a surface region of the n type well NWL. The semiconductor region for forming a channel is formed to adjust the threshold voltage for forming the channel.

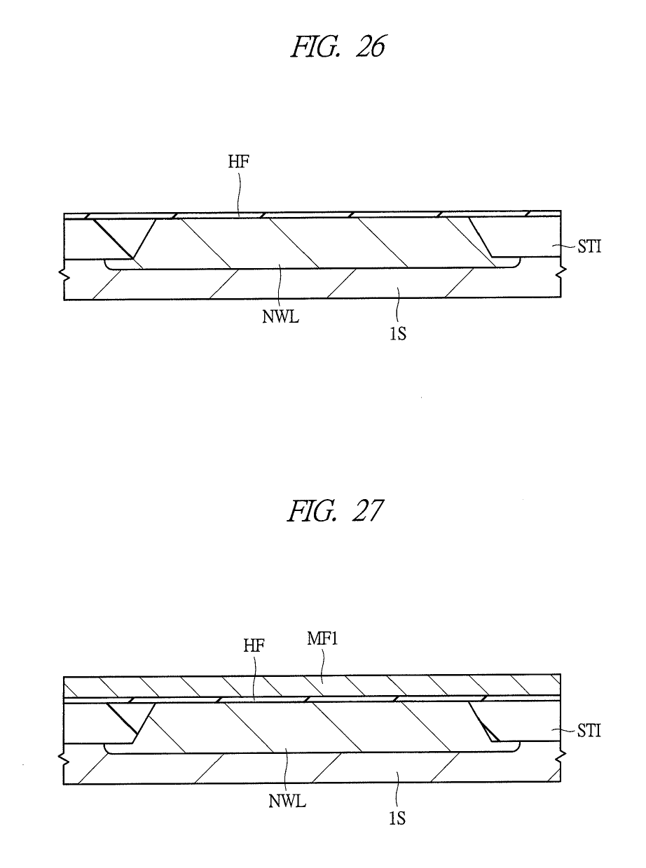

Subsequently, as shown in FIG. 26, a hafnium oxide film HF is formed on the semiconductor substrate 1S (n type well NWL and element isolation region STI). The hafnium oxide film HF can be formed by using, for example, the chemical vapor deposition (CVD) method or the atomic layer deposition (ALD) method. Note that aluminum oxide is added to the hafnium oxide film HF formed in the p channel MISFET forming region.

Then, as shown in FIG. 27, a metal film MF1 is formed on the hafnium oxide film HF. In other words, the metal film MF1 is formed on the whole surface of the semiconductor substrate 1S. Thereafter, the metal film MF1 is patterned by using the photolithography technology and the etching technology. The patterning of the metal film MF1 is performed so that the metal film MF1 is left in the p channel MISFET forming region (region shown in FIG. 27) and the metal film MF1 is removed in the other region (not shown). Therefore, the metal film MF1 is removed in the n channel MISFET forming region (not shown).

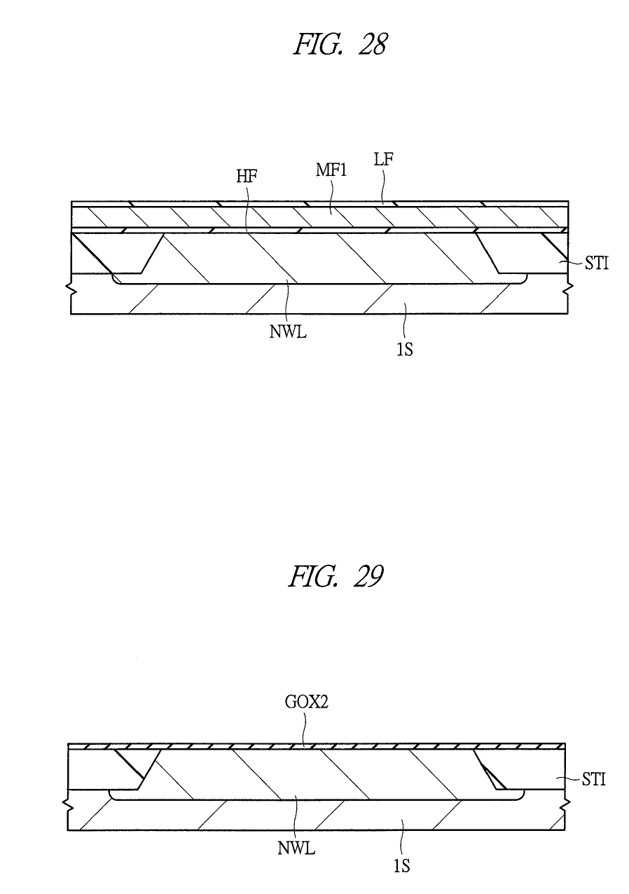

Next, as shown in FIG. 28, a lanthanum oxide film LF is formed on metal film MF1 in the p channel MISFET forming region. The lanthanum oxide film LF can be formed by using, for example, the CVD method or the ALD method. Note that, in the n channel MISFET forming region (not shown), the lanthanum oxide film LF is formed on the hafnium oxide film HF.

Then, the heat treatment is performed to implant lanthanum oxide into the hafnium oxide film HF, thereby forming the gate insulating film formed of the hafnium oxide film containing lanthanum oxide in the n channel MISFET forming region (not shown). On the other hand, in the p channel MISFET forming region, as shown in FIG. 29, the hafnium oxide film HF to which aluminum oxide is added is exposed by removing the lanthanum oxide film LF and the metal film MF1. In the p channel MISFET forming region, the hafnium oxide film HF to which aluminum oxide is added serves as the gate insulating film GOX2. The gate insulating film GOX2 is a high dielectric constant film with a dielectric constant higher than that of a silicon oxide film.

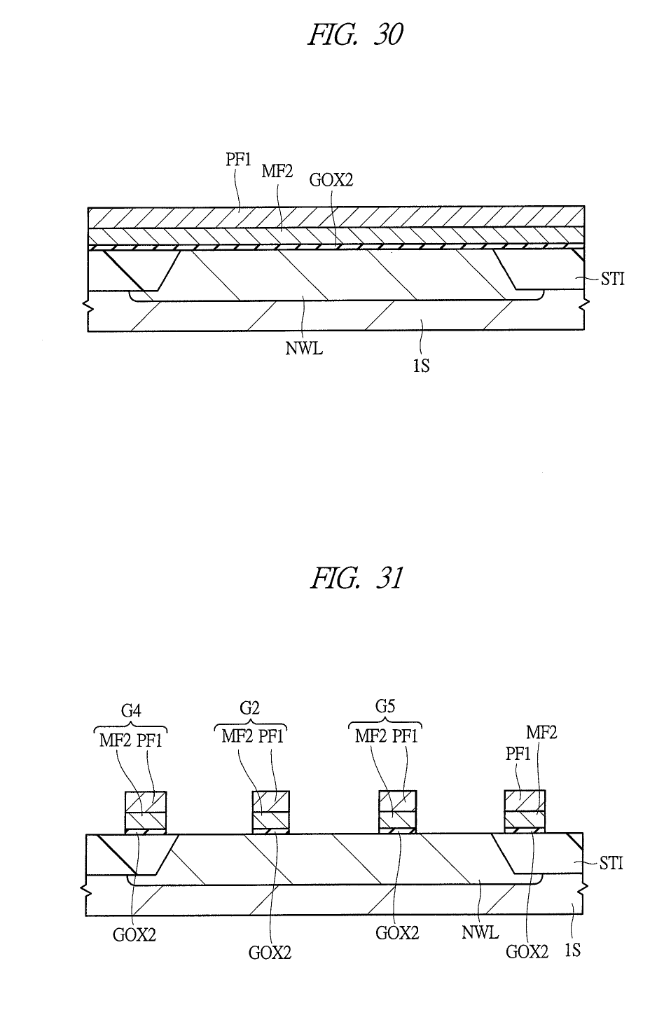

Subsequently, as shown in FIG. 30, the metal film MF2 is formed on the gate insulating film GOX2, and the polysilicon film PF1 is formed on the metal film MF2. The metal film MF2 is made of metal or metal compound and is formed of, for example, a titanium nitride film. The titanium nitride film can be formed by using, for example, the sputtering method. Also, the polysilicon film PF1 can be formed by using, for example, the CVD method.

Next, as shown in FIG. 31, the polysilicon film PF1 and the metal film MF2 are patterned by using the photolithography technology and the etching technology. The patterning of the polysilicon film PF1 and the metal film MF2 is performed so that the polysilicon film PF1 and the metal film MF2 are left only in a gate electrode forming region. In this manner, the gate electrodes G2, G4 and G5 made up of the stacked film of the metal film MF2 and the polysilicon film PF1 are formed. When processing the gate electrodes G2, G4 and G5, the polysilicon film PF1 whose processing is easy is first processed and the metal film MF2 whose processing is relatively difficult is then processed. First, by processing the polysilicon film PF1, the profile (outline) of the gate electrodes G2, G4 and G5 is determined, and thereafter, the metal film MF2 is processed, thereby completing the gate electrodes G2, G4 and G5. Therefore, even when the gate electrodes G2, G4 and G5 are miniaturized, the gate electrodes G2, G4 and G5 can be formed in good shape. In other words, according to the second embodiment, the processing accuracy of the gate electrodes G2, G4 and G5 can be improved compared with the case where the gate electrodes G2, G4 and G5 are formed by processing the single film of the metal film MF2 whose processing is difficult.

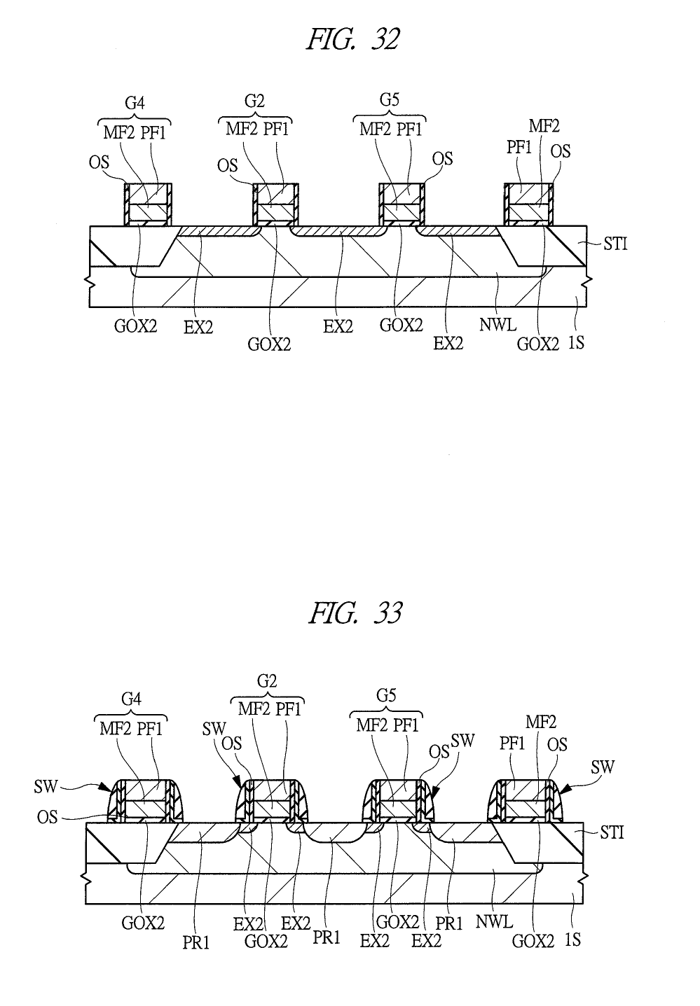

Subsequently, as shown in FIG. 32, a silicon oxide film is formed on the semiconductor substrate 1S on which the gate electrodes G2, G4 and G5 have been formed, and the anisotropic etching is performed to the silicon oxide film. By this means, the offset spacers OS are formed on both sidewalls of the gate electrodes G2, G4 and G5. The offset spacers OS are formed for adjusting the implantation of an impurity to the regions reaching the edges of the channel regions from the edges of the gate electrodes G2, G4 and G5 when the shallow p type impurity diffusion regions EX2 aligned with the gate electrodes G2, G4 and G5 are formed as described later.

After forming the offset spacers OS, the shallow p type impurity diffusion regions EX2 aligned with the gate electrodes G2, G4 and G5 are formed by using the photolithography technology and the ion implantation method. The shallow p type impurity diffusion region EX2 is a semiconductor region and a p type impurity such as boron is implanted thereto.

Next, as shown in FIG. 33, a staked film of a silicon oxide film and a silicon nitride film is formed on the semiconductor substrate 1S. The silicon oxide film and the silicon nitride film can be formed by using, for example, the CVD method. Then, by performing the anisotropic etching to the silicon oxide film and the silicon nitride film, the sidewalls SW are formed on the sidewalls of the gate electrodes G2, G4 and G5. The sidewall SW is formed of a stacked film of a silicon oxide film and a silicon nitride film, but the sidewall SW is not limited to this and it may be formed of a single film of a silicon nitride film or a single film of a silicon oxide film.

Thereafter, the deep p type impurity diffusion regions PR1 aligned with the sidewalls SW are formed by using the photolithography technology and the ion implantation method. The deep p type impurity diffusion region PR1 is a semiconductor region to which a p type impurity such as boron is implanted. The deep p type impurity diffusion region PR1 and the shallow p type impurity diffusion region EX2 constitute the source region. Similarly, the deep p type impurity diffusion region PR1 and the shallow p type impurity diffusion region EX2 constitute the drain region. By forming the source region and the drain region from the shallow p type impurity diffusion regions EX2 and the deep p type impurity diffusion regions PR1 as described above, the source region and the drain region can have the LDD (Lightly Doped Drain) structure.

After forming the deep p type impurity diffusion regions PR1 in the above-described manner, the heat treatment at about 1000° C. is performed. By this means, the activation of the implanted impurity is carried out.

Thereafter, as shown in FIG. 34, a nickel platinum film is formed on the semiconductor substrate 1S. At this time, the nickel platinum film is formed so as to be in direct contact with the gate electrodes G2, G4 and G5. Similarly, the nickel platinum film directly contacts the deep p type impurity diffusion region PR1.

The nickel platinum film can be formed by using, for example, the sputtering method. Then, by performing the heat treatment after forming the nickel platinum film, the polysilicon film PF1 constituting the gate electrodes G2, G4 and G5 and the nickel platinum film are reacted, thereby forming the nickel platinum silicide film CS. In this manner, the gate electrodes G2, G4 and G5 have the stacked structure of the metal film MF2, the polysilicon film PF1 and the nickel platinum silicide film CS. The nickel platinum silicide film CS is formed for reducing the resistance of the gate electrodes G2, G4 and G5. Similarly, the silicon and the nickel platinum film are reacted also on the surface of the deep p type impurity diffusion region PR1 by the above-described heat treatment, thereby forming the nickel platinum silicide film CS. Therefore, the resistance reduction can be achieved also in the deep p type impurity diffusion region PR1.

Then, the unreacted nickel platinum film is removed from the semiconductor substrate 1S. Note that, in the structure of the second embodiment, the nickel platinum silicide film CS is formed, but a nickel silicide film, a titanium silicide film, a cobalt silicide film or a platinum silicide film may be formed instead of the nickel platinum silicide film CS. In the above-described manner, the load MISFET Qp1 can be formed on the semiconductor substrate 1S. Furthermore, the gate electrode G4 may be extended to above the element isolation region STI.

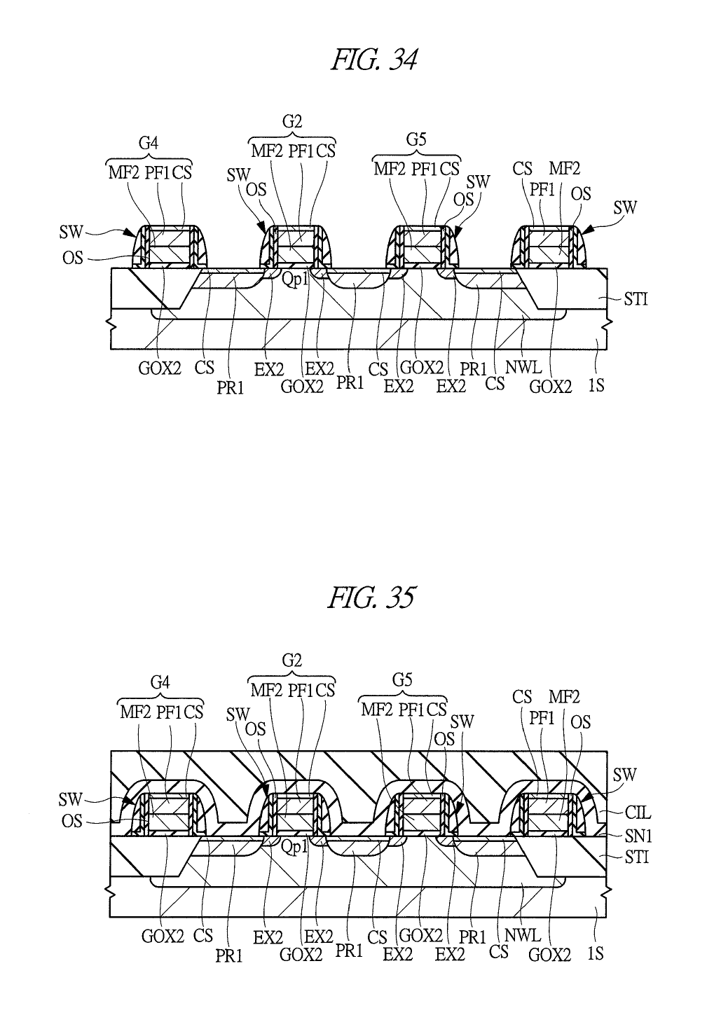

Subsequently, as shown in FIG. 35, the silicon nitride film SN1 is formed on the semiconductor substrate 1S on which the gate electrodes G2, G4 and G5 have been formed. The silicon nitride film SN1 is a film functioning as an etching stopper when contact holes are formed in the subsequent process. The silicon nitride film SN1 can be formed by using, for example, the CVD method.

Then, the contact interlayer insulating film CIL is formed on the silicon nitride film SN1. The contact interlayer insulating film CIL is formed so as to cover the gate electrodes G2, G4 and G5 via the silicon nitride film SN1. More specifically, the contact interlayer insulating film CIL is formed of a stacked film of an ozone TEOS film formed by the thermal CVD method using ozone and TEOS as materials and a plasma TEOS film formed by the plasma CVD method using TEOS as a material.

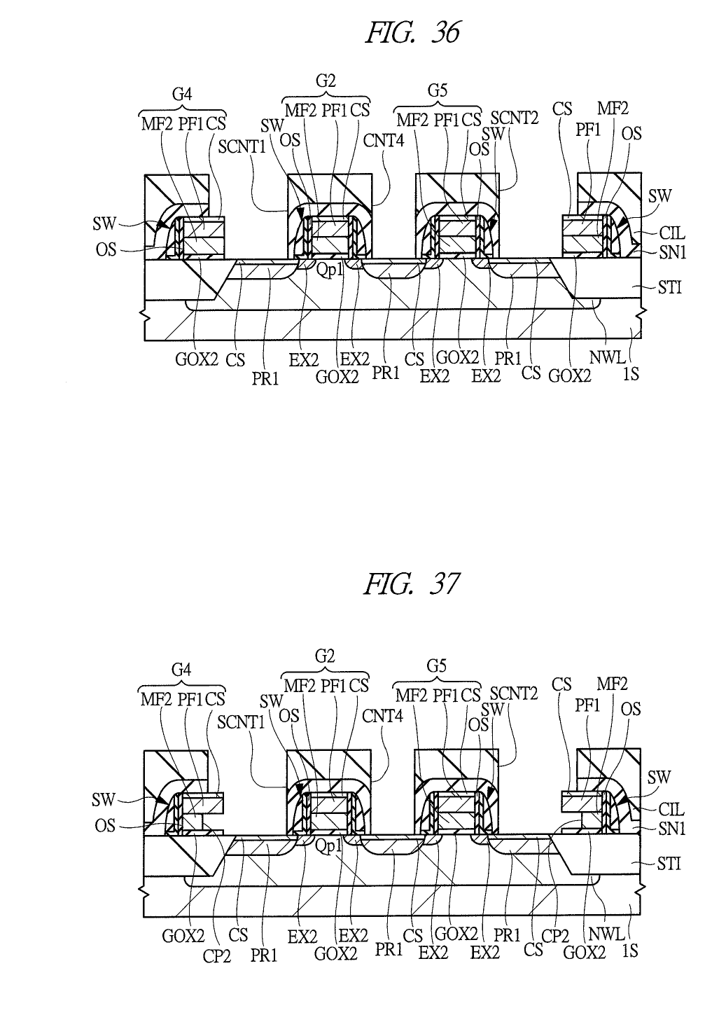

Next, as shown in FIG. 36, the shared contact holes SCNT1 and SCNT2 and the contact hole CNT4 are formed by using the photolithography technology and the etching technology. The shared contact holes SCNT1 and SCNT2 and the contact hole CNT4 are formed in the same process. The shared contact hole SCNT1 is formed so as to expose a part of the upper surface and the right side surface of the gate electrode G4 and also the surface of the drain region (nickel platinum silicide film CS) of the load MISFET Qp1. On the other hand, the contact hole CNT4 is formed so as to expose the surface of the source region (nickel platinum silicide film CS) of the load MISFET Qp1.

Subsequently, as shown in FIG. 37, the concave portion CP2 is formed in the side surface of the metal film MF2 exposed by forming the shared contact hole SCNT1. The following process is performed for forming the concave portion CP2 in the side surface of the metal film MF2. That is, a part of the metal film MF2 is wet-etched from one side surface of the metal film MF2 exposed on the inner surface of the shared contact hole SCNT1, thereby forming the concave portion CP2 in the one side surface of the metal film MF2. More specifically, in the wet etching, the sulfuric acid treatment by sulfuric acid is performed to the inner surface of the shared contact hole SCNT1, and then, the hydrogen peroxide treatment by hydrogen peroxide is performed. At this time, by adjusting the process time for performing the wet etching, the depth of the concave portion CP2 formed in the side surface of the metal film MF2 can be adjusted. Thereafter, the APM cleaning is performed as a cleaning process. The APM cleaning is the cleaning process using mixture solution of ammonia and hydrogen peroxide.

When the sulfuric acid treatment and the hydrogen peroxide treatment are performed, only the metal film MF2 exposed on the inner surface of the shared contact hole SCNT1 is wet-etched, and the polysilicon film PF1 is not etched. Therefore, as shown in FIG. 37, the concave portion CP2 by the etching is formed only in the side surface of the exposed metal film MF2. Note that, although the sulfuric acid treatment and the hydrogen peroxide treatment are performed for the whole surface of the semiconductor substrate 1S, since the metal film MF2 is not exposed in the contact hole CNT4, the metal film MF2 constituting the gate electrodes G2 and G5 is not wet-etched.

Here, in the second embodiment, since the sulfuric acid treatment and the hydrogen peroxide treatment are performed to the inner surface of the shared contact hole SCNT1, the surface of the nickel platinum silicide film CS exposed on the bottom surface of the shared contact hole CNT1 can be sufficiently cleaned. In other words, the solution with a high cleaning effect to the surface of the nickel platinum silicide film CS can be used for the cleaning of the shared contact hole SCNT1 in the second embodiment.

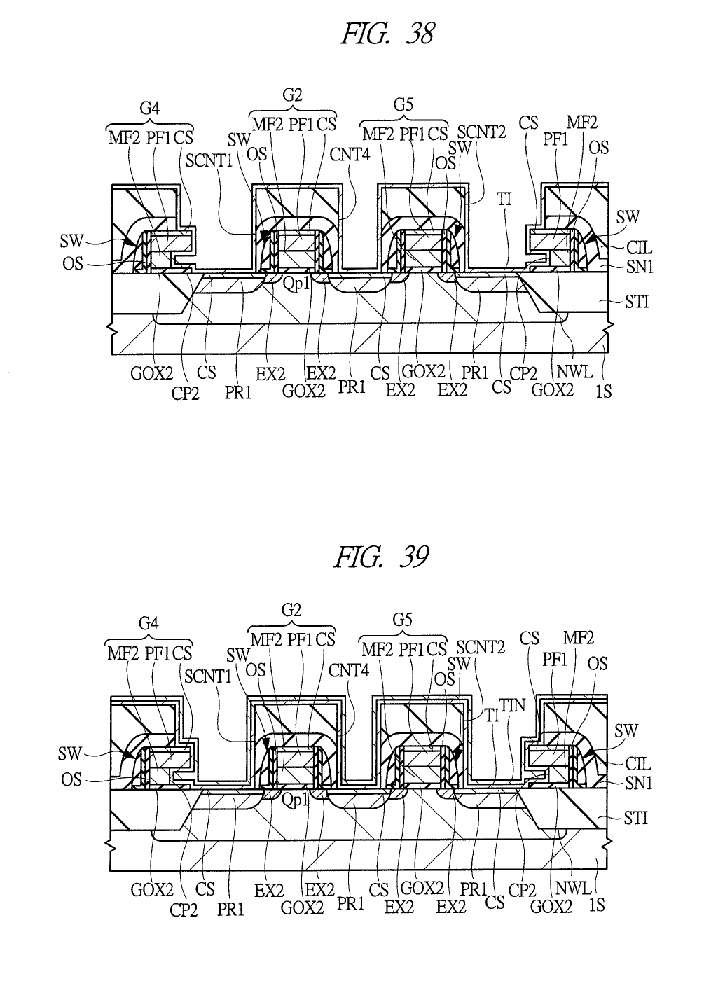

Thereafter, as shown in FIG. 38, the titanium film TI is formed on the contact interlayer insulating film CIL including the inside of the shared contact holes SCNT1 and SCNT2 and the contact hole CNT4. At this time, in the second embodiment, the titanium film TI is formed by the CVD method. The titanium film TI is usually formed by using the sputtering method. In the second embodiment, however, the titanium film TI has to be formed also on the surfaces of the concave portions CP2 formed in the shared contact holes SCNT1 and SCNT2. At this time, when the titanium film TI is formed by the sputtering method, it is difficult to make the titanium atoms reach the inside of the concave portions CP2 due to the geometric arrangement of the concave portions CP2. For its solution, the titanium film TI is formed by using the CVD method in the second embodiment. This is because, since the source gas can be supplied to the inside of the concave portions CP2 by the CVD method, the titanium film TI is produced by the chemical reaction in the concave portions CP2 and the conformal titanium film TI can be produced on the surfaces of the concave portions CP2.

Next, as shown in FIG. 39, the titanium nitride film TIN is formed on the titanium film TI. The titanium nitride film TIN can be formed by, for example, the plasma nitridation treatment using ammonia gas to the surface of the titanium film TI. In this manner, the concave portions CP2 exposed from the shared contact holes SCNT1 and SCNT2 are filled with the titanium film TI and the titanium nitride film TIN. The titanium film TI and the titanium nitride film TIN are provided in order to prevent the diffusion of tungsten constituting the tungsten film described later into silicon.

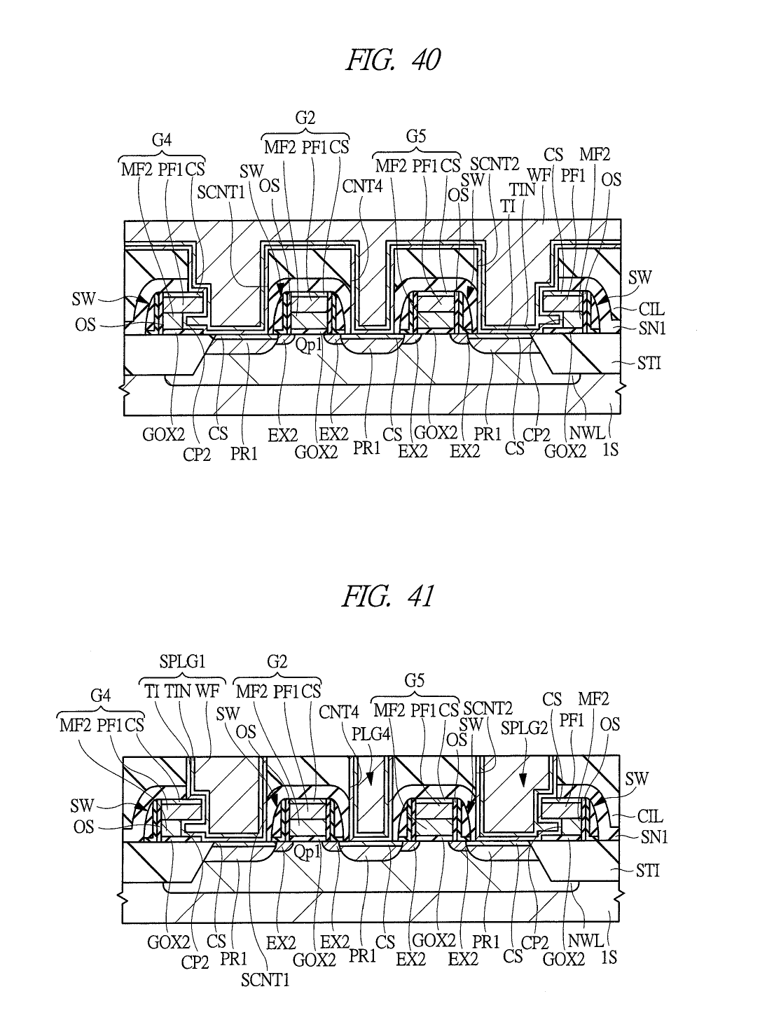

Subsequently, as shown in FIG. 40, the tungsten film WF is formed on the titanium nitride film TIN. In this manner, the inside of the shared contact holes SCNT1 and SCNT2 and the inside of the contact hole CNT4 are filled with the titanium film TI, the titanium nitride film TIN and the tungsten film WF. The tungsten film WF can be formed by, for example, the CVD method. Usually, silane gas is used as a source gas in the CVD method for forming the tungsten film WF, but diborane (B₂H₆) gas is used instead of silane gas in the second embodiment. This is because the damage applied to the inner walls of the shared contact holes SCNT1 and SCNT2 and the inner wall of the contact hole CNT4 can be reduced by using the diborane gas. In particular, the concave portions CP2 are formed in the shared contact holes SCNT1 and SCNT2 in the second embodiment, and the damage applied to the concave portions CP2 can also be reduced by the CVD method using diborane as a source gas.

Note that the concave portions CP2 are filled with the titanium film TI and the titanium nitride film TIN in the second embodiment. This is because the embedding properties for the concave portions CP2 in the formation of the titanium nitride film TIN by the plasma nitridation treatment are better than the coverage properties by the CVD method when forming the tungsten film WF. That is, this is because the occurrence of the voids can be suppressed when the concave portions CP2 are filled with the titanium nitride film TIN formed by the plasma nitridation treatment with good embedding properties. In other words, this is because, when the tungsten film WF is embedded in the concave portions CP2, the voids are likely to occur due to the deterioration of the embedding properties, and there is a possibility that the reduction of the parasitic resistance and the improvement of the connection reliability achieved by providing the concave portions CP2 cannot be fully exerted.

Thereafter, as shown in FIG. 41, the unnecessary titanium film TI, titanium nitride film TIN and tungsten film WF formed on the contact interlayer insulating film CIL are removed by the CMP (Chemical Mechanical Polishing) method. In this manner, the shared plugs SPLG1 and SPLG2 and the plug PLG4 in which the titanium film TI, the titanium nitride film TIN and the tungsten film WF are embedded only in the shared contact holes SCNT1 and SCNT2 and the contact hole CNT4 can be formed. Thereafter, similarly to the first embodiment described above, the wiring L1 (see FIG. 24) is formed by, for example, the damascene method. In the manner as described above, the semiconductor device according to the second embodiment can be manufactured.

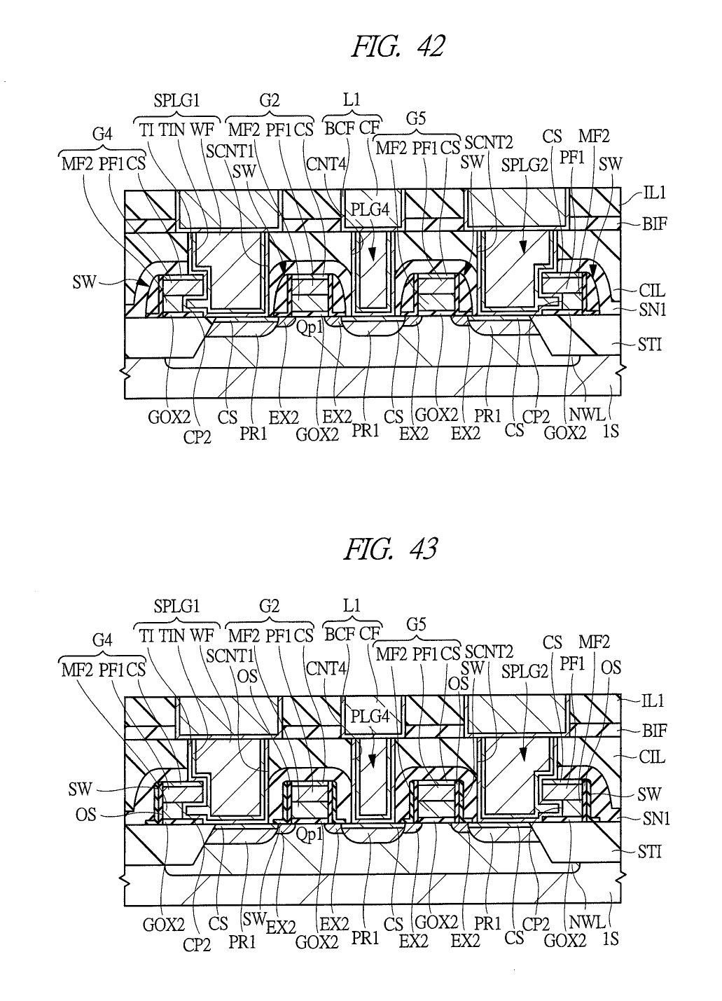

A modification example of the semiconductor device according to the second embodiment will be described below. FIG. 42 is a diagram showing a first modification example according to the second embodiment. FIG. 42 shows the load MISFET Qp1 which is a p channel MISFET and the shared plugs SPLG1 and SPLG2. The first modification example shown in FIG. 42 is also provided with the characteristic point that the concave portion CP2 is formed in the side surface of the metal film MF2 constituting the gate electrode G4. Therefore, the reduction of the gate resistance (parasitic resistance) and the improvement of the connection reliability between the gate electrode G4 and the shared plug SPLG1 can be achieved.

The difference between FIG. 42 and FIG. 24 lies in that the offset spacers OS are not formed on the sidewalls of the gate electrode G2 (gate electrode G4, gate electrode G5) in FIG. 42. The offset spacers OS do not have to be formed on the sidewalls of the gate electrode G2 (gate electrode G4, gate electrode G5) in this way.

FIG. 43 is a diagram showing a second modification example according to the second embodiment. FIG. 43 shows the load MISFET Qp1 which is a p channel MISFET and the shared plugs SPLG1 and SPLG2. The second modification example shown in FIG. 43 is also provided with the characteristic point that the concave portion CP2 is formed in the side surface of the metal film MF2 constituting the gate electrode G4. Therefore, the reduction of the gate resistance (parasitic resistance) and the improvement of the connection reliability between the gate electrode G4 and the shared plug SPLG1 can be achieved.

The difference between FIG. 43 and FIG. 24 lies in the structure of the sidewalls SW formed on the sidewalls of the gate electrode G2 (gate electrode G4, gate electrode G5). More specifically, the sidewall SW formed of a silicon oxide film and a silicon nitride film is formed in FIG. 24, but a silicon nitride film is removed by, for example, thermal phosphoric acid and the sidewall SW formed of only a silicon oxide film is formed in FIG. 43. The sidewall SW like this is called a disposable sidewall. The disposable sidewall may be used as the sidewall SW in this way.

### Third Embodiment

In the first embodiment, as shown in FIG. 4, for example, in the gate electrode G1 connected to the gate plug GPLG1 on the element isolation region STI, the concave portion CP1 is formed in one side surface of the metal film MF2 constituting a part of the gate electrode G1, thereby achieving the reduction of the parasitic resistance and the improvement of the connection reliability between the gate electrode G1 and the gate plug GPLG1. On the other hand, in the second embodiment, as shown in FIG. 24, in the shared plug SPLG1 which simultaneously connects the drain region of the load MISFET Qp1 and the gate electrode G4 formed on the element isolation region STI, the concave portion CP2 is formed in one side surface of the metal film MF2 constituting a part of the gate electrode G4 connected to the shared plug SPLG1. By this means, also in the second embodiment, the reduction of the parasitic resistance and the improvement of the connection reliability between the gate electrode G4 and the shared plug SPLG1 can be achieved.

As described above, the first embodiment has a characteristic point in the gate electrode G1 connected to the gate plug GPLG1, and on the other hand, the second embodiment has a characteristic point in the gate electrode G4 connected to the shared plug SPLG1. Therefore, the concave portion CP1 may be formed only in one side surface of the metal film MF2 connected to the gate plug GPLG1, or the concave portion CP2 may be formed only in one side surface of the metal film MF2 constituting a part of the gate electrode G4 connected to the shared plug SPLG1. Furthermore, the concave portion CP2 may be formed in one side surface of the metal film MF2 connected to the gate plug GPLG1 and the concave portion CP2 may also be formed in one side surface of the metal film MF2 connected to the shared plug SPLG1. In the third embodiment, the manufacturing method of forming the concave portion CP1 (concave portion CP2) in both the metal film MF2 connected to the gate plug GPLG1 and the metal film MF2 connected to the shared plug SPLG1 will be described.

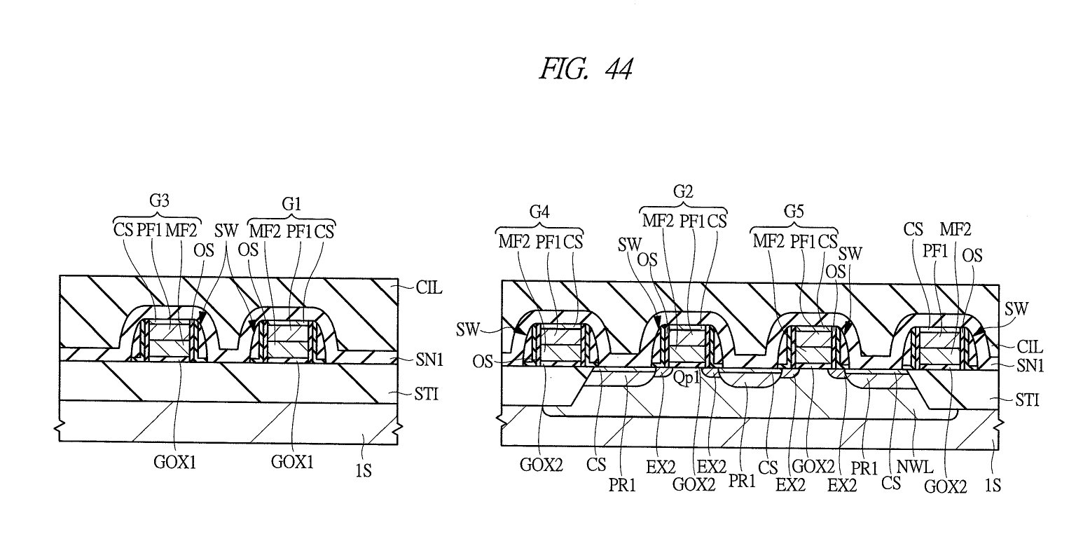

The view on the left side of FIG. 44 corresponds to a cross-sectional view showing the structure which is subjected to the process shown in FIG. 5 to FIG. 15 described in the first embodiment, and the view on the right side of FIG. 44 corresponds to a cross-sectional view showing the structure which is subjected to the process shown in FIG. 25 to FIG. 35 described in the second embodiment. By simultaneously performing the process of FIG. 5 to FIG. 15 of the first embodiment and the process of FIG. 25 to FIG. 35 of the second embodiment, the structure shown in FIG. 44 is formed.

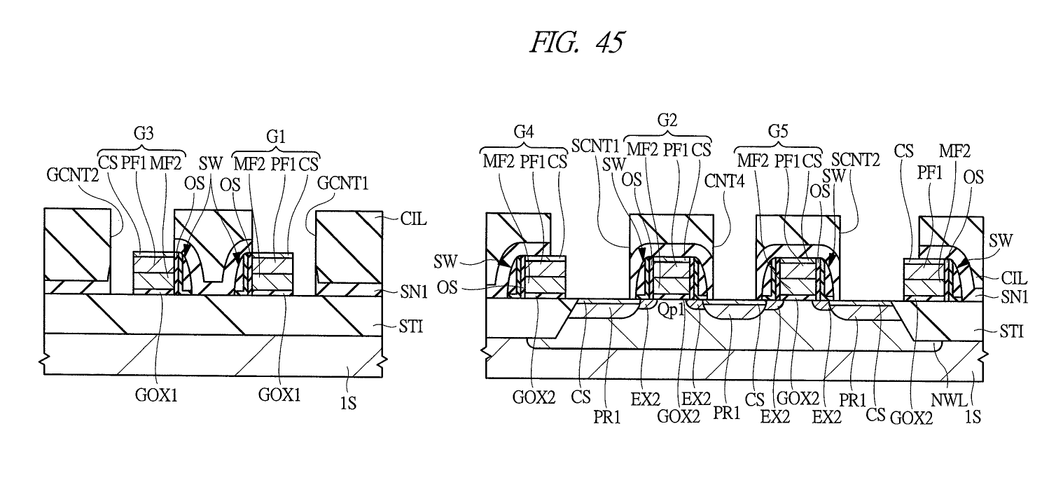

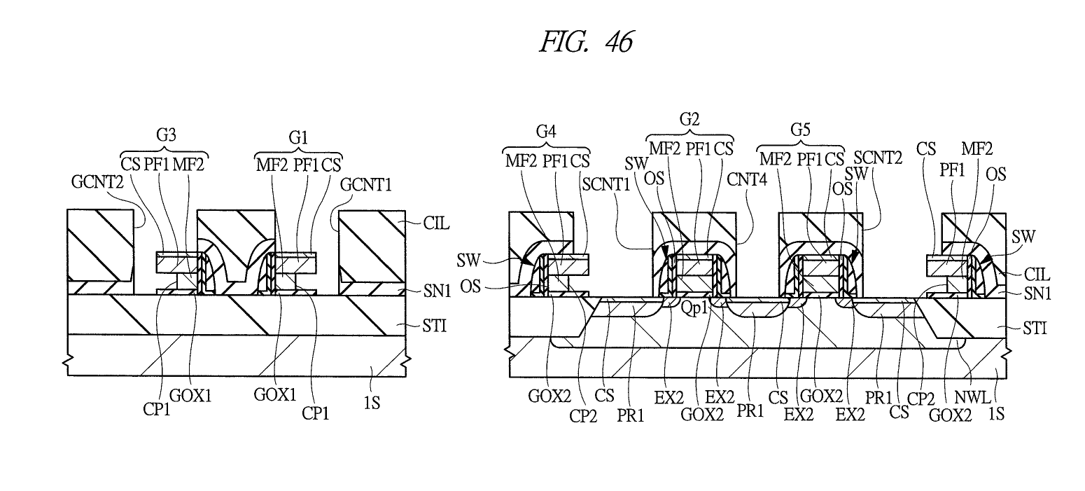

Next, as shown in FIG. 45, the gate contact holes GCNT1 and GCNT2, the shared contact holes SCNT1 and SCNT2 and the contact hole CNT4 are formed by using the photolithography technology and the etching technology. Since the gate contact hole CNT1 and the gate contact hole GCNT2 have the same structure, only the manufacturing process using the gate contact hole GCNT1 will be described below. Also, since the shared contact hole SCNT1 and the shared contact hole SCNT2 have the same structure, only the manufacturing process using the shared contact hole SCNT1 will be described below.

The diameter of the gate contact hole GCNT1 is larger than the gate length of the gate electrode G1. Therefore, by forming the gate contact hole GCNT1, the upper surface and one side surface of the gate electrode G1 are exposed, and a part of the surface of the element isolation region STI is also exposed.

The shared contact hole SCNT1 is formed so as to expose a part of the upper surface and the right side surface of the gate electrode G4 and also the surface of the drain region (nickel platinum silicide film CS) of the load MISFET Qp1. On the other hand, the contact hole CNT4 is formed so as to expose the surface of the source region (nickel platinum silicide film CS) of the load MISFET Qp1.

Subsequently, as shown in FIG. 46, the concave portion CP1 is formed in the side surface of the metal film MF2 exposed by forming the gate contact hole GCNT1, and the concave portion CP2 is formed in the side surface of the metal film MF2 exposed by forming the shared contact hole SCNT1. The following process is performed for forming the concave portions CP1 and CP2 in the side surfaces of the metal films MF2. That is, parts of the metal films MF2 are wet-etched from one side surfaces of the metal films MF2 exposed on the inner surfaces of the gate contact hole GCNT1 and the shared contact hole SCNT1, thereby forming the concave portions CP1 and CP2 in the one side surfaces of the metal films MF2. More specifically, in the wet etching, the sulfuric acid treatment by sulfuric acid is performed to the inner surface of the gate contact hole GCNT1 and the inner surface of the shared contact hole SCNT1, and then, the hydrogen peroxide treatment by hydrogen peroxide is performed. At this time, by adjusting the process time for performing the wet etching, the depth of the concave portions CP1 and CP2 formed in the side surfaces of the metal films MF2 can be adjusted. Thereafter, the APM cleaning is performed as a cleaning process. The APM cleaning is the cleaning process using mixture solution of ammonia and hydrogen peroxide.

When the sulfuric acid treatment and the hydrogen peroxide treatment are performed, only the metal films MF2 exposed on the inner surface of the gate contact hole GCNT1 and on the inner surface of the shared contact hole SCNT1 are wet-etched, and the polysilicon film PF1 is not etched. Therefore, as shown in FIG. 46, the concave portions CP1 and CP2 by the etching are formed only in the side surfaces of the exposed metal films MF2. Note that, although the sulfuric acid treatment and the hydrogen peroxide treatment are performed for the whole surface of the semiconductor substrate 1S, since the metal film MF2 is not exposed in the contact hole CNT4, the metal film MF2 constituting the gate electrodes G2 and G5 is not wet-etched.

Here, in the third embodiment, since the sulfuric acid treatment and the hydrogen peroxide treatment are performed to the inner surface of the shared contact hole SCNT1, the surface of the nickel platinum silicide film CS exposed on the bottom surface of the shared contact hole CNT1 can be sufficiently cleaned. In other words, the solution with a high cleaning effect to the surface of the nickel platinum silicide film CS can be used for the cleaning of the shared contact hole SCNT1 in the third embodiment.

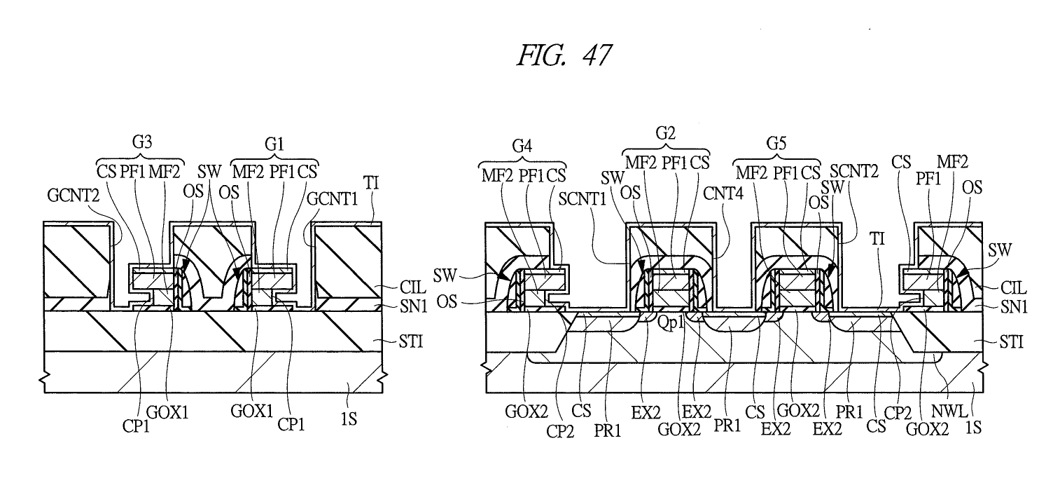

Thereafter, as shown in FIG. 47, the titanium film TI is formed on the contact interlayer insulating film CIL including the inside of the gate contact hole GCNT1, the shared contact hole SCNT1 and the contact hole CNT4. At this time, in the third embodiment, the titanium film TI is formed by the CVD method. The titanium film TI is usually formed by using the sputtering method. In the third embodiment, however, the titanium film TI has to be formed also on the surface of the concave portion CP1 formed in the gate contact hole GCNT1 and on the surface of the concave portion CP2 formed in the shared contact hole SCNT1. At this time, when the titanium film TI is formed by the sputtering method, it is difficult to make the titanium atoms reach the inside of the concave portions CP1 and CP2 due to the geometric arrangement of the concave portions CP1 and CP2. For its solution, the titanium film TI is formed by using the CVD method in the third embodiment. This is because, since the source gas can be supplied to the inside of the concave portions CP1 and CP2 by the CVD method, the titanium film TI is produced by the chemical reaction in the concave portions CP1 and CP2 and the conformal titanium film TI can be produced on the surfaces of the concave portions CP1 and CP2.

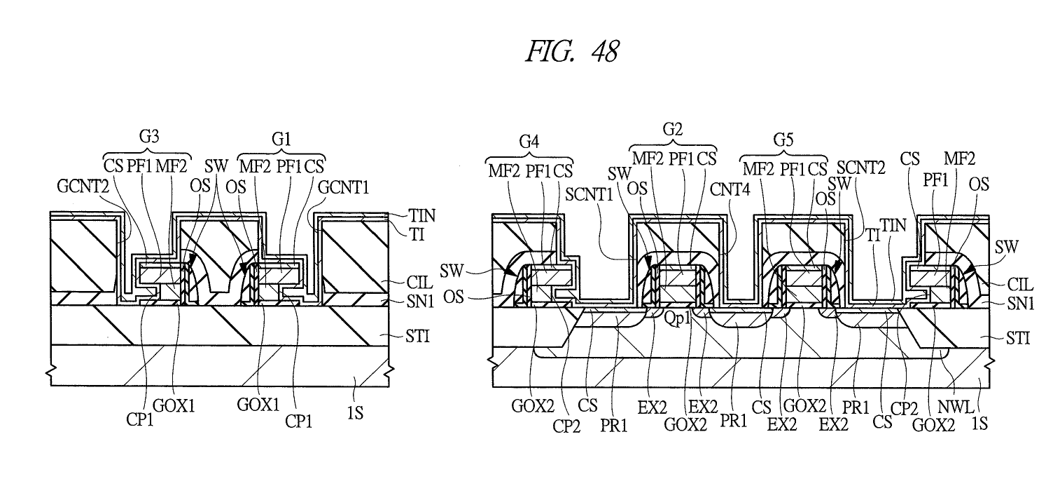

Next, as shown in FIG. 48, the titanium nitride film TIN is formed on the titanium film TI. The titanium nitride film TIN can be formed by, for example, the plasma nitridation treatment using ammonia gas to the surface of the titanium film TI. In this manner, the concave portion CP1 exposed from the gate contact hole GCNT1 and the concave portion CP2 exposed from the shared contact hole SCNT1 are filled with the titanium film TI and the titanium nitride film TIN. The titanium film TI and the titanium nitride film TIN are provided in order to prevent the diffusion of tungsten constituting the tungsten film described later into silicon.

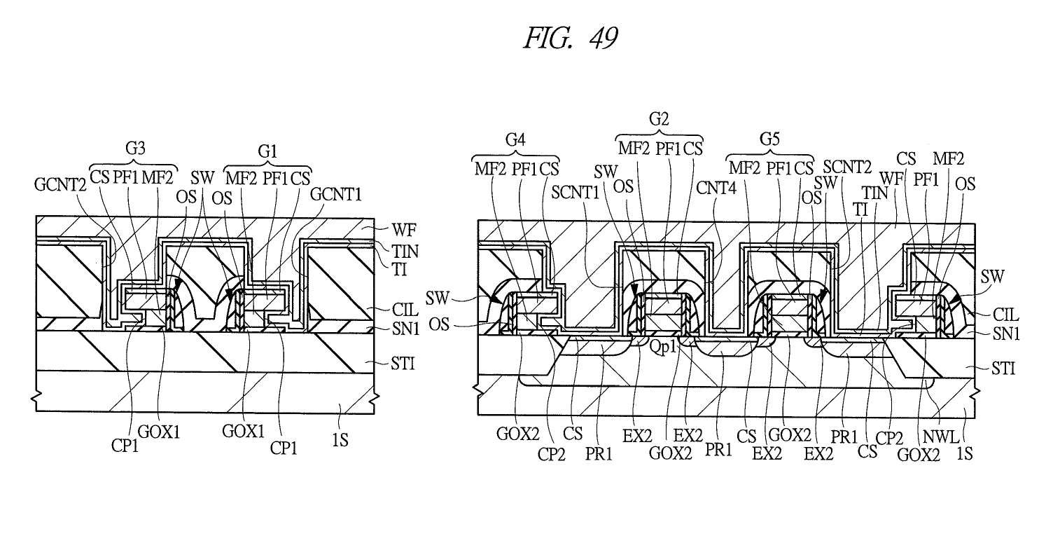

Subsequently, as shown in FIG. 49, the tungsten film WF is formed on the titanium nitride film TIN. In this manner, the inside of the gate contact hole GCNT1 and the shared contact hole SCNT1 and the inside of the contact hole CNT4 are filled with the titanium film TI, the titanium nitride film TIN and the tungsten film WF. The tungsten film WF can be formed by, for example, the CVD method. Usually, silane gas is used as a source gas in the CVD method for forming the tungsten film WF, but diborane (B₂H₆) gas is used instead of silane gas in the third embodiment. This is because the damage applied to the inner walls of gate contact hole GCNT1 and the shared contact hole SCNT1 and the inner wall of the contact hole CNT4 can be reduced by using the diborane gas. In particular, the concave portion CP1 is formed in the gate contact hole GCNT1 and the concave portion CP2 is formed in the shared contact hole SCNT1 in the third embodiment, and the damage applied to the concave portions CP1 and CP2 can also be reduced by the CVD method using diborane as a source gas.

Note that the concave portions CP1 and CP2 are filled with the titanium film TI and the titanium nitride film TIN in the third embodiment. This is because the embedding properties for the concave portions CP1 and CP2 in the formation of the titanium nitride film TIN by the plasma nitridation treatment are better than the coverage properties by the CVD method when forming the tungsten film WF. That is, this is because the occurrence of the voids can be suppressed when the concave portions CP1 and CP2 are filled with the titanium nitride film TIN formed by the plasma nitridation treatment with good embedding properties. In other words, this is because, when the tungsten film WF is embedded in the concave portions CP1 and CP2, the voids are likely to occur due to the deterioration of the embedding properties, and there is a possibility that the reduction of the parasitic resistance and the improvement of the connection reliability achieved by providing the concave portions CP1 and CP2 cannot be fully exerted.

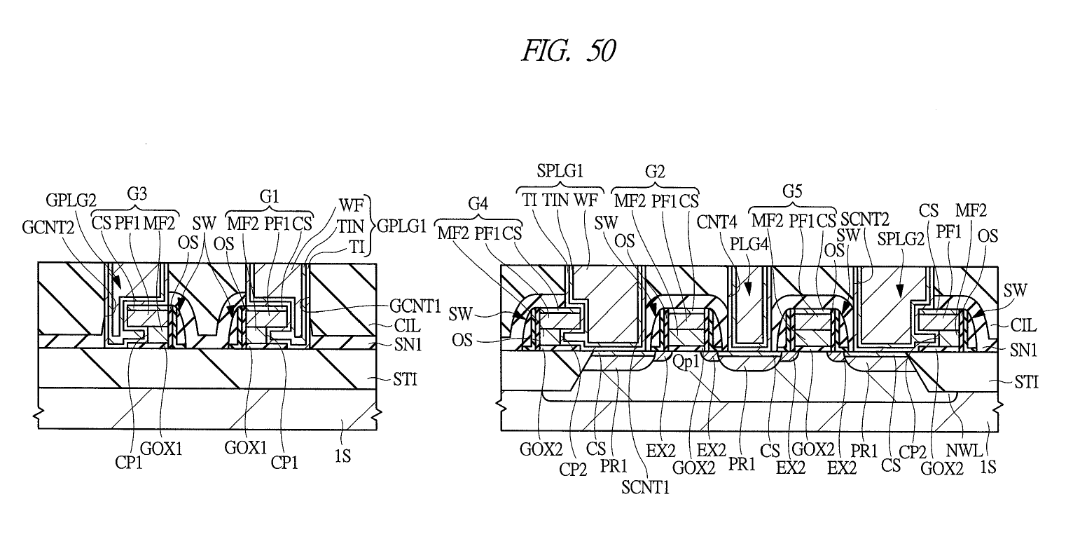

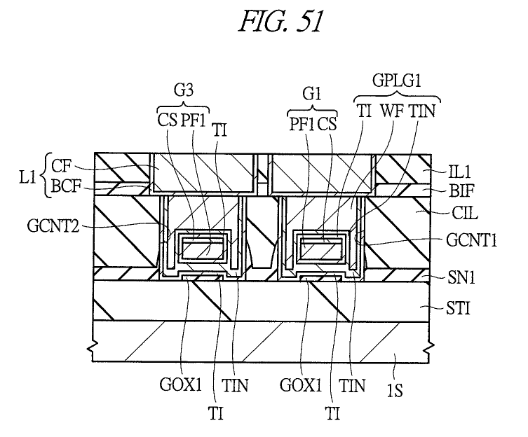

Thereafter, as shown in FIG. 50, the unnecessary titanium film TI, titanium nitride film TIN and tungsten film WF formed on the contact interlayer insulating film CIL are removed by the CMP (Chemical Mechanical Polishing) method. In this manner, the gate plug GPLG1, the shared plug SPLG1 and the plug PLG4 in which the titanium film TI, the titanium nitride film TIN and the tungsten film WF are embedded in the gate contact hole GCNT1, the shared contact hole SCNT1 and the contact hole CNT4 can be formed. Thereafter, similarly to the first embodiment and the second embodiment described above, the wiring L1 (see FIG. 4 and FIG. 24) is formed by, for example, the damascene method. In the manner as described above, the semiconductor device according to the third embodiment can be manufactured.

### Fourth Embodiment

The example in which the concave portion CP1 is formed in one side surface of the metal film MF2 constituting a part of the gate electrode G1 has been described in the first embodiment as shown in FIG. 4, but an example in which the metal film MF2 is completely removed from both side surfaces of the metal film MF2 will be described in the fourth embodiment.

FIG. 51 is a cross-sectional view showing the gate contact region in the fourth embodiment. The gate contact region shown in FIG. 51 corresponds to the cross section taken along the line B-B in FIG. 3. In FIG. 51, the characteristic point of the fourth embodiment is that the diameter of the gate contact hole GCNT1 (gate contact hole GCNT2) is larger than the gate length of the gate electrode G1 (gate electrode G3) and the upper surface and both side surfaces of the gate electrode G1 (gate electrode G3) are exposed from the gate contact hole GCNT1 (gate contact hole GCNT2). Furthermore, in the gate contact region, the metal film MF2 below the polysilicon film PF1 constituting the gate electrode G1 (gate electrode G3) is removed, and the region from which the metal film MF2 has been removed is filled with the titanium film TI and the titanium nitride film TIN.

Accordingly, the gate plug GPLG1 and the gate electrode G1 are connected at the upper surface of the gate electrode G1, both side surfaces of the gate electrode G1 and the bottom surface of the polysilicon film PF1. Similarly, the gate plug GPLG2 and the gate electrode G3 are connected at the upper surface of the gate electrode G3, both side surfaces of the gate electrode G3 and the bottom surface of the polysilicon film PF1. Therefore, according to the fourth embodiment, for example, the contact area between the gate electrode G1 and the gate plug GPLG1 can be increased, and the gate resistance (parasitic resistance) can be further reduced. Also, since the gate electrode G1 and the gate plug GPLG1 are electrically connected also at both side surfaces of the gate electrode G1 and the bottom surface of the polysilicon film PF1, the connection reliability between the gate electrode G1 and the gate plug GPLG1 can be improved.

Note that the manufacturing method of the semiconductor device according to the fourth embodiment is almost the same as the manufacturing method of the semiconductor device according to the first embodiment described above. The difference therebetween lies in the point that, in the fourth embodiment, the gate contact hole GCNT1 is formed so as to expose both side surfaces of the gate electrode G1 in the right view of FIG. 16 and the metal film MF2 below the polysilicon film PF1 is removed by the wet etching (sulfuric acid treatment and hydrogen peroxide treatment) in the right view of FIG. 17. The manufacturing method of the semiconductor device according to the fourth embodiment is the same as that of the first embodiment in the other processes. In the manner as described above, the semiconductor device according to the fourth embodiment can be manufactured.

In the foregoing, the invention made by the inventors of the present invention has been concretely described based on the embodiments. However, it is needless to say that the present invention is not limited to the foregoing embodiments and various modifications and alterations can be made within the scope of the present invention.

The present invention can be widely utilized in the industry of manufacturing semiconductor devices.

What is claimed is:

1. A semiconductor device comprising:
(a) a semiconductor substrate;
(b) element isolation regions formed in the semiconductor substrate;
(c) a MISFET formed in an active region defined by the element isolation regions;
(d) a first insulating film formed on the semiconductor substrate so as to cover the MISFET; and
(e) a plug formed to penetrate through the first insulating film,
the MISFET including:
(f) a gate insulating film formed on the semiconductor substrate;
(g) a gate electrode formed on the gate insulating film;
(h) a source region formed in the semiconductor substrate; and
(i) a drain region formed in the semiconductor substrate,
the gate electrode being made up of:
(g1) a first conductive film made of metal or metal compound formed on the gate insulating film; and
(g2) a second conductive film including a polysilicon film formed on the first conductive film,
the gate insulating film and the gate electrode extending from the active region to the element isolation region, and the gate electrode and the plug being electrically connected on the element isolation region,
wherein a concave portion is formed in one side surface of the first conductive film on the element isolation region, and
the second conductive film and the plug are electrically connected at a part of an upper surface of the second conductive film, one side surface of the second conductive film, and a part of a bottom surface of the second conductive film exposed from the concave portion.

2. The semiconductor device according to claim 1,
wherein the plug is formed to have a diameter larger than a gate length of the gate electrode.

3. The semiconductor device according to claim 2,
wherein a part of a bottom surface of the plug is in contact with an upper surface of the gate electrode, and
another part of the bottom surface of the plug is in contact with the element isolation region.

4. The semiconductor device according to claim 3,
wherein the plug is formed by embedding a conductive material into a contact hole formed in the first insulating film, and
the conductive material is embedded also in the concave portion formed in the one side surface of the first conductive film.

5. The semiconductor device according to claim 4,
wherein the plug includes:
(e1) a barrier conductive film formed in the contact hole, and
(e2) a tungsten film formed on the barrier conductive film so as to fill the contact hole.

6. The semiconductor device according to claim 5,
wherein the concave portion formed in the one side surface of the first conductive film is filled with the barrier conductive film.

7. The semiconductor device according to claim 6,
wherein the barrier conductive film is formed of a titanium film and a titanium nitride film formed on the titanium film.

8. The semiconductor device according to claim 1,
wherein the gate insulating film is formed of a high dielectric constant film with a dielectric constant higher than that of silicon oxide.

9. The semiconductor device according to claim 8,
wherein the first conductive film is formed of a titanium nitride film.

10. The semiconductor device according to claim 9,
wherein the second conductive film is formed of the polysilicon film and a silicide film formed on the polysilicon film.

11. A semiconductor device comprising:
(a) a semiconductor substrate;
(b) element isolation regions formed in the semiconductor substrate;
(c) a first MISFET formed in a first active region defined by the element isolation regions;
(d) a second MISFET formed in a second active region defined by the element isolation regions;
(e) a first insulating film formed on the semiconductor substrate so as to cover the first MISFET and the second MISFET; and
(f) a plug formed to penetrate through the first insulating film,
the first MISFET including:
(g) a first gate insulating film formed on the semiconductor substrate;
(h) a first gate electrode formed on the first gate insulating film;
(i) a first source region formed in the first active region of the semiconductor substrate; and
(j) a first drain region formed in the first active region of the semiconductor substrate,
the first gate electrode being made up of:
(h1) a first conductive film made of metal or metal compound formed on the first gate insulating film; and
(h2) a second conductive film including a polysilicon film formed on the first conductive film,
the first gate insulating film and the first gate electrode extending from the first active region to the element isolation region,
the second MISFET including:
(k) a second gate insulating film formed on the semiconductor substrate;
(l) a second gate electrode formed on the second gate insulating film;
(m) a second source region formed in the second active region of the semiconductor substrate; and
(n) a second drain region formed in the second active region of the semiconductor substrate,
the plug being arranged so as to be electrically connected to both the first gate electrode formed on the element isolation region and the second drain region formed in the second active region,
wherein a concave portion is formed in one side surface of the first conductive film on the element isolation region, and
the second conductive film and the plug are electrically connected at a part of an upper surface of the second conductive film, one side surface of the second conductive film, and a part of a bottom surface of the second conductive film exposed from the concave portion.

12. The semiconductor device according to claim 11,
wherein a part of a bottom surface of the plug is in contact with an upper surface of the first gate electrode, and
another part of the bottom surface of the plug is in contact with the second drain region.

13. The semiconductor device according to claim 12,
wherein the plug is formed by embedding a conductive material into a contact hole formed in the first insulating film, and
the conductive material is embedded also in the concave portion formed in the one side surface of the first conductive film.

14. The semiconductor device according to claim 13,
wherein the plug includes:
(f1) a barrier conductive film formed in the contact hole, and
(f2) a tungsten film formed on the barrier conductive film so as to fill the contact hole.

15. The semiconductor device according to claim 14,
wherein the concave portion formed in the one side surface of the first conductive film is filled with the barrier conductive film.

16. The semiconductor device according to claim 15,
wherein the barrier conductive film is formed of a titanium film and a titanium nitride film formed on the titanium film.

17. The semiconductor device according to claim 11,
wherein the first gate insulating film and the second gate insulating film are formed of high dielectric constant films with a dielectric constant higher than that of silicon oxide.

18. The semiconductor device according to claim 17,
wherein the first conductive film is formed of a titanium nitride film.

19. The semiconductor device according to claim 18,
wherein the second conductive film is formed of the polysilicon film and a silicide film formed on the polysilicon film.

20. The semiconductor device according to claim 11,
wherein the first MISFET and the second MISFET are semiconductor elements which constitute an SRAM.

21. A manufacturing method of a semiconductor device comprising the steps of:
(a) forming element isolation regions for defining active regions in a semiconductor substrate;
(b) forming a gate insulating film from above the active region to above the element isolation region of the semiconductor substrate;
(c) forming a first conductive film made of metal or metal compound on the gate insulating film;
(d) forming a second conductive film including a polysilicon film on the first conductive film;
(e) patterning the second conductive film and the first conductive film, thereby forming a gate electrode extending from the active region to the element isolation region;
(f) forming a source region and a drain region in the active region of the semiconductor substrate;
(g) forming a first insulating film on the semiconductor substrate so as to cover the gate electrode;
(h) forming a contact hole penetrating through the first insulating film so as to expose a part of an upper surface of the gate electrode, one side surface of the gate electrode and a part of a surface of the element isolation region;
(i) performing wet etching to a part of the first conductive film from one side surface of the first conductive film exposed on an inner surface of the contact hole, thereby forming a concave portion in the one side surface of the first conductive film; and
(j) embedding a conductive material into the contact hole including the concave portion, thereby forming a plug,
wherein the second conductive film and the plug are in contact with each other at a part of an upper surface of the second conductive film, one side surface of the second conductive film, and a part of a bottom surface of the second conductive film exposed from the concave portion.

22. The manufacturing method of the semiconductor device according to claim 21,
wherein the wet etching in the step (i) includes a step of performing sulfuric acid treatment using sulfuric acid to the inner surface of the contact hole and then performing hydrogen peroxide treatment using hydrogen peroxide.

23. The manufacturing method of the semiconductor device according to claim 22,
wherein the step (j) includes the steps of:
(j1) forming a barrier conductive film on the inner surface of the contact hole including the concave portion;
(j2) forming a tungsten film on the barrier conductive film, thereby filling the contact hole with the barrier conductive film and the tungsten film; and
(j3) removing unnecessary barrier conductive film and tungsten film formed on the first insulating film.

24. The manufacturing method of the semiconductor device according to claim 23,
wherein the step (j1) includes a step of forming a titanium film by using a CVD method on the inner surface of the contact hole including the concave portion.

25. The manufacturing method of the semiconductor device according to claim 24,
wherein the step (j1) further includes a step of performing plasma nitridation treatment using ammonia gas to a surface of the titanium film, thereby forming a titanium nitride film on the surface of the titanium film.

26. The manufacturing method of the semiconductor device according to claim 25,
wherein, in the step (j2), the tungsten film is formed by a CVD method using diborane as a material.

27. The manufacturing method of the semiconductor device according to claim 26,
wherein the concave portion is filled with the titanium film and the titanium nitride film formed on the surface of the titanium film.

28. A manufacturing method of a semiconductor device comprising the steps of:
(a) forming element isolation regions in a semiconductor substrate, thereby defining a first MISFET forming region and a second MISFET forming region;
(b) forming a first gate insulating film in the first MISFET forming region and a second gate insulating film in the second MISFET forming region;
(c) forming a first conductive film made of metal or metal compound on the first gate insulating film in the first MISFET forming region and on the second gate insulating film in the second MISFET forming region;
(d) forming a second conductive film including a polysilicon film on the first conductive film;
(e) patterning the second conductive film and the first conductive film, thereby forming a first gate electrode extending from the first MISFET forming region to the element isolation region and a second gate electrode extending from the second MISFET forming region to the element isolation region;
(f) forming a first source region and a first drain region in the first MISFET forming region of the semiconductor substrate;
(g) forming a second source region and a second drain region in the second MISFET forming region of the semiconductor substrate;
(h) forming a first insulating film on the semiconductor substrate so as to cover the first gate electrode and the second gate electrode;
(i) forming a contact hole penetrating through the first insulating film so as to expose a part of an upper surface of the first gate electrode formed on the element isolation region, one side surface of the first gate electrode formed on the element isolation region and the second drain region formed in the second MISFET forming region;
(j) performing wet etching to a part of the first conductive film constituting the first gate electrode from one side surface of the first conductive film exposed on an inner surface of the contact hole, thereby forming a concave portion in the one side surface of the first conductive film constituting the first gate electrode; and
(k) embedding a conductive material into the contact hole including the concave portion, thereby forming a plug,
wherein the second conductive film constituting the first gate electrode and the plug are in contact with each other at a part of an upper surface of the second conductive film constituting the first gate electrode, one side surface of the second conductive film constituting the first gate electrode, and a part of a bottom surface of the second conductive film constituting the first gate electrode and exposed from the concave portion.

29. The manufacturing method of the semiconductor device according to claim 28,
wherein the wet etching in the step (j) includes a step of performing sulfuric acid treatment using sulfuric acid to the inner surface of the contact hole and then performing hydrogen peroxide treatment using hydrogen peroxide.

30. The manufacturing method of the semiconductor device according to claim 29,
wherein the step (k) includes the steps of:
(k1) forming a barrier conductive film on the inner surface of the contact hole including the concave portion;
(k2) forming a tungsten film on the barrier conductive film, thereby filling the contact hole with the barrier conductive film and the tungsten film; and
(k3) removing unnecessary barrier conductive film and tungsten film formed on the first insulating film.

31. The manufacturing method of the semiconductor device according to claim 30,
wherein the step (k1) includes a step of forming a titanium film by using a CVD method on the inner surface of the contact hole including the concave portion.

32. The manufacturing method of the semiconductor device according to claim 31,
wherein the step (k1) further includes a step of performing plasma nitridation treatment using ammonia gas to a surface of the titanium film, thereby forming a titanium nitride film on the surface of the titanium film.

33. The manufacturing method of the semiconductor device according to claim 32,
wherein, in the step (k2), the tungsten film is formed by a CVD method using diborane as a material.

34. The manufacturing method of the semiconductor device according to claim 33,
wherein the concave portion is filled with the titanium film and the titanium nitride film formed on the surface of the titanium film.
